(19) United States
(12) Patent Application Publication
(10) Pub. No.: US 2025/0255172 A1
(43) Pub. Date: Aug. 7, 2025

(54) Organic Compound, Light-Emitting Device, and Display Apparatus

(71) Applicant: Semiconductor Energy Laboratory Co., Ltd., Kanagawa-Ken (JP)

(72) Inventors: Tomoya YAMAGUCHI, Atsugi, Kanagawa (JP); Hideko YOSHIZUMI, Atsugi, Kanagawa (JP); Airi UEDA, Zama, Kanagawa (JP); Takeyoshi WATABE, Atsugi, Kanagawa (JP); Satoshi SEO, Atsugi, Kanagawa (JP)

(73) Assignee: Semiconductor Energy Laboratory Co., Ltd., Kanagawa-Ken (JP)

(21) Appl. No.: 18/856,290

(22) PCT Filed: Mar. 31, 2023
(86) PCT No.: PCT/IB2023/053221

§ 371 Date: Oct. 11, 2024

(30) Foreign Application Priority Data
Apr. 15, 2022 (JP) 2022-067292

(51) Int. Cl. H10K 85/30; C07F 15/00; C09K 11/06; H10K 50/11; H10K 101/25; H10K 101/30; H10K 101/40

(52) U.S. Cl. CPC H10K 85/342; C07F 15/0033; C09K 11/06; C09K 2211/1007; C09K 2211/1029; C09K 2211/185; H10K 50/11; H10K 2101/25; H10K 2101/30; H10K 2101/40

(57) ABSTRACT

A novel organic compound that is highly convenient, useful, or reliable is provided. The organic compound is represented by General Formula (G0).

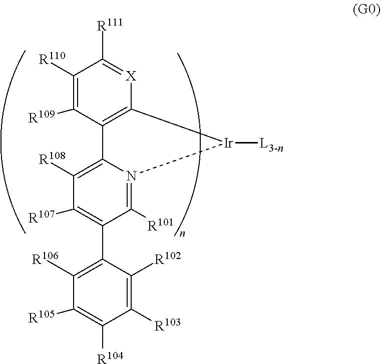

In General Formula (G0), X is a nitrogen atom or a carbon atom. When X is a carbon atom, X is bonded to hydrogen or a substituent. One of R104 and R105 is a cyano group. At least one of R102 and R107 is an alkyl group having 1 to 6 carbon atoms. The rest of R101 to R111 are each independently hydrogen or a substituent. The substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group. The substituents may be bonded to each other to form a ring. n is an integer greater than or equal to 1 and less than or equal to 3. L is a ligand.

### TECHNICAL FIELD

One embodiment of the present invention relates to an organic compound, a light-emitting device, a display apparatus, an electronic device, a light-emitting apparatus, a lighting device, or a semiconductor device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specific examples of the technical field of one embodiment of the present invention disclosed in this specification include a semiconductor device, a display apparatus, a light-emitting apparatus, a power storage device, a memory device, a method for driving any of them, and a method for manufacturing any of them.

### BACKGROUND ART

Novel organic compounds each having a twisted aryl group are known, for example. In particular, the organic compounds each include a 2-phenylpyridine ligand having a twisted aryl group in a pyridine portion of the ligand. These compounds can be each used particularly as a light-emitting dopant in an organic light-emitting device (Patent Document 1).

### REFERENCE

### Patent Document

[Patent Document 1] PCT International Publication No. WO2010/028151

### SUMMARY OF THE INVENTION

### Problems to be Solved by the Invention

An object of one embodiment of the present invention is to provide a novel organic compound that is highly convenient, useful, or reliable. Another object is to provide a novel light-emitting device that is highly convenient, useful, or reliable. Another object is to provide a novel display apparatus that is highly convenient, useful, or reliable. Another object is to provide a novel electronic device that is highly convenient, useful, or reliable. Another object is to provide a novel light-emitting apparatus that is highly convenient, useful, or reliable. Another object is to provide a novel lighting device that is highly convenient, useful, or reliable. Another object is to provide a novel organic compound, a novel light-emitting device, a novel display apparatus, a novel electronic device, a novel light-emitting apparatus, a novel lighting device, or a novel semiconductor device.

Note that the description of these objects does not preclude the existence of other objects. In one embodiment of the present invention, there is no need to achieve all these objects. Other objects will be apparent from the description of the specification, the drawings, the claims, and the like, and other objects can be derived from the description of the specification, the drawings, the claims, and the like.

### Means for Solving the Problems

(1) One embodiment of the present invention is an organic compound represented by General Formula (G0).

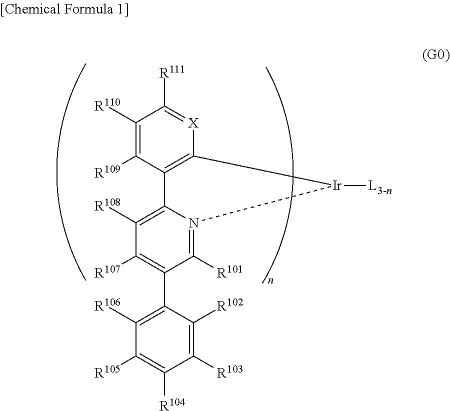

Note that in General Formula (G0), X is a nitrogen atom or a carbon atom. When X is a carbon atom, X is bonded to hydrogen or a substituent.

One of R¹⁰⁴ and R¹⁰⁵ is a cyano group. At least one of R¹⁰² and R¹⁰⁷ is an alkyl group having 1 to 6 carbon atoms. The rest of R¹⁰¹ to R¹¹¹ are each independently hydrogen or a substituent.

The substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group. The substituents may be bonded to each other to form a ring.

n is an integer greater than or equal to 1 and less than or equal to 3. L is a ligand represented by Structural Formula (L0).

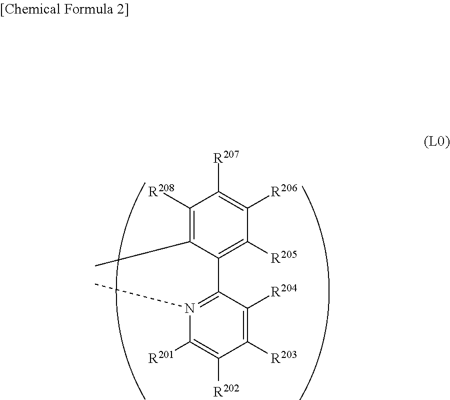

In Structural Formula (L0), R²⁰¹ to R²⁰⁸ are each independently hydrogen or an alkyl group having 1 to 6 carbon atoms. In General Formula (G0), any hydrogen may be deuterium.

Accordingly, the cyano group introduced into the phenyl group can stabilize bonding energy in a molecule, so that the thermophysical property can be improved. Furthermore, the cyano group introduced into the phenyl group stabilizes molecular orbital energy, so that the emission wavelength can be adjusted. As a result, a novel organic compound that is highly convenient, useful, or reliable can be provided.

(2) One embodiment of the present invention is an organic compound represented by General Formula (G1).

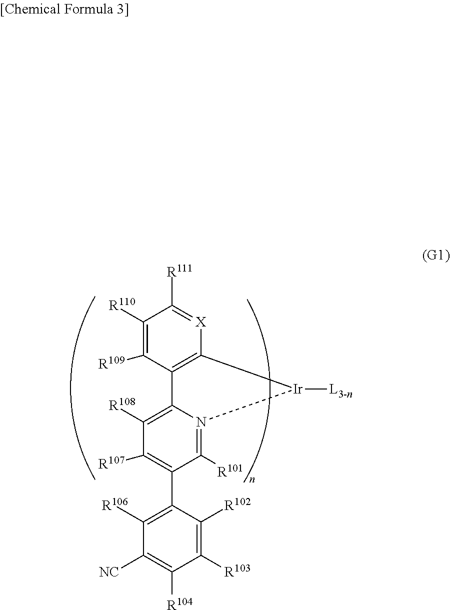

Note that in General Formula (G1), X is a nitrogen atom or a carbon atom. When X is a carbon atom, X is bonded to hydrogen or a substituent.

At least one of R¹⁰² and R¹⁰⁷ is an alkyl group having 1 to 6 carbon atoms. The rest of R¹⁰¹ to R¹¹¹ are each independently hydrogen or a substituent.

The substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group. The substituents may be bonded to each other to form a ring.

n is an integer greater than or equal to 1 and less than or equal to 3. L is a ligand represented by Structural Formula (L1).

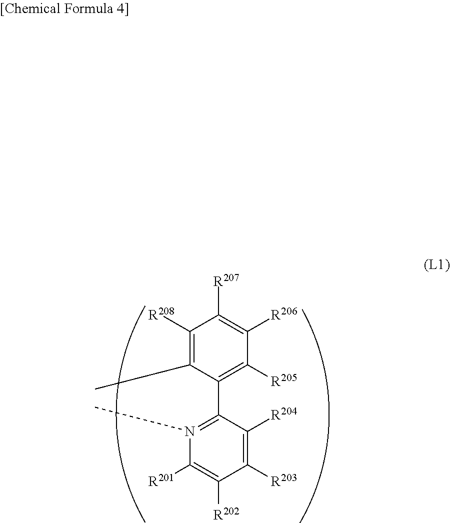

In Structural Formula (L1), R²⁰¹ to R²⁰⁸ are each independently hydrogen or an alkyl group having 1 to 6 carbon atoms. In General Formula (G1), any hydrogen may be deuterium.

In the organic compound that has the above structure and is represented by General Formula (G1), R¹⁰² or R¹⁰⁷ brings about a steric hindrance effect between a phenyl group into which a cyano group is introduced and a phenylpyridine skeleton to which iridium coordinates. This inhibits free rotation of the phenyl group into which the cyano group is introduced, enabling an improvement in the thermophysical property of the compound, for example, inhibition of thermal decomposition and inhibition of decomposition due to high-temperature heating in a synthesis reaction; thus, the yield of synthesis can be improved. Moreover, the sublimation property can be improved without thermal decomposition in sublimation. Resistance to use in a high-temperature environment can be exhibited. Furthermore, the emission wavelength can be shortened by a twist generated between the phenyl group into which the cyano group is introduced and the phenylpyridine skeleton to which iridium coordinates. High emission efficiency can also be achieved. As a result, a novel organic compound that is highly convenient, useful, or reliable can be provided.

(3) One embodiment of the present invention is an organic compound represented by General Formula (G2).

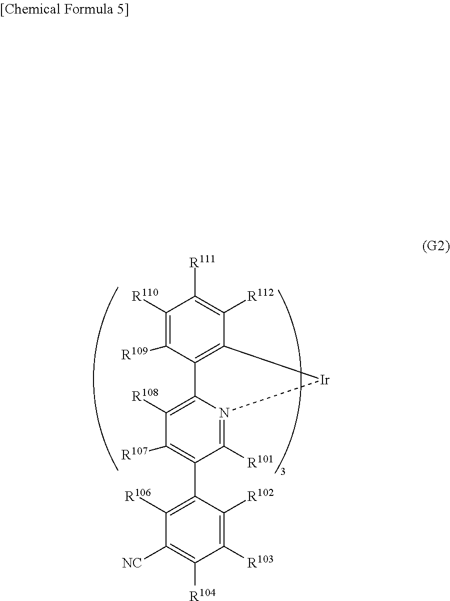

Note that in General Formula (G2), at least one of R¹⁰² and R¹⁰⁷ is an alkyl group having 1 to 6 carbon atoms. The rest of R¹² to R¹¹² are each independently hydrogen or a substituent.

The substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group. The substituents may be bonded to each other to form a ring.

In General Formula (G2), any hydrogen may be deuterium.

Accordingly, the synthesis step can be shortened and the yield can be improved. In addition, molecules are easily oriented, and emission efficiency can be improved. As a result, a novel organic compound that is highly convenient, useful, or reliable can be provided.

(4) One embodiment of the present invention is an organic compound represented by General Formula (G3).

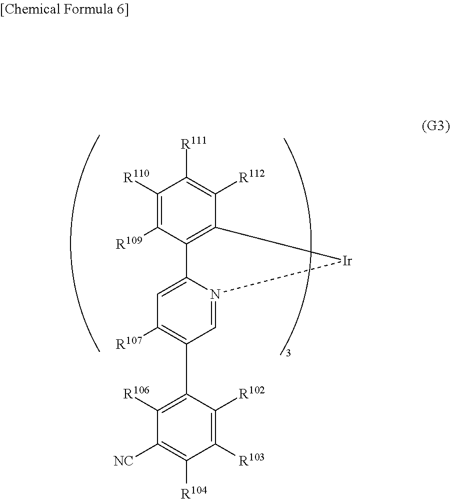

Note that in General Formula (G3), at least one of R¹⁰² and R¹⁰⁷ is an alkyl group having 1 to 6 carbon atoms. The rest of R¹⁰² to R¹² are each independently hydrogen or a substituent.

The substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group. The substituents may be bonded to each other to form a ring.

In General Formula (G3), any hydrogen may be deuterium.

Accordingly, the yield of synthesis can be improved. As a result, a novel organic compound that is highly convenient, useful, or reliable can be provided.

(5) One embodiment of the present invention is an organic compound represented by General Formula (G4).

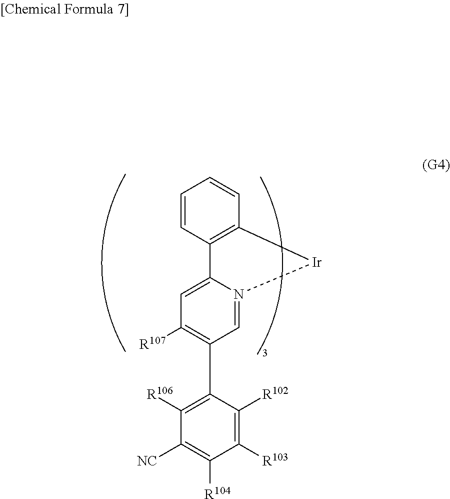

Note that in General Formula (G4), at least one of R¹⁰² and R¹⁰⁷ is an alkyl group having 1 to 6 carbon atoms. The rest of R¹⁰² to R¹⁰⁷ are each independently hydrogen or a substituent.

The substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group. The substituents may be bonded to each other to form a ring.

In General Formula (G4), any hydrogen may be deuterium.

Accordingly, thermal stability can be improved even in a homoleptic structure. As a result, a novel organic compound that is highly convenient, useful, or reliable can be provided.

(6) One embodiment of the present invention is a light-emitting device including a first electrode, a second electrode, and a first unit. The first unit is interposed between the first electrode and the second electrode. The first unit includes the above-described organic compound.

Therefore, the first unit includes the organic compound of one embodiment of the present invention. The emission spectrum of the organic compound of one embodiment of the present invention includes light with a wavelength shorter than 500 nm, so that when the organic compound is used with a fluorescent material, energy can be efficiently transferred to the fluorescent material. A phenomenon in which the luminance of the light-emitting device decreases in use can be inhibited. The reliability of the light-emitting device can be increased. In addition, the reliability of the light-emitting device can be increased particularly at a temperature higher than room temperature. As a result, a novel light-emitting device that is highly convenient, useful, or reliable can be provided.

(7) One embodiment of the present invention is a display apparatus including a first light-emitting device and a second light-emitting device.

The first light-emitting device includes a third electrode, a fourth electrode, a second unit, and a first layer. The second unit is interposed between the third electrode and the fourth electrode. The first layer is interposed between the second unit and the third electrode.

The second unit includes the organic compound. The first layer includes a second organic compound comprising having a halogen group or a cyano group, or a transition metal oxide.

The second light-emitting device is adjacent to the first light-emitting device. The second light-emitting device includes a fifth electrode, a sixth electrode, a third unit, and a second layer. A space is between the fifth electrode and the third electrode. The third unit is interposed between the sixth electrode and the fifth electrode. The third unit includes a light-emitting material. The second layer is interposed between the third unit and the fifth electrode.

The second layer includes the second organic compound or the transition metal oxide. The second layer includes a region thinner than the first layer between the second layer and the first layer. The region overlaps with the space.

Accordingly, current flowing through a region having a small thickness can be reduced, for example. In addition, current flowing between the first layer and the second layer can be reduced. Occurrence of a phenomenon in which the second light-emitting device that is adjacent to the first light-emitting device unintentionally emits light in accordance with the operation of the first light-emitting device can be inhibited. As a result, a novel display apparatus that is highly convenient, useful, or reliable can be provided.

(8) One embodiment of the present invention is a display apparatus including a first functional layer and a second functional layer.

The first functional layer overlaps with the second functional layer. The first functional layer includes a first pixel circuit and a second pixel circuit. The second functional layer includes a first light-emitting device and a second light-emitting device.

The first light-emitting device includes a third electrode, a fourth electrode, and a second unit. The second unit is interposed between the third electrode and the fourth electrode. The second unit includes the organic compound. The third electrode is electrically connected to the first pixel circuit.

The second light-emitting device includes a fifth electrode, a sixth electrode, and a third unit. The third unit is interposed between the fifth electrode and the sixth electrode. The fifth electrode is electrically connected to the second pixel circuit. The sixth electrode is electrically connected to the fourth electrode.

Although the block diagram in drawings attached to this specification shows components classified based on their functions in independent blocks, it is difficult to classify actual components based on their functions completely, and one component can have a plurality of functions.

Note that the light-emitting apparatus in this specification includes, in its category, an image display device that uses a light-emitting device. The light-emitting apparatus may also include, in its category, a module in which a light-emitting device is provided with a connector such as an anisotropic conductive film or a TCP (Tape Carrier Package), a module in which a printed wiring board is provided at the end of a TCP, and a module in which an IC (integrated circuit) is directly mounted on a light-emitting device by a COG (Chip On Glass) method. Furthermore, a lighting device or the like may include the light-emitting apparatus.

### Effect of the Invention

With one embodiment of the present invention, a novel organic compound that is highly convenient, useful, or reliable can be provided. One embodiment of the present invention can provide a novel light-emitting device that is highly convenient, useful, or reliable. One embodiment of the present invention can provide a novel display apparatus that is highly convenient, useful, or reliable. One embodiment of the present invention can provide a novel electronic device that is highly convenient, useful, or reliable. One embodiment of the present invention can provide a novel light-emitting apparatus that is highly convenient, useful, or reliable. One embodiment of the present invention can provide a novel lighting device that is highly convenient, useful, or reliable. A novel organic compound can be provided. A novel light-emitting device can be provided. A novel display apparatus can be provided. A novel electronic device can be provided. A novel light-emitting apparatus can be provided. A novel lighting device can be provided.

Note that the description of these effects does not preclude the existence of other effects. One embodiment of the present invention does not necessarily have all these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A and FIG. 1B illustrate structures of a light-emitting device of an embodiment.

FIG. 2A and FIG. 2B illustrate structures of a light-emitting device of an embodiment.

FIG. 3A and FIG. 3B illustrate structures of a display apparatus of an embodiment.

FIG. 4A and FIG. 4B illustrate structures of a display apparatus of an embodiment.

FIG. 5A to FIG. 5C illustrate a structure of a device of an embodiment.

FIG. 6 illustrates a structure of a device of an embodiment.

FIG. 7A and FIG. 7B illustrate structures of a device of an embodiment.

FIG. 8A and FIG. 8B illustrate a structure of an active matrix light-emitting apparatus of an embodiment.

FIG. 9A and FIG. 9B illustrate structures of an active matrix light-emitting apparatus of an embodiment.

FIG. 10 illustrates a structure of an active matrix light-emitting apparatus of an embodiment.

FIG. 11A and FIG. 11B illustrate a structure of a passive matrix light-emitting apparatus of an embodiment.

FIG. 12A and FIG. 12B illustrate a structure of a lighting device of an embodiment.

FIG. 13A to FIG. 13D illustrate structures of electronic devices of embodiments.

FIG. 14A to FIG. 14C illustrate structures of electronic devices of embodiments.

FIG. 15 illustrates a structure of a lighting device of an embodiment.

FIG. 16 illustrates a structure of a lighting device of an embodiment.

FIG. 17 illustrates structures of in-vehicle display apparatuses and lighting devices of embodiments.

FIG. 18A to FIG. 18C illustrate a structure of an electronic device of an embodiment.

FIG. 19 shows a proton NMR spectrum of an organic compound of an example.

FIG. 20 shows an absorption spectrum and an emission spectrum of an organic compound of an example.

FIG. 21 shows a proton NMR spectrum of an organic compound of an example.

FIG. 22 shows an absorption spectrum and an emission spectrum of an organic compound of an example.

FIG. 23 shows a proton NMR spectrum of an organic compound of an example.

FIG. 24 shows an absorption spectrum and an emission spectrum of an organic compound of an example.

FIG. 25 shows a proton NMR spectrum of an organic compound of an example.

FIG. 26 shows an absorption spectrum and an emission spectrum of an organic compound of an example.

FIG. 27 illustrates a structure of a light-emitting device of an example.

FIG. 28 shows current density-luminance characteristics of light-emitting devices of an example.

FIG. 29 shows luminance-current efficiency characteristics of light-emitting devices of an example.

FIG. 30 shows voltage-luminance characteristics of light-emitting devices of an example.

FIG. 31 shows voltage-current characteristics of light-emitting devices of an example.

FIG. 32 shows luminance-external quantum efficiency characteristics of light-emitting devices of an example.

FIG. 33 shows emission spectra of light-emitting devices of an example.

FIG. 34 shows changes in normalized luminance overtime of light-emitting devices of an example.

### MODE FOR CARRYING OUT THE INVENTION

An organic compound of one embodiment of the present invention is represented by General Formula (G0).

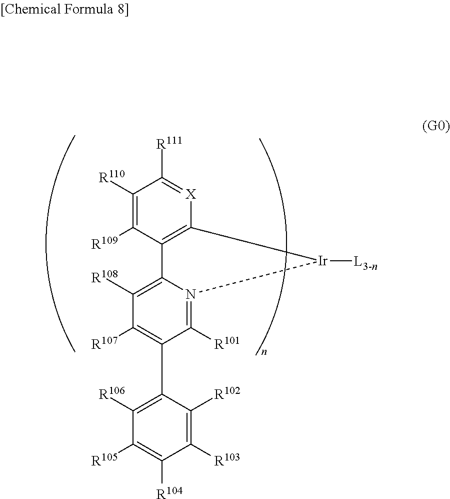

Note that in General Formula (G0), X is a nitrogen atom or a carbon atom. When X is a carbon atom, X is bonded to hydrogen or a substituent. One of R¹⁰⁴ and R¹⁰⁵ is a cyano group. At least one of R¹⁰² and R¹⁰⁷ is an alkyl group having 1 to 6 carbon atoms. The rest of R¹⁰¹ to R¹¹¹ are each independently hydrogen or a substituent. The substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group. The substituents may be bonded to each other to form a ring. n is an integer greater than or equal to 1 and less than or equal to 3. L is a ligand.

Thus, R¹⁰² or R¹⁰⁷ brings about a steric hindrance effect between a phenyl group into which a cyano group is introduced and a phenylpyridine skeleton to which iridium coordinates. This inhibits free rotation of the phenyl group into which the cyano group is introduced, leading to the thermophysical property of the compound, for example, inhibition of thermal decomposition and inhibition of decomposition due to high-temperature heating in a synthesis reaction, and the yield of synthesis can be improved. Moreover, the sublimation property can be improved without thermal decomposition in sublimation. Resistance to use in a high-temperature environment can be exhibited. Furthermore, a twist is generated between the phenyl group into which the cyano group is introduced and the phenylpyridine skeleton to which iridium coordinates. The emission wavelength can be shortened. High emission efficiency can also be achieved. As a result, a novel organic compound that is highly convenient, useful, or reliable can be provided.

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

In this embodiment, an organic compound of one embodiment of the present invention is described.

### Organic Compound Example 1

An organic compound of one embodiment of the present invention described in this embodiment is represented by General Formula (G0).

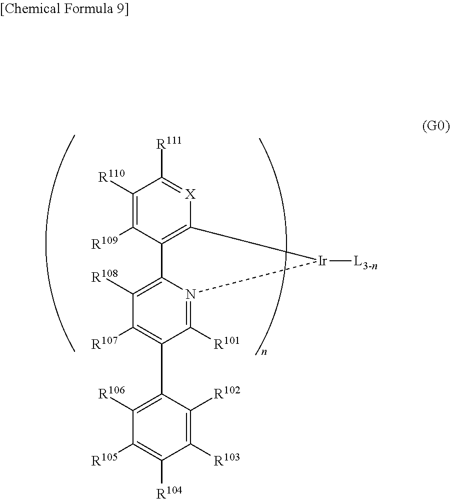

Note that in General Formula (G0), X is a nitrogen atom or a carbon atom. When X is a carbon atom, X is bonded to hydrogen or a substituent.

Among R¹⁰¹ to R¹¹¹, one of R¹⁰⁴ and R¹⁰⁵ is a cyano group. At least one of R¹⁰² and R¹⁰⁷ is an alkyl group having 1 to 6 carbon atoms. The rest of R¹⁰¹ to R¹¹¹ are each independently hydrogen or a substituent.

Note that the hydrogen may be substituted by deuterium. Examples of the alkyl group having 1 to 6, inclusive, carbon atoms include a methyl group, an ethyl group, a propyl group, a butyl group, an isobutyl group, a sec-butyl group, a tert-butyl group, a pentyl group, and a hexyl group. Part or all of hydrogen of the alkyl group having 1 to 6, inclusive, carbon atoms may be substituted by deuterium.

The substituent bonded to X when X is a carbon atom and R¹⁰¹ to R¹¹¹ are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group. The substituents may be bonded to each other to form a ring.

Examples of the alkyl group having 1 to 6 carbon atoms include a methyl group, an ethyl group, a propyl group, a butyl group, an isobutyl group, a sec-butyl group, a tert-butyl group, a pentyl group, and a hexyl group.

Examples of the cycloalkyl group having 3 to 7 carbon atoms include a cyclopropyl group, a cyclobutyl group, a cyclopentyl group, a cyclohexyl group, a 1-methylcyclohexyl group, a 2,6-dimethylcyclohexyl group, a cycloheptyl group, and a cyclooctyl group. Note that in the case where these groups have a substituent, the substituent can be an alkyl group having 1 to 6 carbon atoms or a phenyl group.

Examples of the aryl group having 6 to 13 carbon atoms include a phenyl group, an o-tolyl group, an in-tolyl group, a p-tolyl group, a mesityl group, an o-biphenyl group, an m-biphenyl group, a p-biphenyl group, a 1-naphthyl group, a 2-naphthyl group, and fluorenyl. Note that in the case where these groups have a substituent, the substituent can be an alkyl group having 1 to 6 carbon atoms or a phenyl group.

Examples of the heteroaryl group having 1 to 5 carbon atoms include a pyridinyl group, a pyrimidinyl group, a pyridazinyl group, a pyrazinyl group, and a triazinyl group. Note that in the case where these groups have a substituent, the substituent can be an alkyl group having 1 to 6 carbon atoms or a phenyl group.

Examples of the amino group include a methylamino group, an ethylamino group, an isopropylamino group, an isobutylamino group, a phenylamino group, and a 2,6-dimethylphenylamino group.

Note that in this entire specification, the description of the substituent bonded to X when X is a carbon atom and R¹⁰¹ to R¹¹¹ is used for the description of the substituent of the organic compound of one embodiment of the present invention.

n is an integer greater than or equal to 1 and less than or equal to 3. L is a ligand represented by Structural Formula (L0).

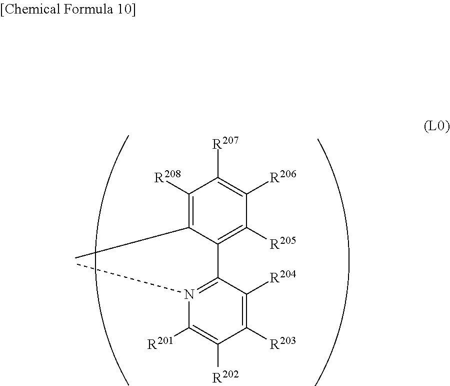

Note that in Structural Formula (L0), R²⁰¹ to R²⁰⁸ are each independently hydrogen or an alkyl group having 1 to 6 carbon atoms. The hydrogen may be substituted by deuterium. Examples of the alkyl group having 1 to 6, inclusive, carbon atoms include a methyl group, an ethyl group, a propyl group, a butyl group, an isobutyl group, a sec-butyl group, a tert-butyl group, a pentyl group, and a hexyl group. Part or all of hydrogen of the alkyl group having 1 to 6, inclusive, carbon atoms may be substituted by deuterium. When n is 1 or 2, for example, 2-phenylpyridine can be used as the ligand L.

In General Formula (G0), any hydrogen may be deuterium.

Specific examples of the organic compound having the above-described structure are shown below.

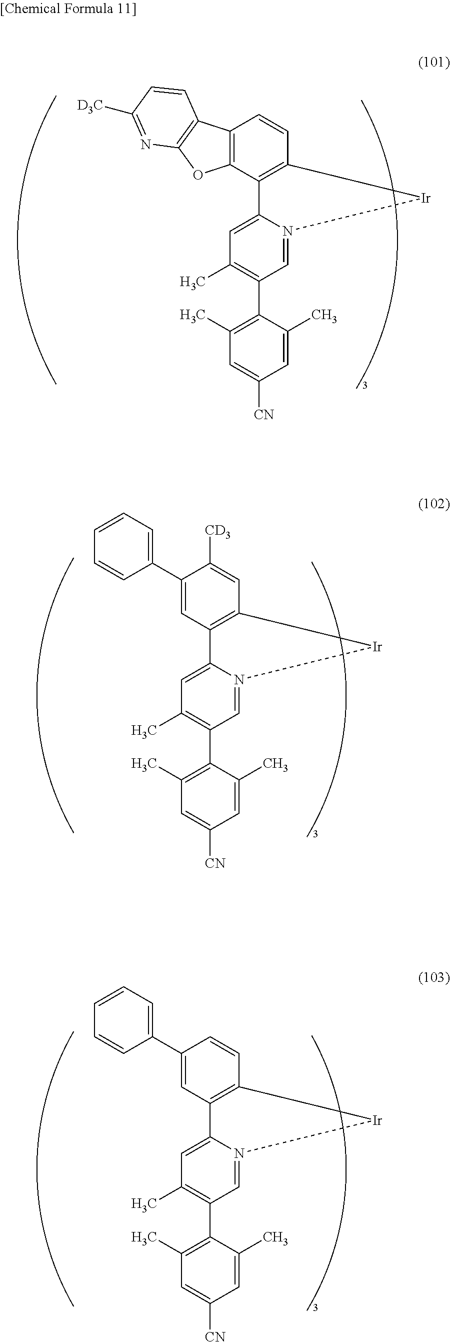

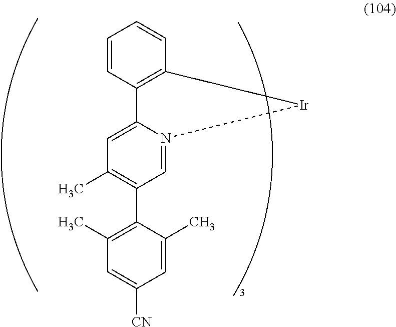

### Organic Compound Example 2

An organic compound of one embodiment of the present invention is represented by General Formula (G1).

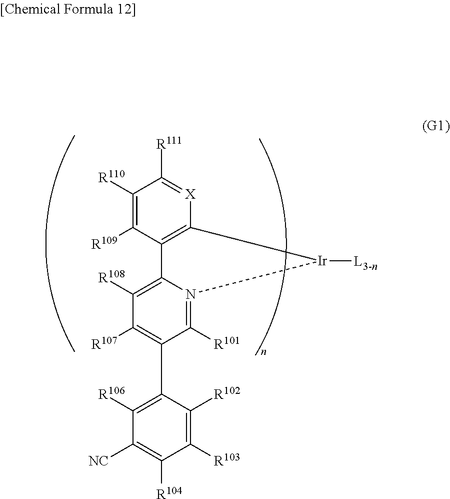

Note that in General Formula (G1), X is a nitrogen atom or a carbon atom. When X is a carbon atom, X is bonded to hydrogen or a substituent.

At least one of R¹⁰² and R¹⁰⁷ is an alkyl group having 1 to 6 carbon atoms. The rest of R¹⁰¹ to R¹¹¹ are each independently hydrogen or a substituent. The substituents may be bonded to each other to form a ring.

The substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group.

n is an integer greater than or equal to 1 and less than or equal to 3. L is a ligand represented by Structural Formula (L1).

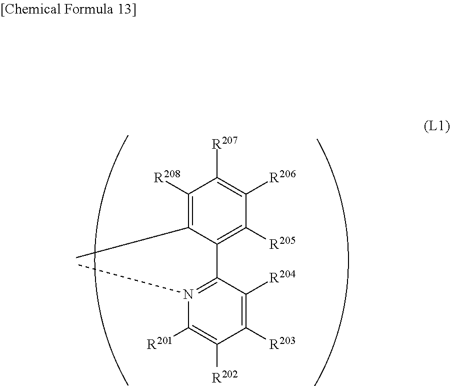

Note that in Structural Formula (L1), R²⁰¹ to R²⁰⁸ are each independently hydrogen or an alkyl group having 1 to 6 carbon atoms.

In General Formula (G1), any hydrogen may be deuterium.

Thus, R¹⁰² or R¹⁰⁷ brings about a steric hindrance effect between a phenyl group into which a cyano group is introduced and a phenylpyridine skeleton to which iridium coordinates. This inhibits free rotation of the phenyl group into which the cyano group is introduced, enabling an improvement in the thermophysical property of the compound, for example, inhibition of thermal decomposition and inhibition of decomposition due to high-temperature heating in a synthesis reaction; thus, the yield of synthesis can be improved. Moreover, the sublimation property can be improved without thermal decomposition in sublimation. Resistance to use in a high-temperature environment can be exhibited. Furthermore, a twist is generated between the phenyl group into which the cyano group is introduced and the phenylpyridine skeleton to which iridium coordinates. The emission wavelength can be shortened. High emission efficiency can also be achieved. As a result, a novel organic compound that is highly convenient, useful, or reliable can be provided.

Specific examples of the organic compound having the above-described structure are shown below.

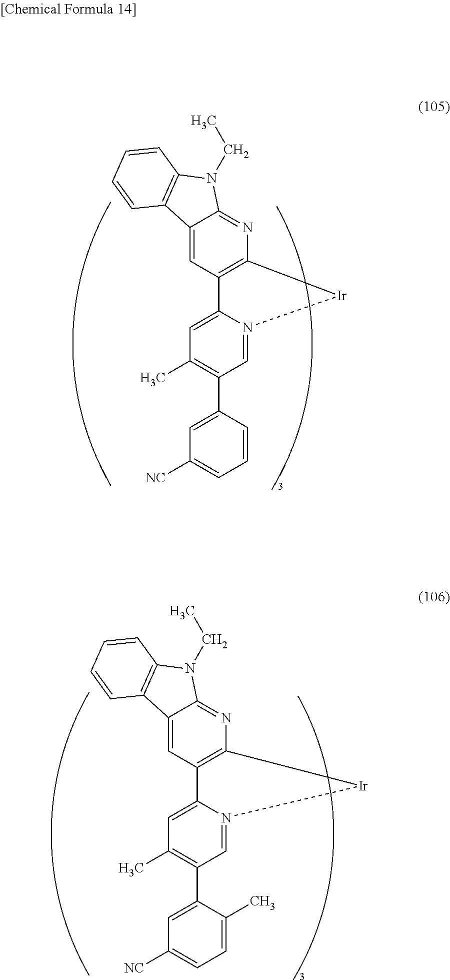

### Organic Compound Example 3

An organic compound of one embodiment of the present invention is represented by General Formula (G2).

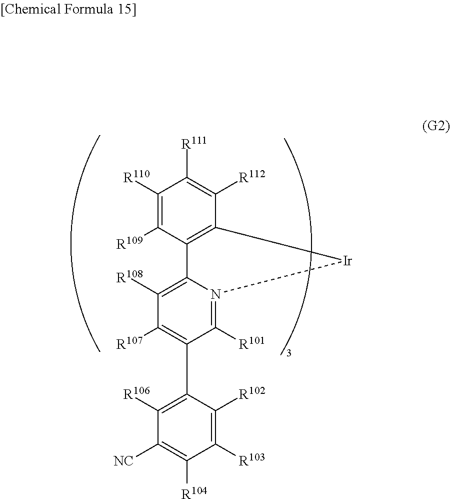

Note that in General Formula (G2), at least one of R¹⁰² and R¹⁰⁷ is an alkyl group having 1 to 6 carbon atoms. The rest of R¹⁰² to R¹¹² are each independently hydrogen or a substituent. The substituents may be bonded to each other to form a ring.

The substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group.

In General Formula (G2), any hydrogen may be deuterium.

Specific examples of the organic compound having the above-described structure are shown below.

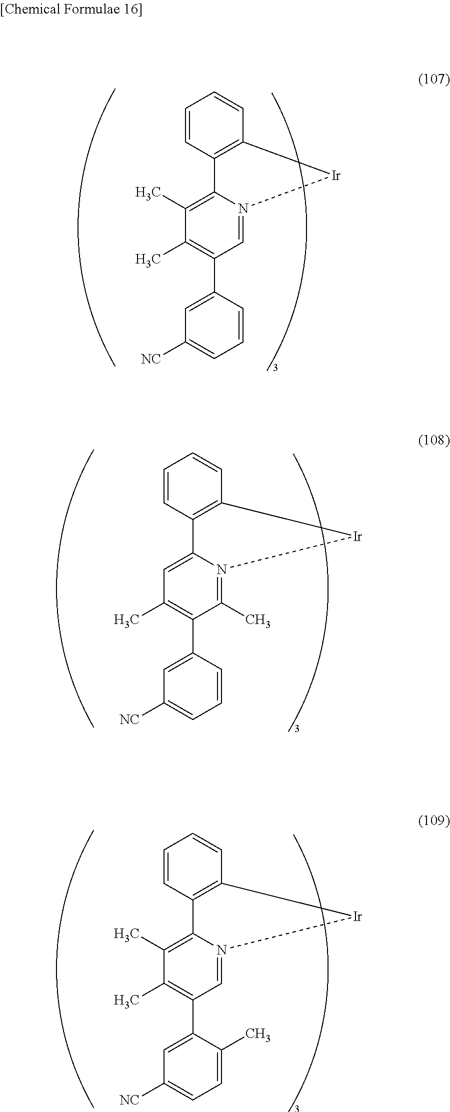

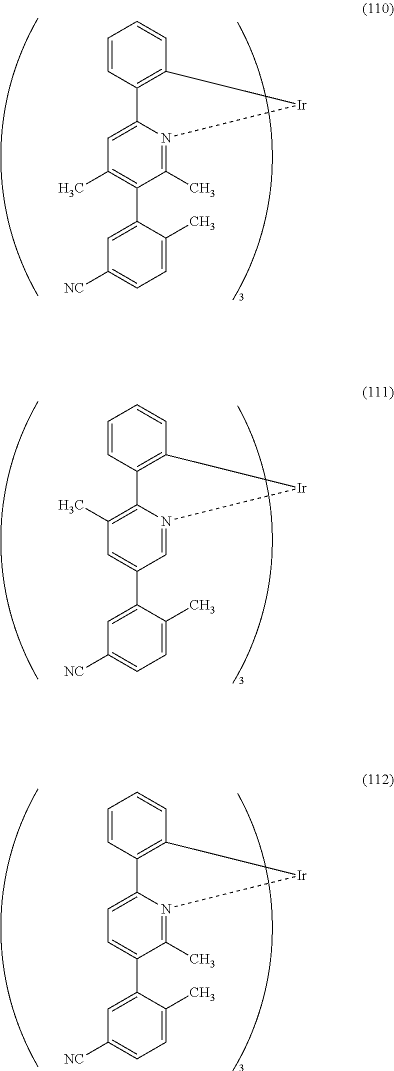

### Organic Compound Example 4

An organic compound of one embodiment of the present invention is represented by General Formula (G³).

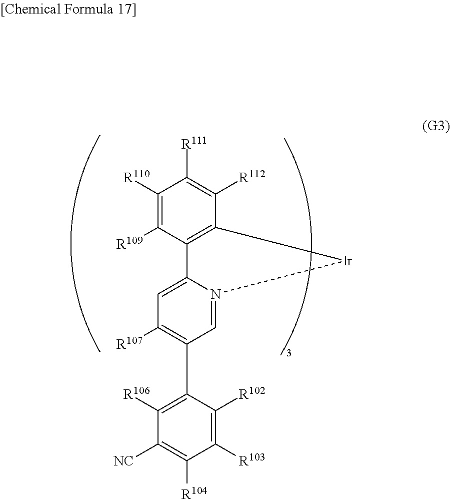

Note that in General Formula (G3), at least one of R¹⁰² and R¹⁰⁷ is an alkyl group having 1 to 6 carbon atoms. The rest of R¹⁰² to R¹¹² are each independently hydrogen or a substituent. The substituents may be bonded to each other to form a ring.

The substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group.

In General Formula (G3), any hydrogen may be deuterium.

Specific examples of the organic compound having the above-described structure are shown below.

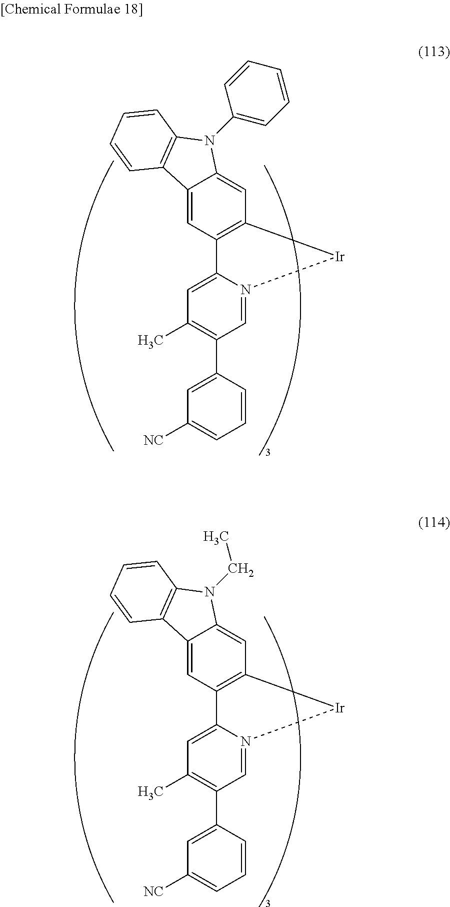

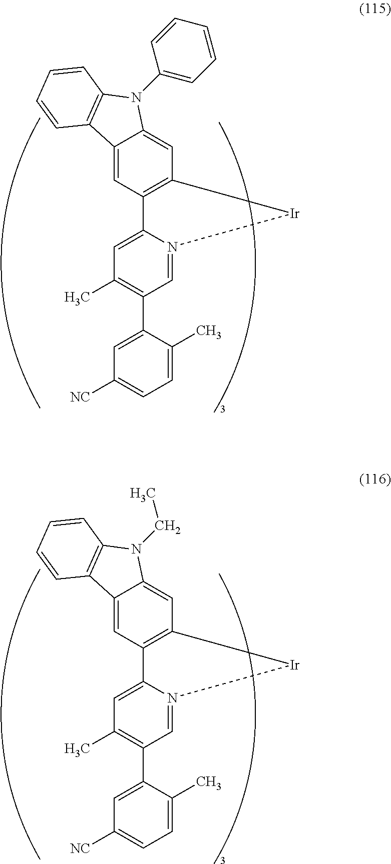

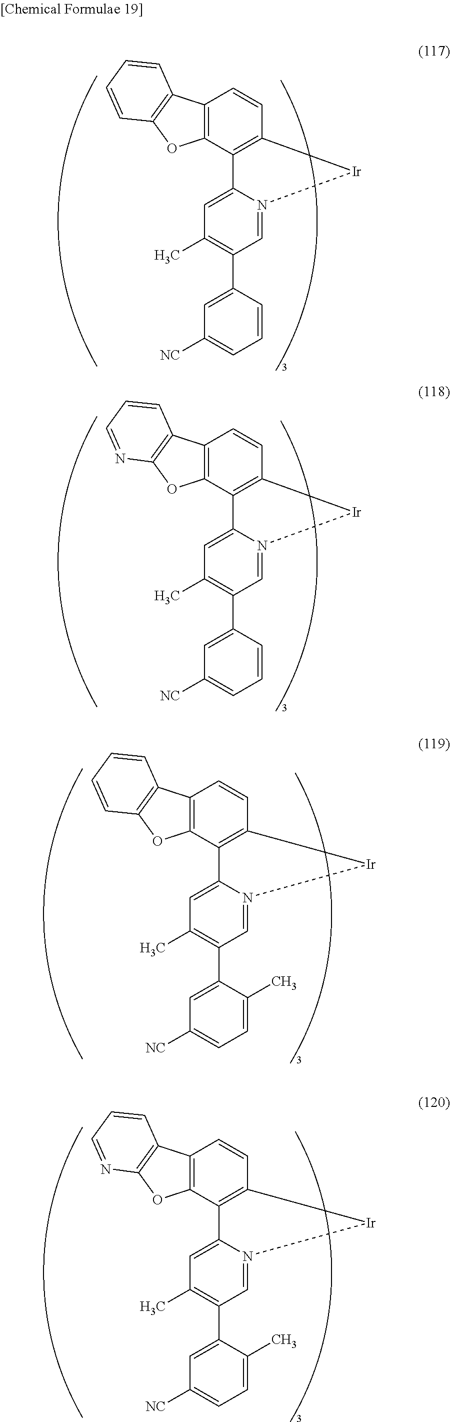

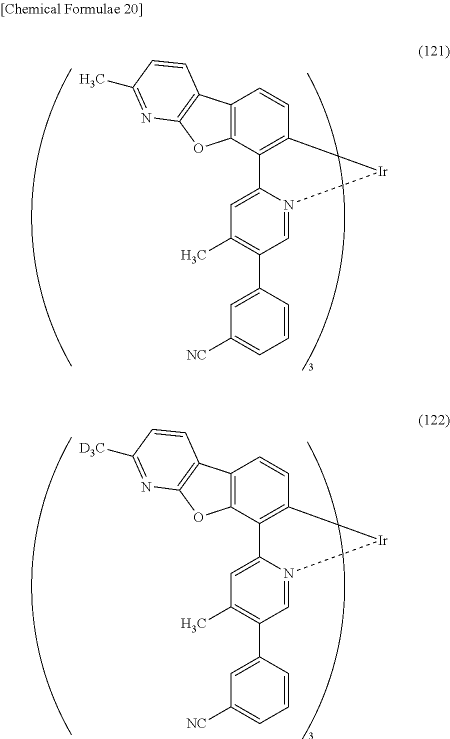

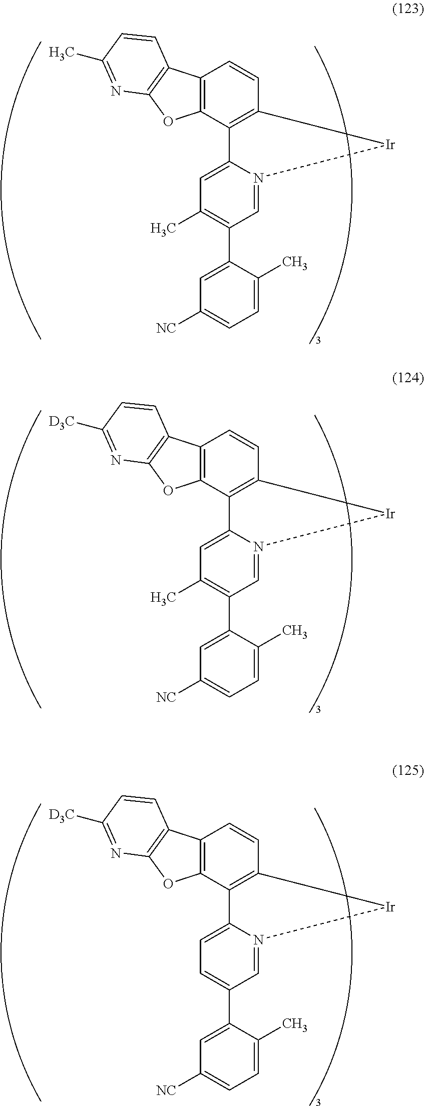

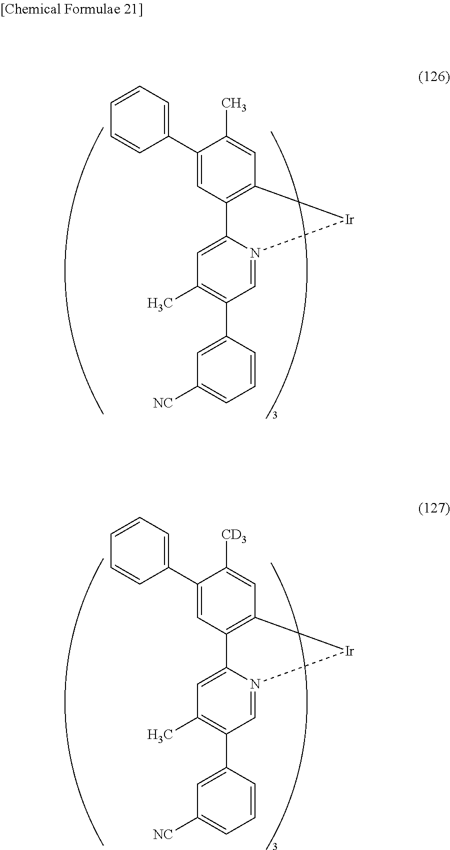

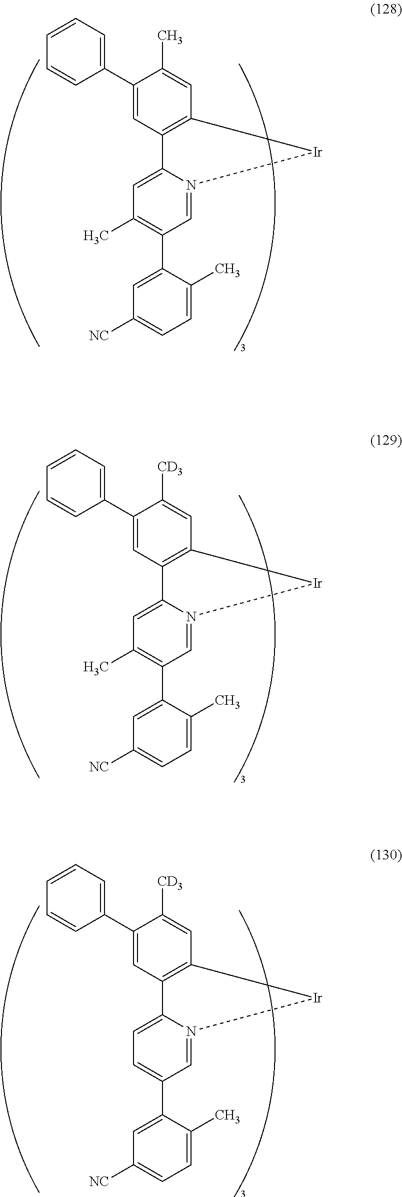

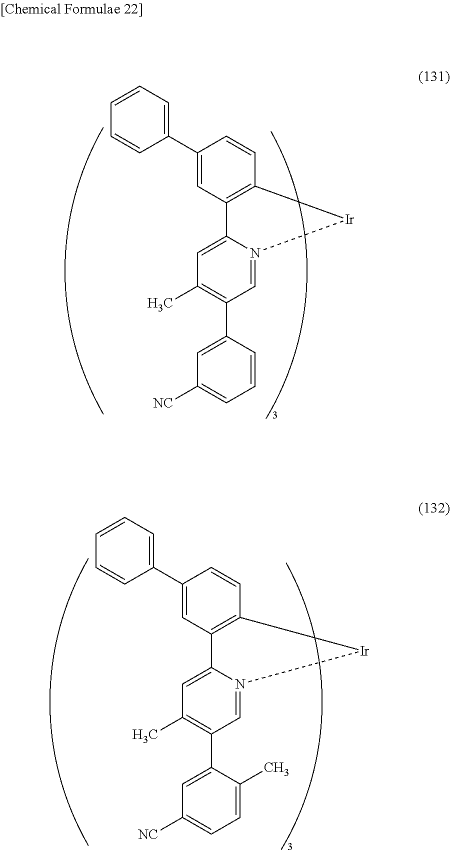

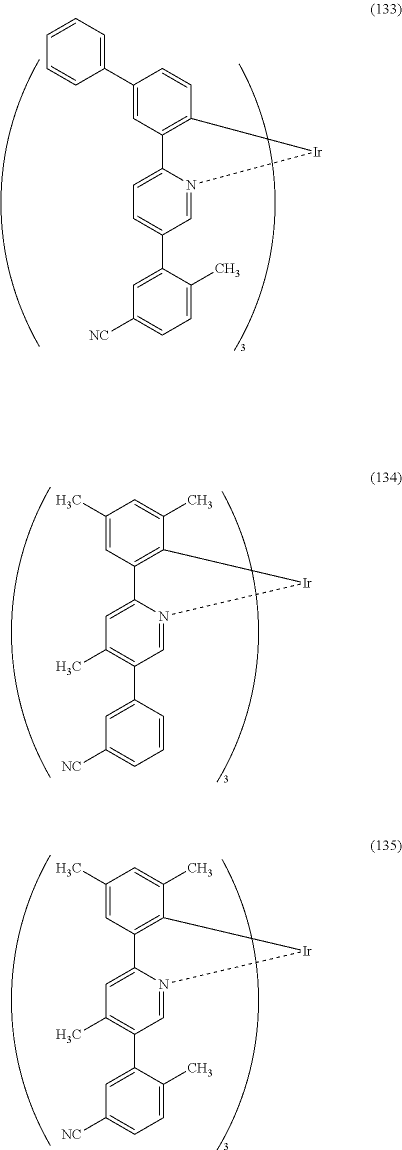

### Organic Compound Example 5

An organic compound of one embodiment of the present invention is represented by General Formula (G4).

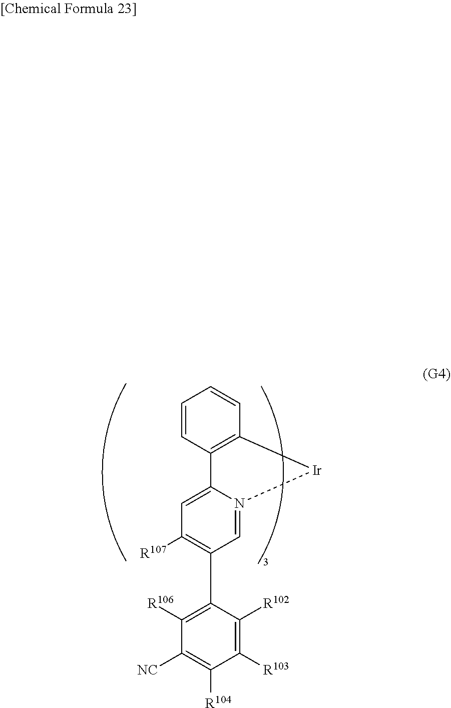

Note that in General Formula (G4), at least one of R¹⁰² and R¹⁰⁷ is an alkyl group having 1 to 6 carbon atoms. The rest of R¹⁰² to R are each independently hydrogen or a substituent. The substituents may be bonded to each other to form a ring.

The substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group.

In General Formula (G4), any hydrogen may be deuterium.

Accordingly, thermal stability can be improved even in a homoleptic structure. As a result, a novel organic compound that is highly convenient, useful, or reliable can be provided.

Specific examples of the organic compound having the above-described structure are shown below.

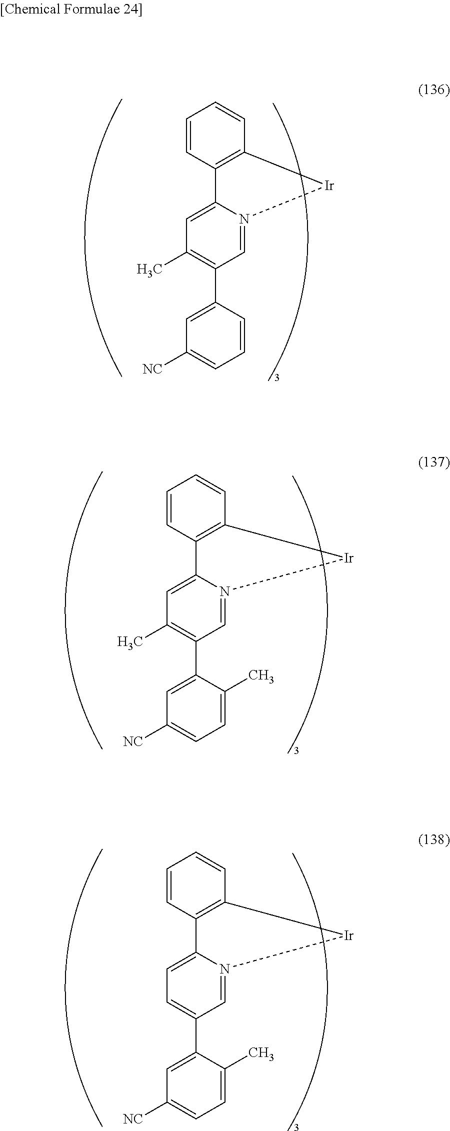

### <Example of Method for Synthesizing Organic Compound>

A method for synthesizing an organic compound of one embodiment of the present invention will be described. Note that the synthesis method is not limited to this. Another synthesis method or a known synthesis method can be employed for the synthesis.

### <<Method for Synthesizing Organic Compound Represented by General Formula (G0)

An organic compound represented by General Formula (G0) below can be synthesized by a method shown in Synthesis Scheme (a) below.

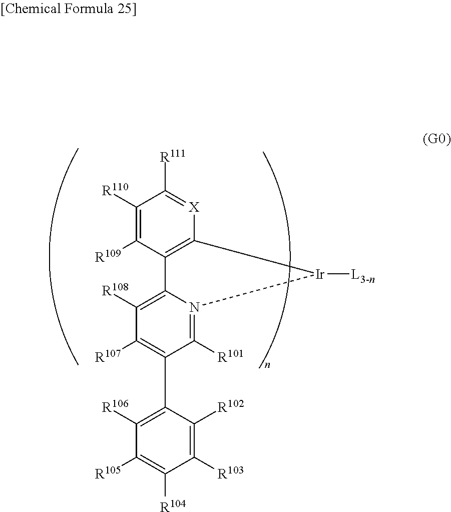

Note that in General Formula (G0), X is a nitrogen atom or a carbon atom. When X is a carbon atom, X is bonded to hydrogen or a substituent.

One of R¹⁰⁴ and R¹⁰⁵ is a cyano group. At least one of R¹⁰² and R¹⁰⁷ is an alkyl group having 1 to 6 carbon atoms. The rest of R¹¹ to R¹¹¹ are each independently hydrogen or a substituent.

The substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group. The substituents may be bonded to each other to form a ring.

Note that n is an integer greater than or equal to 1 and less than or equal to 3. L is a ligand represented by Structural Formula (L0).

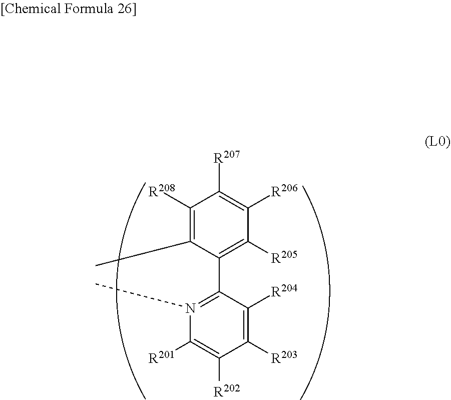

Note that in Structural Formula (L0), R²⁰¹ to R²⁰⁸ are each independently hydrogen or an alkyl group having 1 to 6 carbon atoms. In General Formula (G0), any hydrogen may be deuterium.

For example, as shown in Synthesis Scheme (a), a pyridine derivative represented by General Formula (Gpy0) is mixed with an iridium metal compound containing halogen (e.g., an iridium chloride hydrate or ammonium hexachloroiridate) or an iridium organometallic complex compound (e.g., an acetylacetonate complex or a diethylsulfide complex) and then heating is performed, whereby the organic compound represented by General Formula (G0) can be synthesized.

Alternatively, the pyridine derivative represented by General Formula (Gpy0) and the iridium metal compound containing halogen or the iridium organometallic complex compound are dissolved in an alcohol-based solvent (e.g., glycerol, ethylene glycol, 2-methoxyethanol, or 2-ethoxyethanol) and then heating is performed, whereby the organic compound represented by General Formula (G0) can be synthesized.

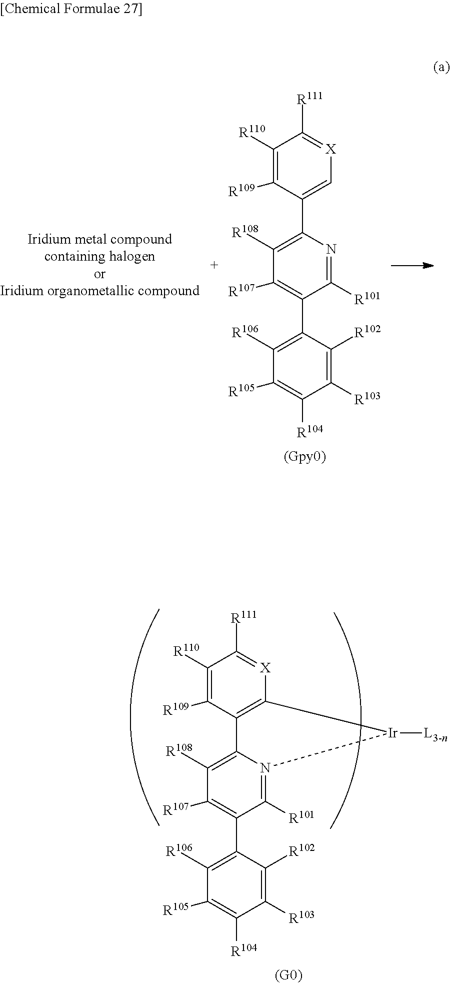

In Synthesis Scheme (a) above, X is a nitrogen atom or a carbon atom. When X is a carbon atom, X is bonded to hydrogen or a substituent.

One of R¹⁰⁴ and R¹⁰⁷ is a cyano group. At least one of R¹⁰² and R¹⁰⁷ is an alkyl group having 1 to 6 carbon atoms. The rest of R¹⁰¹ to R¹¹¹ are each independently hydrogen or a substituent.

The substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group. The substituents may be bonded to each other to form a ring.

n is an integer greater than or equal to 1 and less than or equal to 3. L is a ligand represented by Structural Formula (L0).

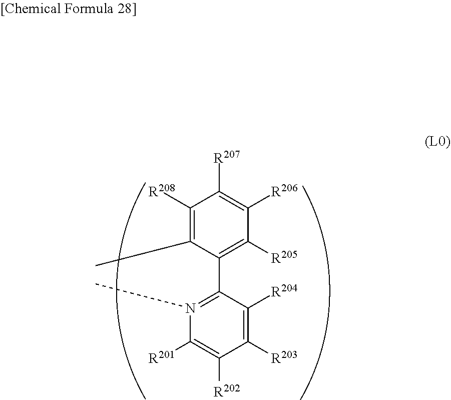

In Structural Formula (L0), R²⁰¹ to R²⁰⁸ are each independently hydrogen or an alkyl group having 1 to 6 carbon atoms. In General Formula (G0), any hydrogen may be deuterium.

Various types of the above compounds (Gpy0) and (L0) are commercially available or can be synthesized, and thus, a large number of types of the pyridine derivative represented by General Formula (G0) can be synthesized. Thus, the organometallic complex of one embodiment of the present invention is characterized by having numerous variations of ligands.

Note that this embodiment can be combined with any of the other embodiments described in this specification as appropriate.

### Embodiment 2

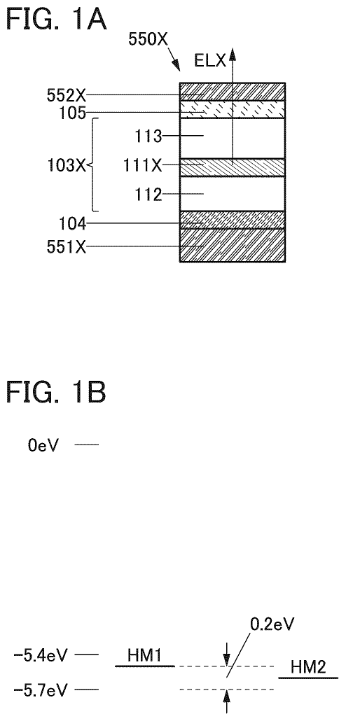

In this embodiment, a structure of a light-emitting device 550X of one embodiment of the present invention will be described with reference to FIG. 1A and FIG. 1B.

FIG. 1A is a cross-sectional view illustrating a structure of a light-emitting device of one embodiment of the present invention, and FIG. 1B is a diagram illustrating energy levels of materials used for the light-emitting device of one embodiment of the present invention.

### Structure Example of Light-Emitting Device 550X

The light-emitting device 550X described in this embodiment includes an electrode 551X, an electrode 552X, and a unit 103X. The electrode 552X overlaps with the electrode 551X, and the unit 103X is interposed between the electrode 552X and the electrode 551X.

### Structure Example of Unit 103X

The unit 103X has a single-layer structure or a stacked-layer structure. For example, the unit 103X includes a layer 111X, a layer 112, and a layer 113 (see FIG. 1A). The unit 103X has a function of emitting light ELX.

The layer 111X is interposed between the layer 113 and the layer 112, the layer 113 is interposed between the electrode 552X and the layer 111X, and the layer 112 is interposed between the layer 111X and the electrode 551X.

For example, a layer selected from layers having functions of a light-emitting layer, a hole-transport layer, an electron-transport layer, a carrier-blocking layer, and the like can be used in the unit 103X. Moreover, a layer selected from functional layers such as a hole-injection layer, an electron-injection layer, an exciton-blocking layer, and a charge-generation layer can be used in the unit 103X.

### Structure Example of Layer 112

For example, a hole-transport material can be used for the layer 112. The layer 112 can be referred to as a hole-transport layer. A material having a wider band gap than the light-emitting material contained in the layer 111X is preferably used for the layer 112. In that case, energy transfer from excitons generated in the layer 111X to the layer 112 can be inhibited.

### [Hole-Transport Material]

A material having a hole mobility higher than or equal to 1×10⁶ cm²/Vs can be suitably used as the hole-transport material.

As the hole-transport material, an amine compound or an organic compound having a π-electron rich heteroaromatic ring skeleton can be used, for example. Specifically, a compound having an aromatic amine skeleton, a compound having a carbazole skeleton, a compound having a thiophene skeleton, a compound having a furan skeleton, or the like can be used. The compound having an aromatic amine skeleton and the compound having a carbazole skeleton are particularly preferable because these compounds are highly reliable and have high hole-transport properties to contribute to a reduction in driving voltage.

As the compound having an aromatic amine skeleton, 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), 4,4′-bis(9,9′-spirobi[9H-fluoren]-2-y)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBiIBP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-91H-carbazol-3-yl)phenyl]-9,9′-spirobi[9H-fluoren]-2-amine (abbreviation: PCBASF) can be used, for example.

As the compound having a carbazole skeleton, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 9,9′-diphenyl-9H,9′H-3,3′-bicarbazole (abbreviation: PCCP) can be used, for example.

As the compound having a thiophene skeleton, 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9/1-fluoren-9-yl)phenyl]-6-phenyldibenzothiophene (abbreviation: DBTFLP-IV) can be used, for example.

As the compound having a furan skeleton, 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II) can be used, for example.

### Structure Example of Layer 113

An electron-transport material, a material having an anthracene skeleton, or a mixed material can be used for the layer 113, for example. The layer 113 can be referred to as an electron-transport layer. A material having a wider band gap than the light-emitting material contained in the layer 111X is preferably used for the layer 113. In that case, energy transfer from excitons generated in the layer 111X to the layer 113 can be inhibited.

### [Electron-Transport Material]

A material having an electron mobility higher than or equal to 1×10⁻⁷ cm²/Vs and lower than or equal to 5×10⁻⁵ cm²/Vs in a condition where the square root of the electric field strength [V/cm] is 600 can be suitably used as the electron-transport material. Thus, the electron-transport property in the electron-transport layer can be inhibited. Alternatively, the amount of electrons injected into the light-emitting layer can be controlled. Alternatively, the light-emitting layer can be prevented from having excess electrons.

For example, a metal complex or an organic compound having a π-electron deficient heteroaromatic ring skeleton can be used as the electron-transport material.

As a metal complex, bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ) can be used, for example.

As an organic compound having a n-electron deficient heteroaromatic ring skeleton, a heterocyclic compound having a polyazole skeleton, a heterocyclic compound having a diazine skeleton, a heterocyclic compound having a pyridine skeleton, or a heterocyclic compound having a triazine skeleton can be used, for example. In particular, the heterocyclic compound having a diazine skeleton or the heterocyclic compound having a pyridine skeleton has favorable reliability and thus is preferable. In addition, the heterocyclic compound having a diazine (pyrimidine or pyrazine) skeleton has a high electron-transport property to contribute to a reduction in driving voltage.

As a heterocyclic compound having a polyazole skeleton, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′, 2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II) can be used, for example.

As a heterocyclic compound having a diazine skeleton, 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), or 4,8-bis[3-(dibenzothiophen-4-yl)phenyl]benzo[h]quinazoline (abbreviation: 4,8mDBtP2Bqn) can be used, for example.

As a heterocyclic compound having a pyridine skeleton, 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB) can be used, for example.

As a heterocyclic compound having a triazine skeleton, 2-[3′-(9,9-dimethyl-9N-fluoren-2-yl)biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), or 2-{3-[3-(benzo[b]naphtho[1,2-d]furan-6-yl)phenyl]phenyl}-4,6-diphenyl-1,3,5-triazine (abbreviation: mBnf3PTzn-02) can be used, for example.

### [Material Having Anthracene Skeleton]

An organic compound having an anthracene skeleton can be used for the layer 113. In particular, an organic compound having both an anthracene skeleton and a heterocyclic skeleton can be suitably used.

For example, an organic compound having both an anthracene skeleton and a nitrogen-containing five-membered ring skeleton can be used for the layer 113. Alternatively, an organic compound having both an anthracene skeleton and a nitrogen-containing five-membered ring skeleton where two heteroatoms are included in a ring can be used for the layer 113. Specifically, a pyrazole ring, an imidazole ring, an oxazole ring, a thiazole ring, or the like can be favorably used as the heterocyclic skeleton.

For example, an organic compound having both an anthracene skeleton and a nitrogen-containing six-membered ring skeleton can be used for the layer 113. Alternatively, an organic compound having both an anthracene skeleton and a nitrogen-containing six-membered ring skeleton where two heteroatoms are included in a ring can be used for the layer 113. Specifically, a pyrazine ring, a pyrimidine ring, a pyridazine ring, or the like can be favorably used as the heterocyclic skeleton.

### [Structure Example of Mixed Material]

A material in which a plurality of kinds of substances are mixed can be used for the layer 113. Specifically, a mixed material that contains an electron-transport substance and any of an alkali metal, an alkali metal compound, and an alkali metal complex can be used for the layer 113. Note that it is further preferable that the highest occupied molecular orbital (HOMO) level of the electron-transport material be −6.0 eV or higher.

The concentration of the alkali metal, the alkali metal compound, or the alkali metal complex preferably differs in the thickness direction of the layer 113 (including the case where the concentration is 0).

For example, a metal complex having an 8-hydroxyquinolinato structure can be used. A methyl-substituted product of the metal complex having an 8-hydroxyquinolinato structure (e.g., a 2-methyl-substituted product or a 5-methyl-substituted product) or the like can also be used.

As the metal complex having an 8-hydroxyquinolinato structure, 8-hydroxyquinolinato-lithium (abbreviation: Liq), 8-hydroxyquinolinato-sodium (abbreviation: Naq), or the like can be used. In particular, a complex of a monovalent metal ion, especially a complex of lithium is preferable, and Liq is further preferable.

The mixed material can be suitably used for the layer 113 in combination with a structure using a composite material, which is separately described, for a layer 104. For example, a composite material of a substance having an electron-accepting property and a hole-transport material can be used for the layer 104. Specifically, a composite material of a substance having an electron-accepting property and a substance having a relatively deep HOMO level HM1, which is greater than or equal to −5.7 eV and less than or equal to −5.4 eV, can be used for the layer 104 (see FIG. 1B). By using the mixed material for the layer 113 in combination with a structure using such a composite material for the layer 104, the reliability of the light-emitting device can be increased.

Furthermore, a structure using a hole-transport material for the layer 112 is preferably combined with the structure using the mixed material for the layer 113 and the composite material for the layer 104. For example, a substance having a HOMO level HM2, which is within the range of −0.2 eV to 0 eV from the relatively deep HOMO level HM1, can be used for the layer 112 (see FIG. 1B). As a result, the reliability of the light-emitting device can be increased. Note that in this specification and the like, the structure of the above-described light-emitting device is referred to as a Recombination-Site Tailoring Injection structure (ReSTI structure) in some cases.

### Structure Example 1 of Layer 111X

A light-emitting material or a light-emitting material and a host material can be used for the layer 111X, for example. The layer 111X can be referred to as a light-emitting layer. The layer 111X is preferably provided in a region where holes and electrons are recombined. In that case, energy generated by recombination of carriers can be efficiently converted into light and emitted.

Furthermore, the layer 111X is preferably provided apart from a metal used for the electrode or the like. In that case, a quenching phenomenon caused by the metal used for the electrode or the like can be inhibited.

It is preferable that a distance from an electrode or the like having reflectivity to the layer 111X be adjusted and the layer 111X be placed in an appropriate position in accordance with an emission wavelength. Thus, the amplitude can be increased by utilizing an interference phenomenon between light reflected by the electrode or the like and light emitted from the layer 111X. Light with a predetermined wavelength can be intensified and the spectrum of the light can be narrowed. In addition, bright light emission colors with high intensity can be obtained. In other words, the layer 111X is placed in an appropriate position between electrodes or the like, and thus a microcavity structure (microcavity) can be formed.

For example, a phosphorescent substance can be used as the light-emitting material. Thus, energy generated by recombination of carriers can be released as the light ELX from the light-emitting material (see FIG. TA).

### [Phosphorescent Substance]

A phosphorescent substance can be used for the layer 111X. For example, the organic compound of one embodiment of the present invention described in Embodiment 1 can be used for the layer 111X.

For the layer 111X, {2-[5-(methyl-d3)-4-phenyl-2-pyridinyl-κN]phenyl-κC}bis[2-(2-pyridinyl-κN)phenyl-κC]iridium(III) (abbreviation: Ir(ppy)₂(5m4dppy-d3)), bis{2-[5-(methyl-d3)-4-phenyl-2-pyridinyl-κN]phenyl-κC}[2-(2-pyridinyl-κN)phenyl-κC]iridium(II) (abbreviation: Ir(5m4dppy-d3)₂(ppy)), or {2-[4-(3,5-di-tert-butylphenyl)-5-(methyl-d3)-2-pyridinyl-κN]phenyl-κC}bis{2-[4-(methyl-d3)-5-(2-methylpropyl-1,1-d2)-2-pyridinyl-κN]phenyl-κC}iridium(III) (abbreviation: Ir(5iBu4mppy-d5)₂(4mmtBup5mppy-d3)) can be used, for example.

The layer 111X includes the organic compound of one embodiment of the present invention. This inhibits free rotation of the phenyl group into which the cyano group is introduced, enabling an improvement in the thermophysical property of the compound, for example, inhibition of thermal decomposition and inhibition of decomposition due to high-temperature heating in a synthesis reaction; thus, the yield of synthesis can be improved. Moreover, the sublimation property can be improved without thermal decomposition in sublimation. Resistance to use in a high-temperature environment can be exhibited. Furthermore, the emission wavelength can be shortened by a twist generated between the phenyl group into which the cyano group is introduced and the phenylpyridine skeleton to which iridium coordinates. High emission efficiency can also be achieved. As a result, a novel light-emitting device that is highly convenient, useful, or reliable can be provided.

### Structure Example 2 of Layer 111X

A carrier-transport material can be used as the host material. For example, a hole-transport material, an electron-transport material, a substance exhibiting thermally activated delayed fluorescence (TADF), a material having an anthracene skeleton, or a mixed material of two or more selected from these materials can be used as the host material. A material having a wider band gap than the light-emitting material contained in the layer 111X is preferably used as the host material. Thus, energy transfer from excitons generated in the layer 111X to the host material can be inhibited.

### [Hole-Transport Material]

A material having a hole mobility higher than or equal to 1×10⁻⁶ cm²/Vs can be suitably used as the hole-transport material. For example, a hole-transport material that can be used for the layer 112 can be used as the host material.

### [Electron-Transport Material]

A metal complex or an organic compound having a n-electron deficient heteroaromatic ring skeleton can be used as the electron-transport material. For example, an electron-transport material that can be used for the layer 113 can be used as the host material.

### Structure Example 1 of Mixed Material

A material in which a plurality of kinds of substances are mixed can be used as the host material. For example, an electron-transport material and a hole-transport material can be used for the mixed material. The weight ratio between the hole-transport material and the electron-transport material contained in the mixed material is (the hole-transport material/the electron-transport material)=(1/19) or more and (19/1) or less. Accordingly, the carrier-transport property of the layer 111X can be easily adjusted. In addition, a recombination region can be controlled easily.

### Structure Example 2 of Mixed Material

The organic compound of one embodiment of the present invention can be used as the host material. The organic compound of one embodiment of the present invention is a phosphorescent substance; when a fluorescent substance is used as the light-emitting substance, a phosphorescent substance can be used as an energy donor for supplying excitation energy to the fluorescent substance.

Therefore, the emission spectrum of the organic compound of one embodiment of the present invention includes light with a wavelength shorter than 500 nm, so that when the organic compound is used with a fluorescent material having an absorption spectrum having a region overlapping with the emission spectrum, e.g., a green fluorescent material, energy can be efficiently transferred to the fluorescent material. A phenomenon in which the luminance of the light-emitting device decreases in use can be inhibited. In addition, the reliability of the light-emitting device can be increased. As a result, a novel light-emitting device that is highly convenient, useful, or reliable can be provided.

### Structure Example 3 of Mixed Material

A mixed material containing a material forming an exciplex can be used as the host material. For example, a material forming an exciplex whose emission spectrum overlaps with the wavelength of the absorption band on the lowest energy side of the light-emitting substance can be used as the host material. Specifically, a mixed material containing an electron-transport material and a hole-transport material can be used as the material forming an exciplex. This enables smooth energy transfer and improves emission efficiency. Alternatively, the driving voltage can be reduced. With such a structure, light emission can be efficiently obtained by ExTET (Exciplex-Triplet Energy Transfer), which is energy transfer from the exciplex to the light-emitting substance (phosphorescent material).

A phosphorescent substance can be used as at least one of the materials forming an exciplex. Accordingly, reverse intersystem crossing can be used. Triplet excitation energy can be efficiently converted into singlet excitation energy.

A combination of materials forming an exciplex is preferably such that the HOMO level of a hole-transport material is higher than or equal to the HOMO level of an electron-transport material. Alternatively, the lowest unoccupied molecular orbital (LUMO) level of the hole-transport material is preferably higher than or equal to the LUMO level of the electron-transport material. In that case, an exciplex can be efficiently formed. Note that the LUMO levels and the HOIMO levels of the materials can be derived from the electrochemical characteristics (the reduction potentials and the oxidation potentials). Specifically, the reduction potentials and the oxidation potentials can be measured by cyclic voltammetry (CV).

The formation of an exciplex can be confirmed by a phenomenon in which the emission spectrum of a mixed film in which the hole-transport material and the electron-transport material are mixed is shifted to a longer wavelength than the emission spectrum of each of the materials (or has another peak on the longer wavelength side) observed in comparison of the emission spectrum of the hole-transport material, the emission spectrum of the electron-transport material, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than the transient PL lifetime of each of the materials, observed in comparison of the transient PL of the hole-transport material, the transient PL of the electron-transport material, and the transient PL of the mixed film of these materials. The transient PL can be rephrased as transient electroluminescence (EL). That is, the formation of an exciplex can also be confirmed by a difference in transient response observed in comparison of the transient EL of the hole-transport material, the transient EL of the electron-transport material, and the transient EL of the mixed film of these materials.

Note that this embodiment can be combined with any of the other embodiments described in this specification as appropriate.

### Embodiment 3

In this embodiment, a structure of the light-emitting device 550X of one embodiment of the present invention is described with reference to FIG. 1A and FIG. 1B.

### <Structure Example of Light-Emitting Device 550X>

The light-emitting device 550X described in this embodiment includes the electrode 551X, the electrode 552X, the unit 103X, and the layer 104. The electrode 552X overlaps with the electrode 551X, and the unit 103X is interposed between the electrode 551X and the electrode 552X. The layer 104 is interposed between the electrode 551X and the unit 103X. For example, the structure described in Embodiment 2 can be employed for the unit 103X.

### <Structure example of electrode 551X>

For example, a conductive material can be used for the electrode 551X. Specifically, a single layer or stacked layers using a metal, an alloy, or a film containing a conductive compound can be used for the electrode 551X.

A film that efficiently reflects light can be used for the electrode 551X, for example. Specifically, an alloy containing silver, copper, and the like, an alloy containing silver, palladium, and the like, or a metal film of aluminum or the like can be used for the electrode 551X.

For example, a metal film that transmits part of light and reflects the other part of light can be used for the electrode 551X. Thus, a microcavity structure (microcavity) can be provided in the light-emitting device 550X. Alternatively, light with a predetermined wavelength can be extracted more efficiently than other light. Alternatively, light with a narrow spectral half-width can be extracted. Alternatively, light of a bright color can be extracted.

A film having a visible-light-transmitting property can be used for the electrode 551X, for example. Specifically, a single layer or stacked layers using a metal film, an alloy film, a conductive oxide film, or the like that is thin enough to transmit light can be used for the electrode 551X.

In particular, a material having a work function higher than or equal to 4.0 eV can be suitably used for the electrode 551X.

For example, a conductive oxide containing indium can be used. Specifically, indium oxide, indium oxide-tin oxide (abbreviation: ITO), indium oxide-tin oxide containing silicon or silicon oxide (abbreviation: ITSO), indium oxide-zinc oxide, indium oxide containing tungsten oxide and zinc oxide (abbreviation: IWZO), or the like can be used.

For another example, a conductive oxide containing zinc can be used. Specifically, zinc oxide, zinc oxide to which gallium is added, zinc oxide to which aluminum is added, or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), or a nitride of a metal material (e.g., titanium nitride) can be used. Graphene can also be used.

### Structure Example 1 of Layer 104

A hole-injection material can be used for the layer 104, for example. The layer 104 can be referred to as a hole-injection layer.

For example, a material having a hole mobility lower than or equal to 1×10⁻³ cm/Vs when the square root of the electric field strength V/cm is 600 can be used for the layer 104. A film having an electrical resistivity greater than or equal to 1×10⁴ Ω·cm and less than or equal to 1×10⁷ Ω·cm can be used as the layer 104. The electrical resistivity of the layer 104 is preferably greater than or equal to 5×10⁴ Ω·cm and less than or equal to 1×10⁷ Ω·cm, further preferably greater than or equal to 1×10⁵ Ω·cm and less than or equal to 1×10⁷ Ω·cm.

### Structure Example 2 of Layer 104

Specifically, an electron-accepting substance can be used for the layer 104. Alternatively, a composite material containing a plurality of kinds of substances can be used for the layer 104. This can facilitate the injection of holes from the electrode 551X, for example. Alternatively, the driving voltage of the light-emitting device 550X can be reduced.

### [Electron-Accepting Substance]

An organic compound or an inorganic compound can be used as the electron-accepting substance. The electron-accepting substance can extract electrons from an adjacent hole-transport layer or a hole-transport material by the application of an electric field.

For example, a compound having an electron-withdrawing group (a halogen group or a cyano group) can be used as the electron-accepting substance. Note that an electron-accepting organic compound is easily evaporated, which facilitates film formation. Thus, the productivity of the light-emitting device 550X can be increased.

Specifically, 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), 2-(7-dicyanomethylen-1,3,4,5,6,8,9,10-octafluoro-7H-pyren-2-ylidene)malononitrile, or the like can be used.

A compound in which electron-withdrawing groups are bonded to a condensed aromatic ring having a plurality of heteroatoms, such as HAT-CN, is particularly preferable because it is thermally stable.

A [3]radialene derivative having an electron-withdrawing group (in particular, a cyano group or a halogen group such as a fluoro group) has a very high electron-accepting property and thus is preferred.

Specifically, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], α,α′,α″-1,2,3-cyclopropanetriylidenetris[2,3,4,5,6-pentafluorobenzeneacetonitrile], or the like can be used.

For the electron-accepting substance, a transition metal oxide such as a molybdenum oxide, a vanadium oxide, a ruthenium oxide, a tungsten oxide, or a manganese oxide can be used.

It is possible to use phthalocyanine (abbreviation: H2Pc), a phthalocyanine-based compound or complex compound such as copper phthalocyanine (abbreviation: CuPc), or a compound having an aromatic amine skeleton such as 4,4′-bis[N-(4-diphenylaminophenyl)-N-phenylamino]biphenyl (abbreviation: DPAB) or N,N′-bis[4-bis(3-methylphenyl)aminophenyl]-N,N′-diphenyl-4,4′-diaminobiphenyl (abbreviation: DNTPD).

In addition, high molecular compounds such as poly(3,4-ethylenedioxythiophene)/poly(styrenesulfonic acid) (PEDOT/PSS), and the like can be used.

### Structure Example 1 of Composite Material

For example, a composite material containing an electron-accepting substance and a hole-transport material can be used for the layer 104. Accordingly, not only a material having a high work function but also a material having a low work function can be used for the electrode 551X. Alternatively, a material used for the electrode 551X can be selected from a wide range of materials regardless of its work function.

For the hole-transport material in the composite material, for example, a compound having an aromatic amine skeleton, a carbazole derivative, an aromatic hydrocarbon, an aromatic hydrocarbon having a vinyl group, or a high molecular compound (such as an oligomer, a dendrimer, or a polymer) can be used. A material having a hole mobility higher than or equal to 1×10⁻⁶ cm²/Vs can be suitably used as the hole-transport material in the composite material. For example, a hole-transport material that can be used for the layer 112 can be used for the mixed material.

A substance having a relatively deep HOMO level can be suitably used for the hole-transport material in the composite material. Specifically, the HOMO level is preferably higher than or equal to −5.7 eV and lower than or equal to −5.4 eV. Accordingly, hole injection to the unit 103X can be facilitated. Hole injection to the layer 112 can be facilitated. The reliability of the light-emitting device 550X can be increased.

As the compound having an aromatic amine skeleton, for example, N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N-bis[4-bis(3-methylphenyl)aminophenyl]-N,N-diphenyl-4,4′-diaminobiphenyl (abbreviation: DNTPD), or 1,3,5-tris[N-(4-diphenylaminophenyl)-N-phenylamino]benzene (abbreviation: DPA3B) can be used.

As the carbazole derivative, for example, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), or 1,4-bis[4-(N-carbazolyl)phenyl]-2,3,5,6-tetraphenylbenzene can be used.

As the aromatic hydrocarbon, for example, 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, or coronene can be used.

As the aromatic hydrocarbon having a vinyl group, for example, 4,4′-bis(2,2-diphenylvinyl)biphenyl (abbreviation: DPVBi) or 9,10-bis[4-(2,2-diphenylvinyl)phenyl]anthracene (abbreviation: DPVPA) can be used.

As the high molecular compound, for example, poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide](abbreviation: PTPDMA), or poly[N,N′-bis(4-butylphenyl)-N,N′-bis(phenyl)benzidine](abbreviation: Poly-TPD) can be used.

Furthermore, a substance having any of a carbazole skeleton, a dibenzofuran skeleton, a dibenzothiophene skeleton, and an anthracene skeleton can be suitably used as the hole-transport material in the composite material, for example. Moreover, a substance including any of an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group can be used as the hole-transport material in the composite material. With use of a substance having an N,N-bis(4-biphenyl)amino group, the reliability of the light-emitting device 550X can be increased.

Examples of the above-described materials include N-(4-biphenyl)-6, N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBAIBP), 4-(2-naphthyl)-4′, 4″-diphenyltriphenylamine (abbreviation: BBAβNB), 4-[4-(2-naphthyl)phenyl]-4′, 4″-diphenyltriphenylamine (abbreviation: BBAβNBi), 4,4′-diphenyl-4″-(6;1′-binaphthyl-2-yl)triphenylamine (abbreviation: BBAαβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βNα)B), 4,4′-diphenyl-4″-(7;2′-binaphthyl-2-yl)triphenylamine (abbreviation: BBAβNα)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1B), 4,4′-bis(1-naphthyl)triphenylamine (abbreviation: αNBBIBP), 4,4′-diphenyl-4″-[4′-(carbazol-9-yl)biphenyl-4-yl]triphenylamine (abbreviation: YGTBiIBP), 4′-[4-(3-phenyl-911-carbazol-9-yl)phenyl]tris(1,1′-biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[91-fluoren]-2-amine (abbreviation: PCBNBSF), N,N-bis([1,1′-biphenyl]-4-yl)-9,9′-spirobi[9H-fluoren]-2-amine (abbreviation: BBASF), N,N-bis([1,1′-biphenyl]-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-91-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBAlBP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), A-phenyl-N-[4-(9-phenyl-9H-carbazol-3-yl)phenyl]-9,9′-spirobi[911-fluoren]-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9/1-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

### Structure Example 2 of Composite Material

For example, a composite material containing an electron-accepting substance, a hole-transport material, and a fluoride of an alkali metal or a fluoride of an alkaline earth metal can be used as the hole-injection material. In particular, a composite material in which the proportion of fluorine atoms is higher than or equal to 20% can be suitably used. Thus, the refractive index of the layer 104 can be reduced. A layer with a low refractive index can be formed inside the light-emitting device 550X. Alternatively, the external quantum efficiency of the light-emitting device 550X can be improved.

Note that this embodiment can be combined with any of the other embodiments described in this specification as appropriate.

### Embodiment 4

In this embodiment, a structure of the light-emitting device 550X of one embodiment of the present invention is described with reference to FIG. 1A and FIG. 1B.

### <Structure Example of Light-Emitting Device 550X>

The light-emitting device 550X described in this embodiment includes the electrode 551X, the electrode 552X, the unit 103X, and a layer 105. The electrode 552X includes a region overlapping with the electrode 551X, and the unit 103X includes a region interposed between the electrode 551X and the electrode 552X. The layer 105 includes a region interposed between the unit 103X and the electrode 552X. For example, the structure described in Embodiment 2 can be employed for the unit 103X.

### <Structure Example of Electrode 552X>

For example, a conductive material can be used for the electrode 552X. Specifically, a single layer or stacked layers using a metal, an alloy, or a material containing a conductive compound can be used for the electrode 552X.

For example, the material that can be used for the electrode 551X described in Embodiment 3 can be used for the electrode 552X. In particular, a material with a lower work function than the electrode 551X can be suitably used for the electrode 552X. Specifically, a material having a work function lower than or equal to 3.8 eV is preferable.

For example, an element belonging to Group 1 of the periodic table, an element belonging to Group 2 of the periodic table, a rare earth metal, or an alloy containing any of these can be used for the electrode 552X.

Specifically, lithium (L1), cesium (Cs), or the like; magnesium (Mg), calcium (Ca), strontium (Sr), or the like; europium (Eu), ytterbium (Yb), or the like; or an alloy containing any of these such as an alloy of magnesium and silver or an alloy of aluminum and lithium can be used for the electrode 552X.

### Structure Example of Layer 105

An electron-injection material can be used for the layer 105, for example. The layer 105 can be referred to as an electron-injection layer.

Specifically, an electron-donating substance can be used for the layer 105. Alternatively, a material in which an electron-donating substance and an electron-transport material are combined can be used for the layer 105. Alternatively, electrode can be used for the layer 105. This can facilitate the injection of electrons from the electrode 552X, for example. Alternatively, not only a material having a low work function but also a material having a high work function can be used for the electrode 552X. Alternatively, a material used for the electrode 552X can be selected from a wide range of materials regardless of its work function. Specifically, Al, Ag, ITO, indium oxide-tin oxide containing silicon or silicon oxide, or the like can be used for the electrode 552X. The driving voltage of the light-emitting device 550X can be reduced.

### [Electron-Donating Substance]

For example, an alkali metal, an alkaline earth metal, a rare earth metal, or a compound thereof (an oxide, a halide, a carbonate, or the like) can be used for the electron-donating substance. Alternatively, an organic compound such as tetrathianaphthacene (abbreviation: TTN), nickelocene, or decamethylnickelocene can be used as the electron-donating substance.

As an alkali metal compound (including an oxide, a halide, and a carbonate), lithium oxide, lithium fluoride (LiF), cesium fluoride (CsF), lithium carbonate, cesium carbonate, 8-hydroxyquinolinato-lithium (abbreviation: Liq), or the like can be used.

As an alkaline earth metal compound (including an oxide, a halide, and a carbonate), calcium fluoride (CaF₂) or the like can be used.

### Structure Example 1 of Composite Material

A material composed of a plurality of kinds of substances can be used as the electron-injection material. For example, an electron-donating substance and an electron-transport material can be used for the composite material.

### [Electron-Transport Material]

A material having an electron mobility higher than or equal to 1×10⁻⁷ cm²/Vs and lower than or equal to 5×10⁻⁵ cm²/Vs in a condition where the square root of the electric field strength V/cm is 600 can be suitably used as the electron-transport material. Thus, the amount of electrons injected into the light-emitting layer can be controlled. Alternatively, the light-emitting layer can be prevented from having excess electrons.

A metal complex or an organic compound having a π-electron deficient heteroaromatic ring skeleton can be used as the electron-transport material. For example, an electron-transport material that can be used for the layer 113 can be used as the composite material.

### Structure Example 2 of Composite Material

A material including a fluoride of an alkali metal in a microcrystalline state and an electron-transport material can be used for the composite material. Alternatively, a material including a fluoride of an alkaline earth metal in a microcrystalline state and an electron-transport material can be used for the composite material. In particular, a composite material containing a fluoride of an alkali metal or an alkaline earth metal at 50 wt % or higher can be suitably used. Alternatively, a composite material containing an organic compound having a bipyridine skeleton can be suitably used. Thus, the refractive index of the layer 105 can be reduced. Alternatively, the external quantum efficiency of the light-emitting device 550X can be improved.

### Structure Example 3 of Composite Material

For example, a composite material containing a first organic compound including an unshared electron pair and a first metal can be used for the layer 105. The sum of the number of electrons of the first organic compound and the number of electrons of the first metal is preferably an odd number. The molar ratio of the first metal to 1 mol of the first organic compound is preferably greater than or equal to 0.1 and less than or equal to 10, further preferably greater than or equal to 0.2 and less than or equal to 2, still further preferably greater than or equal to 0.2 and less than or equal to 0.8.

Accordingly, the first organic compound including an unshared electron pair interacts with the first metal and thus can form a singly occupied molecular orbital (SOMO). Furthermore, in the case where electrons are injected from the electrode 552X into the layer 105, a barrier therebetween can be reduced.

The layer 105 can adopt a composite material that allows the spin density measured by an electron spin resonance method (ESR) to be preferably greater than or equal to 1×10¹⁶ spins/cm³, further preferably greater than or equal to 5×10¹⁶ spins/cm³, still further preferably greater than or equal to 1×10¹⁷ spins/cm³.

### [Organic Compound Including Unshared Electron Pair]

For example, an electron-transport material can be used for the organic compound including an unshared electron pair. For example, a compound having an electron deficient heteroaromatic ring can be used. Specifically, a compound with at least one of a pyridine ring, a diazine ring (a pyrimidine ring, a pyrazine ring, and a pyridazine ring), and a triazine ring can be used. Accordingly, the driving voltage of the light-emitting device 550X can be reduced.

Note that the lowest unoccupied molecular orbital (LUMO) level of the organic compound including an unshared electron pair is preferably higher than or equal to −3.6 eV and lower than or equal to −2.3 eV. In general, the HOMO level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(2-naphthyl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), 2,2′-(1,3-phenylene)bis(9-phenyl-1,10-phenanthroline) (abbreviation: mPPhen2P), or the like can be used as the organic compound including an unshared electron pair. Note that NBPhen has a higher glass transition temperature (Tg) than BPhen and thus has high heat resistance.

Alternatively, for example, copper phthalocyanine can be used for the organic compound including an unshared electron pair. The number of electrons of the copper phthalocyanine is an odd number.

### [First Metal]

When the number of electrons of the first organic compound including an unshared electron pair is an even number, for example, a composite material of a metal belonging to an odd-numbered group in the periodic table and the first organic compound can be used for the layer 105.

For example, manganese (Mn), which is a metal belonging to Group 7, cobalt (Co), which is a metal belonging to Group 9, copper (Cu), silver (Ag), and gold (Au), which are metals belonging to Group 11, aluminum (Al) and indium (In), which are metals belonging to Group 13 are elements belonging to odd-numbered groups in the periodic table. Note that elements belonging to Group 11 have a lower melting point than elements belonging to Group 7 or Group 9 and thus are suitable for vacuum evaporation. In particular, Ag is preferable because of its low melting point. By using a metal having a low reactivity with water or oxygen as the first metal, the moisture resistance of the light-emitting device 550X can be improved.

The use of Ag for the electrode 552X and the layer 105 can increase the adhesion between the layer 105 and the electrode 552X.

When the number of electrons of the first organic compound including an unshared electron pair is an odd number, a composite material of the first metal belonging to an even-numbered group in the periodic table and the first organic compound can be used for the layer 105. For example, iron (Fe), which is a metal belonging to Group 8, is an element belonging to an even-numbered group in the periodic table.

### [Electride]

For example, a substance obtained by adding electrons at high concentration to an oxide in which calcium and aluminum are mixed can be used, for example, as the electron-injection material.

Note that this embodiment can be combined with any of the other embodiments described in this specification as appropriate.

### Embodiment 5

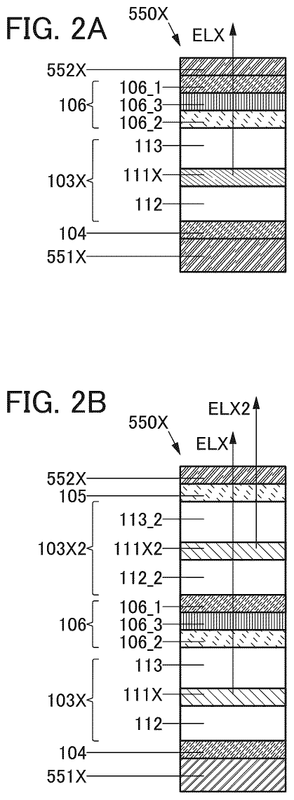

In this embodiment, a structure of the light-emitting device 550X of one embodiment of the present invention is described with reference to FIG. 2A.

FIG. 2A is a cross-sectional view illustrating a structure of a light-emitting device of one embodiment of the present invention.

### <Structure Example of Light-Emitting Device 550X>

The light-emitting device 550X described in this embodiment includes the electrode 551X, the electrode 552X, the unit 103X, and a layer 106 (see FIG. 2A). The electrode 552X includes a region overlapping with the electrode 551X, and the unit 103X includes a region interposed between the electrode 551X and the electrode 552X. The layer 106 includes a region interposed between the electrode 552X and the unit 103X.

### Structure Example 1 of Layer 106

The layer 106 has a function of supplying electrons to the anode side and supplying holes to the cathode side when voltage is applied. The layer 106 can be referred to as a charge-generation layer.

For example, a hole-injection material that can be used for the layer 104 described in Embodiment 3 can be used for the layer 106. Specifically, a composite material can be used for the layer 106.

Alternatively, for example, a stacked film in which a film including the composite material and a film including a hole-transport material are stacked can be used for the layer 106. Note that the film including a hole-transport material is interposed between the film including the composite material and the cathode.

### Structure Example 2 of Layer 106

A stacked film in which a layer 106_1 and a layer 106_2 are stacked can be used for the layer 106. The layer 106_1 includes a region interposed between the unit 103X and the electrode 552X, and the layer 106_2 includes a region interposed between the unit 103X and the layer 106_1.

### Structure Example of Layer 106_1

For example, a hole-injection material that can be used for the layer 104 described in Embodiment 3 can be used for the layer 106_1. Specifically, a composite material can be used for the layer 106_1. A film having an electrical resistivity greater than or equal to 1×10⁴ [Ω·cm] and less than or equal to 1×10⁷ [Ω·cm] can be used as the layer 106_1. The electrical resistivity of the layer 106_1 is preferably greater than or equal to 5×10⁴ [Ω·cm] and less than or equal to 1×10⁷ [Ω·cm], further preferably greater than or equal to 1×10⁵ [Ω·cm] and less than or equal to 1×10⁷ [Ω·cm].

### Structure Example of Layer 106_2

For example, a material that can be used for the layer 105 described in Embodiment 4 can be used for the layer 106_2.

### Structure Example 3 of Layer 106

A stacked film in which the layer 106_1, the layer 106_2, and a layer 106_3 are stacked can be used for the layer 106. The layer 106_3 includes a region interposed between the layer 106_1 and the layer 106_2.

### Structure Example of Layer 106_3

For example, an electron-transport material can be used for the layer 106_3. The layer 106_3 can be referred to as an electron-relay layer. With the layer 106_3, a layer in contact with the anode side of the layer 106_3 can be distanced from a layer in contact with the cathode side of the layer 1063. Interaction between the layer in contact with the anode side of the layer 106_3 and the layer in contact with the cathode side of the layer 106_3 can be reduced. Electrons can be smoothly supplied to the layer in contact with the anode side of the layer 106_3.

A substance whose LUMO level is positioned between the LUMO level of the electron-accepting substance contained in the layer in contact with the cathode side of the layer 106_3 and the LUMO level of the substance contained in the layer in contact with the anode side of the layer 106_3 can be suitably used for the layer 106_3.

For example, a material having a LUMO level in a range higher than or equal to −5.0 eV, preferably higher than or equal to −5.0 eV and lower than or equal to −3.0 eV, can be used for the layer 106_3.

Specifically, a phthalocyanine-based material can be used for the layer 106_3. For example, copper phthalocyanine (abbreviation: CuPc) or a metal complex having a metal-oxygen bond and an aromatic ligand can be used for the layer 106_3.

Note that this embodiment can be combined with any of the other embodiments described in this specification as appropriate.

### Embodiment 6

In this embodiment, a structure of the light-emitting device 550X of one embodiment of the present invention is described with reference to FIG. 2B.

FIG. 2B is a cross-sectional view illustrating a structure of a light-emitting device of one embodiment of the present invention, whose structure is different from the structure illustrated in FIG. 2A.

### <Structure Example of Light-Emitting Device 550X>

The light-emitting device 550X described in this embodiment includes the electrode 551X, the electrode 552X, the unit 103X, the layer 106, and a unit 103X2 (see FIG. 2B).

The unit 103X is interposed between the electrode 552X and the electrode 551X, and the layer 106 is interposed between the electrode 552X and the unit 103X.

The unit 103X2 is interposed between the electrode 552X and the layer 106. The unit 103X2 has a function of emitting light ELX2.

In other words, the light-emitting device 550X includes the stacked units between the electrode 551X and the electrode 552X. The number of stacked units is not limited to two, and three or more units can be stacked. A structure including the stacked units interposed between the electrode 551X and the electrode 552X and the layer 106 interposed between the units is referred to as a stacked light-emitting device or a tandem light-emitting device in some cases.

This structure enables high luminance emission while the current density is kept low. Alternatively, reliability can be improved. Alternatively, the driving voltage can be reduced as compared to other structures with the same luminance. Alternatively, the power consumption can be reduced.

### Structure Example 1 of Unit 103X2

The unit 103X2 includes a layer 111X2, a layer 1122, and a layer 113_2. The layer 111X2 is interposed between the layer 112_2 and the layer 113_2.

The structure that can be employed for the unit 103X can be employed for the unit 103X2. For example, the same structure as the unit 103X can be employed for the unit 103X2.

### Structure Example 2 of Unit 103X2

The structure different from that of the unit 103X can be employed for the unit 103X2. For example, the unit 103X2 can have a structure emitting light whose hue is different from that of light emitted from the unit 103X.

Specifically, a stack including the unit 103X emitting red light and green light and the unit 103X2 emitting blue light can be employed. With this structure, a light-emitting device emitting light of a desired color can be provided. A light-emitting device emitting white light can be provided, for example.

### Structure Example of Layer 106

The layer 106 has a function of supplying electrons to one of the unit 103X and the unit 103X2 and supplying holes to the other. For example, the layer 106 described in Embodiment 5 can be used.

### <Fabrication Method of Light-Emitting Device 550X>

For example, each of the electrode 551X, the electrode 552X, the unit 103X, the layer 106, and the unit 103X2 can be formed by a dry process, a wet process, an evaporation method, a droplet discharging method, a coating method, a printing method, or the like. Different methods can be employed to form the components.

Specifically, the light-emitting device 550X can be manufactured with a vacuum evaporation apparatus, an inkjet apparatus, a coating apparatus such as a spin coater, a gravure printing apparatus, an offset printing apparatus, a screen printing apparatus, or the like.

For example, the electrode can be formed by a wet process or a sol-gel method using a paste of a metal material. In addition, an indium oxide-zinc oxide film can be formed by a sputtering method using a target obtained by adding, to indium oxide, zinc oxide at higher than or equal to 1 wt % and lower than or equal to 20 wt %. Furthermore, an indium oxide film containing tungsten oxide and zinc oxide (IWZO) can be formed by a sputtering method using a target containing, with respect to indium oxide, tungsten oxide at higher than or equal to 0.5 wt % and lower than or equal to 5 wt % and zinc oxide at higher than or equal to 0.1 wt % and lower than or equal to 1 wt %.

Note that this embodiment can be combined with any of the other embodiments described in this specification as appropriate.

### Embodiment 7

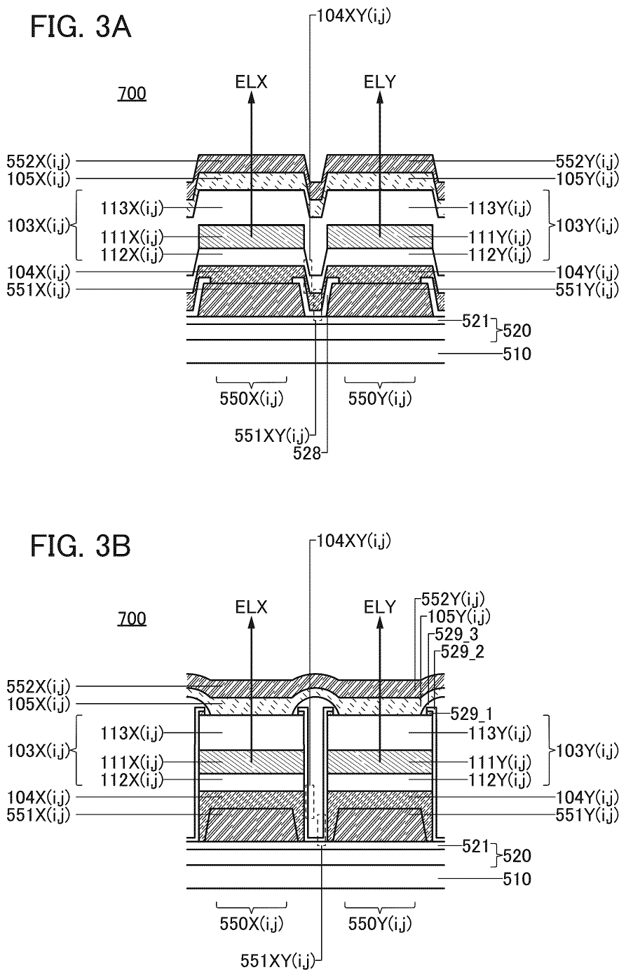

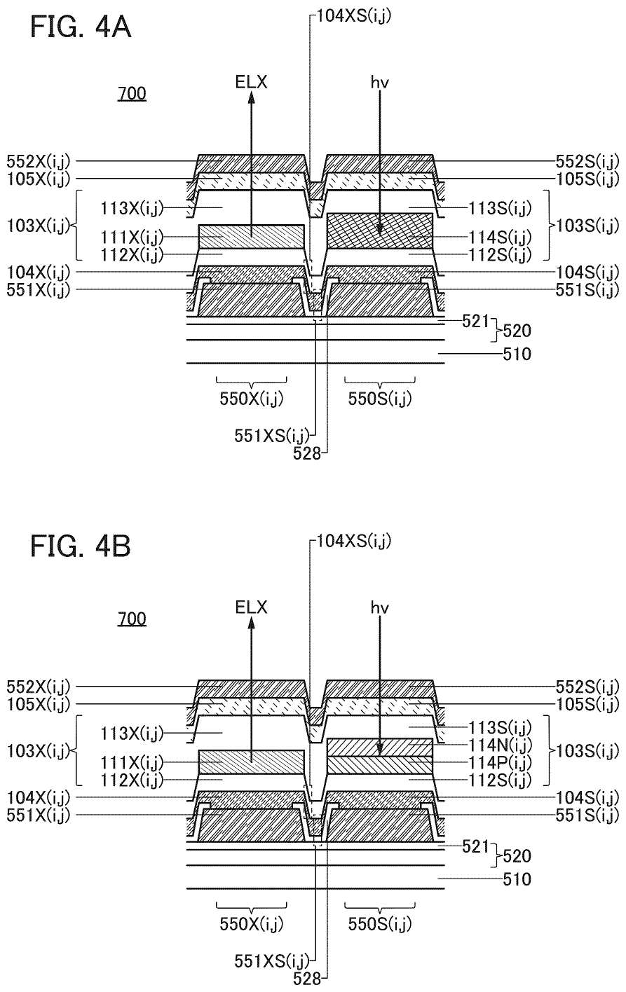

In this embodiment, structures of a display apparatus 700 of one embodiment of the present invention will be described with reference to FIG. 3A and FIG. 3B.

FIG. 3A is a cross-sectional view illustrating a structure of the display apparatus 700 of one embodiment of the present invention, and FIG. 3B is a cross-sectional view illustrating a structure of the display apparatus 700 of one embodiment of the present invention, which is different from the structure in FIG. 3A.

In this specification, an integer variable of 1 or more may be used for reference numerals. For example, (p) where p is an integer variable of 1 or more may be used for part of a reference numeral that specifies any one of up top components. For another example, (m,n) where each of m and n is an integer variable of 1 or more may be used for part of a reference numeral that specifies any one of up to m×n components.

### Structure Example 1 of Display Apparatus 700

The display apparatus 700 described in this embodiment includes a light-emitting device 550X(i,j) and a light-emitting device 550Y(i,j) (see FIG. 3A). The light-emitting device 550Y(i,j) is adjacent to the light-emitting device 550X(i,j).

Note that the display apparatus 700 includes a substrate 510 and a functional layer 520. The functional layer 520 includes an insulating film 521, and the light-emitting device 550X(i,j) and the light-emitting device 550Y(i,j) are formed over the insulating film 521. The functional layer 520 is interposed between the substrate 510 and the light-emitting devices 550X(i,j) and 550Y(i,j).

### <Structure Example of Light-Emitting Device 550X(i,j)

The light-emitting device 550X(i,j) includes an electrode 551X(i,j), an electrode 552X(i,j), and a unit 103X(i,j). The electrode 552X(i,j) overlaps with the electrode 551X(i,j), and the unit 103X(i,j) is interposed between the electrode 552X(i,j) and the electrode 551X(i,j). The light-emitting device 550X(i,j) includes a layer 104X(i,j) and a layer 105X(i,j). The layer 104X(i,j) is interposed between the unit 103X(i,j) and the electrode 551X(i,j), and the layer 105X(i,j) is interposed between the electrode 552X(i,j) and the unit 103X(i,j). Note that the unit 103X(i,j) includes a layer 111X(i,j), a layer 112X(i,j), and a layer 113X(i,j).

For example, the light-emitting device 550X described in Embodiment 2 to Embodiment 6 can be used as the light-emitting device 550X(i,j). Specifically, a structure that can be employed for the electrode 551X can be employed for the electrode 551X(i,j), and a structure that can be employed for the electrode 552X can be employed for the electrode 552X(i,j). A structure that can be employed for the unit 103X can be employed for the unit 103X(i,j). A structure that can be employed for the layer 104 can be employed for the layer 104X(i,j), and a structure that can be employed for the layer 105 can be employed for the layer 105X(i,j). A structure that can be employed for the layer 111X can be employed for the layer 111X(i,j), a structure that can be employed for the layer 112 can be employed for the layer 112X(i,j), and a structure that can be employed for the layer 113 can be employed for the layer 113X(i,j).

### Structure Example of Light-Emitting Device 550Y(i,j)

The light-emitting device 550Y(i,j) includes an electrode 551Y(i,j), an electrode 552Y(i,j), and a unit 103Y(i,j). The electrode 552Y(i,j) overlaps with the electrode 551Y(i,j), and the unit 103Y(i,j) is interposed between the electrode 552Y(i,j) and the electrode 551Y(i,j). The light-emitting device 550Y(i,j) includes a layer 104Y(i,j) and a layer 105Y(i,j). The layer 104Y(i,j) is interposed between the unit 103Y(i,j) and the electrode 551Y(i,j), and the layer 105Y(i,j) is interposed between the electrode 552Y(i,j) and the unit 103Y(i,j).

The electrode 551Y(i,j) is adjacent to the electrode 551X(i,j), and a space 551XY(i,j) is provided between the electrode 551X(i,j) and the electrode 551Y(i,j).

Note that part of a structure that can be employed as a structure of the light-emitting device 550X(i,j) can be employed as a structure of the light-emitting device 550Y(i,j). For example, part of a conductive film that can be used for the electrode 552X(i,j) can be used for the electrode 552Y(i,j). A structure that can be employed for the electrode 551X can be employed for the electrode 551Y(i,j). A structure that can be employed for the layer 104 can be employed for the layer 104Y(i,j), and a structure that can be employed for the layer 105 can be employed for the layer 105Y(i,j). Thus, some of the components can be used in common. In addition, the manufacturing process can be simplified.

Moreover, the light-emitting device 550Y(i,j) can have a structure emitting light whose hue is the same as that of light emitted from the light-emitting device 550X(i,j).

For example, both the light-emitting device 550X(i,j) and the light-emitting device 550Y(i,j) may emit white light. A coloring layer is provided to overlap with the light-emitting device 550X(i,j), whereby light of a predetermined hue can be extracted from white light. Another coloring layer is provided to overlap with the light-emitting device 550Y(i,j), whereby light of another predetermined hue can be extracted from white light.

For example, both the light-emitting device 550X(i,j) and the light-emitting device 550Y(i,j) may emit blue light. A color conversion layer is provided to overlap with the light-emitting device 550X(i,j), whereby blue light can be converted into light of a predetermined hue. Another color conversion layer is provided to overlap with the light-emitting device 550Y(i,j), whereby blue light can be converted into light of another predetermined hue. Blue light can be converted into green light or red light, for example.

Moreover, the light-emitting device 550Y(i,j) can have a structure emitting light whose hue is different from that of light emitted from the light-emitting device 550X(i,j). For example, the hue of light ELY emitted from the unit 103Y(i,j) can be differentiated from the hue of the light ELX.

### Structure Example of Unit 103Y(i,j)

The light-emitting device 550Y(i,j) is different from the light-emitting device 550X(i,j) in the structure of a layer 111Y(i,j). Different portions are described in detail here, and the above description is referred to for portions having the same structure as the above.

### Structure example of layer 111Y(i,j)

A light-emitting material or a light-emitting material and a host material can be used for the layer 111Y(i,j), for example. The layer 111Y(i,j) can be referred to as a light-emitting layer. The layer 111Y(i,j) is preferably provided in a region where holes and electrons are recombined. In that case, energy generated by recombination of carriers can be efficiently converted into light and emitted.

Furthermore, the layer 111Y(i,j) is preferably provided apart from a metal used for the electrode or the like. In that case, a quenching phenomenon caused by the metal used for the electrode or the like can be inhibited.

It is preferable that a distance from an electrode or the like having reflectivity to the layer 111Y(i,j) be adjusted and the layer 111Y(i,j) be placed in an appropriate position in accordance with an emission wavelength. Thus, the amplitude can be increased by utilizing an interference phenomenon between light reflected by the electrode or the like and light emitted from the layer 111Y(i,j). Light with a predetermined wavelength can be intensified and the spectrum of the light can be narrowed. In addition, bright light emission colors with high intensity can be obtained. In other words, the layer 111Y(i,j) is placed in an appropriate position between electrodes or the like, and thus a microcavity structure (microcavity) can be formed.

For example, a fluorescent substance, a phosphorescent substance, or a substance exhibiting thermally activated delayed fluorescence (TADF) (also referred to as a TADF material) can be used as the light-emitting material. Thus, energy generated by recombination of carriers can be released as the light ELY from the light-emitting material (see FIG. 3A and FIG. 3B).

[Fluorescent substance]A fluorescent substance can be used for the layer 111Y(i,j). For example, fluorescent substances described below as examples can be used for the layer 111Y(i,j). Note that without limitation to the following, any of a variety of known fluorescent substances can be used for the layer 111Y(i,j).

Specifically, 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-91-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA25), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis[N,N′,N″-triphenyl-1,4-phenylenediamine](abbreviation: DPABPA), N,9-diphenyl-N-[4-(9,10-diphenyl-2-anthryl)phenyl]-91-carbazol-3-amine (abbreviation: 2PCAPPA), N,N-(pyrene-1,6-diyl)bis[(6,N-diphenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), 3,10-bis[N-(dibenzofuran-3-yl)-N-phenylamino]naphtho[2,3-b;6,7-b′]bisbenzofuran (abbreviation: 3,10FrA2Nbf(IV)-02), or the like can be used.

Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

Moreover, N-[4-(9,10-diphenyl-2-antbryl)phenyl]-N,N′,N″-triphenyl-1,4-phenylenediamine (abbreviation: 2DPAPPA), N,N,N′,N″,N′″,N″″,N′″″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N,N′-triphenyl-1,4-phenylenediamine (abbreviation: 2DPAPA), N-[9,10-bis(1,1′-biphenyl-2-yl)-2-anthryl]-N,N,N-triphenyl-1,4-phenylenediamine (abbreviation: 2DPABPhA), 9,10-bis(1,1′-biphenyl-2-yl)-N-[4-(9H1-carbazol-9-yl)phenyl]-N-phenylanthracene-2-amine (abbreviation: 2YGABPhA), N,N,9-triphenylanthracene-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), or the like can be used.

Furthermore, 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,511-benzo[i,j]quinolizin-9-yl)ethenyl]-4H-pyran-4-ylidene}propanedinitrile (abbreviation: DCM2), N,N,N′,N″-tetrakis(4-methylphenyl)tetracene-5,11-diamine (abbreviation: p-mPhTD), 7,14-diphenyl-N,N,N,N-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-41-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-11,5H-benzo[ij]quinolizin-9-yl)ethenyl]-41-pyran-4-ylidene}propanedinitrile (abbreviation: BisDCJTM), or the like can be used.

### [Phosphorescent Substance]

A phosphorescent substance can be used for the layer 111Y(i,j). For example, phosphorescent substances described below as examples can be used for the layer 111Y(i,j). Note that without limitation to the following, any of a variety of known phosphorescent substances can be used for the layer 111Y(i,j).

For example, the layer 111Y(i,j) can include an organometallic iridium complex having a 4H-triazole skeleton, an organometallic iridium complex having a 1H-triazole skeleton, an organometallic iridium complex having an imidazole skeleton, an organometallic iridium complex having a phenylpyridine derivative with an electron-withdrawing group as a ligand, an organometallic iridium complex having a pyrimidine skeleton, an organometallic iridium complex having a pyrazine skeleton, an organometallic iridium complex having a pyridine skeleton, a rare earth metal complex, or a platinum complex.

### [Phosphorescent Substance (Blue)]

As an organometallic iridium complex having a 4H-triazole skeleton or the like, tris{2-[5-(2-methylphenyl)-4-(2,6-dimethylphenyl)-4H-1,2,4-triazol-3-yl-N2]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), or the like can be used.

As an organometallic iridium complex having a 1H-triazole skeleton or the like, tris[3-methyl-1-(2-methylphenyl)-5-phenyl-1H-1,2,4-triazolato]iridium(III) (abbreviation: [Ir(Mptzl-mp)₃]), tris(1-methyl-5-phenyl-3-propyl-1H-1,2,4-triazolato)iridium(III) (abbreviation: [Ir(Prptzl-Me)₃]), or the like can be used.

As an organometallic iridium complex having an imidazole skeleton or the like, fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), or the like can be used.

As an organometallic iridium complex having a phenylpyridine derivative with an electron-withdrawing group as a ligand, or the like, bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: Flrpic), bis{2-[3′,5′-bis(trifluoromethyl)phenyl]pyridinato-N,C^{2′}}iridium(III) picolinate (abbreviation: [Ir(CF₃ppy)₂(pic)]), bis[2-(4′,6′-difluorophenyl)pyridinato-N,C^{2′}]iridium(III) acetylacetonate (abbreviation: FIracac), or the like can be used.

These are compounds that exhibit blue phosphorescent light and have an emission wavelength peak at 440 nm to 520 nm.

### [Phosphorescent Substance (Green)]

As an organometallic iridium complex having a pyrimidine skeleton or the like, tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis(4,6-diphenylpyrimidinato)iridium(III) (abbreviation: [Ir(dppm)₂(acac)]), or the like can be used.

As an organometallic iridium complex having a pyrazine skeleton or the like, (acetylacetonato)bis(3,5-dimethyl-2-phenylpyrazinato)iridium(III) (abbreviation: [Ir(mppr-Me)₂(acac)]), (acetylacetonato)bis(5-isopropyl-3-methyl-2-phenylpyrazinato)iridium(III) (abbreviation: [Ir(mppr-iPr)₂(acac)]), or the like can be used.

As an organometallic iridium complex having a pyridine skeleton or the like, tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′}-iridium(III) (abbreviation: [Ir(pq)₃]), bis(2-phenylquinolinato-N,C^{2′}-iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d3-methyl-2-pyridinyl-κN²)phenyl-κC]iridium(III) (abbreviation: [Ir(5mppy-d₃)₂(mbfpypy-d₃)]), [2-d₃-methyl-(2-pyridinyl-κN)benzofuro[2,3-b]pyridine-κC]bis[2-(2-pyridinyl-KA)phenyl-κC]iridium(III) (abbreviation: [Ir(ppy)₂(mbfpypy-d₃)]), or the like can be used.

Examples of a rare earth metal complex include tris(acetylacetonato) (monophenanthroline)terbium(III) (abbreviation: [Tb(acac)₃(Phen)]).

These are compounds that mainly exhibit green phosphorescent light and have an emission wavelength peak at 500 nm to 600 nm. Note that an organometallic iridium complex having a pyrimidine skeleton has distinctively high reliability or emission efficiency.

### [Phosphorescent Substance (Red)]

As an organometallic iridium complex having a pyrimidine skeleton or the like, (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimnidinato](dipivaloylmethanato)iridium(III) (abbreviation: [Ir(5mdppm)₂(dpm)]), bis[4,6-di(naphthalen-1-yl)pyrimidinato](dipivaloylmethanato)iridium(III) (abbreviation: [Ir(dlnpm)₂(dpm)]), or the like can be used.

As an organometallic iridium complex having a pyrazine skeleton or the like, (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), (acetylacetonato)bis[2,3-bis(4-fluorophenyl)quinoxalinato]iridium(III) (abbreviation: [Ir(Fdpq)₂(acac)]), or the like can be used.

As an organometallic iridium complex having a pyridine skeleton or the like, tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), or the like can be used.

As a rare earth metal complex or the like, tris(1,3-diphenyl-1,3-propanedionato)(monophenanthroline)europium(III) (abbreviation: [Eu(DBM)₃(Phen)]), tris[1-(2-thenoyl)-3,3,3-trifluoroacetonato](monophenanthroline)europium(III) (abbreviation: [Eu(TTA)₃(Phen)]), or the like can be used.

As a platinum complex or the like, 2,3,7,8,12,13,17,18-octaethyl-21H,23H-porphyrin platinum(II) (abbreviation: PtOEP) or the like can be used.

These are compounds that exhibit red phosphorescent light and have an emission peak at 600 nm to 700 nm. Furthermore, the organometallic iridium complex having a pyrazine skeleton can provide red light emission with chromaticity favorably used for display apparatus.

### [Substance Exhibiting Thermally Activated Delayed Fluorescence (TADF)]

A TADF material can be used for the layer 111Y(i,j). When a TADF material is used as the light-emitting substance, the S1 level of the host material is preferably higher than the S1 level of the TADF material. In addition, the T1 level of the host material is preferably higher than the T1 level of the TADF material.

For example, TADF materials described below as examples can be used as the light-emitting material. Note that without limitation thereto, a variety of known TADF materials can be used.

In the TADF material, the difference between the S1 level and the T1 level is small, and reverse intersystem crossing (upconversion) from the triplet excited state into the singlet excited state can be achieved by a small amount of thermal energy. Thus, the singlet excited state can be efficiently generated from the triplet excited state. In addition, the triplet excitation energy can be converted into luminescence.

An exciplex whose excited state is formed of two kinds of substances has an extremely small difference between the S1 level and the T1 level and has a function of a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

Examples of the TADF material include a fullerene, a derivative thereof, an acridine, a derivative thereof, and an eosin derivative. Furthermore, porphyrin containing a metal such as magnesium (Mg), zinc (Zn), cadmium (Cd), tin (Sn), platinum (Pt), indium (In), or palladium (Pd) can also be used for the TADF material.

Specifically, the following materials whose structural formulae are shown below can be used: a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), an octaethylporphyrin-platinum chloride complex (PtCl₂OEP), and the like.

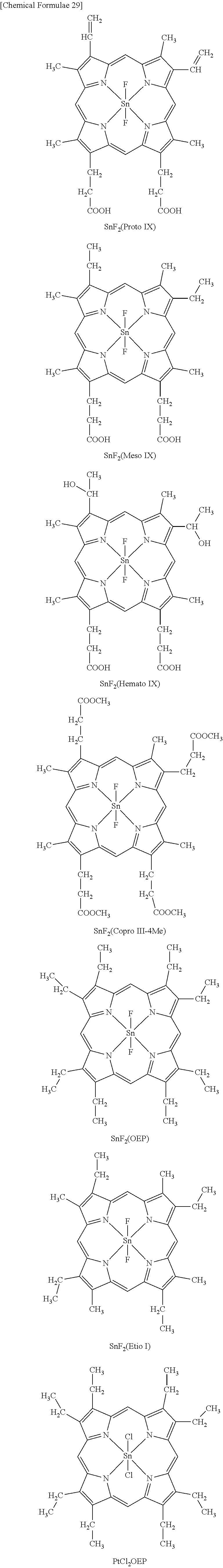

Furthermore, a heterocyclic compound including one or both of a π-electron rich heteroaromatic ring and a π-electron deficient beteroaromatic ring can be used, for example, as the TADF material.

Specifically, the following compounds whose structural formulae are shown below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H-,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), and the like.

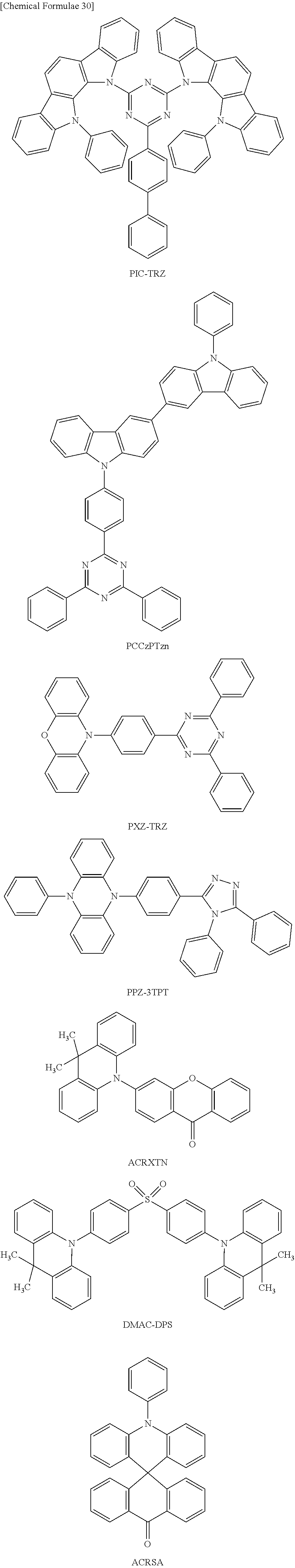

Such a heterocyclic compound is preferable because of having excellent electron-transport and hole-transport properties owing to a π-electron rich heteroaromatic ring and a π-electron deficient heteroaromatic ring. Among skeletons having the π-electron deficient heteroaromatic ring, in particular, a pyridine skeleton, a diazine skeleton (a pyrimidine skeleton, a pyrazine skeleton, and a pyridazine skeleton), and a triazine skeleton are preferred because of their high stability and reliability. In particular, a benzofuropyrimidine skeleton, a benzothienopyrimidine skeleton, a benzofuropyrazine skeleton, and a benzothienopyrazine skeleton are preferred because of their high electron-accepting properties and high reliability.

Among skeletons having the t-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton and a dibenzothiophene skeleton are preferable as a furan skeleton and a thiophene skeleton, respectively. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which the π-electron rich heteroaromatic ring is directly bonded to the π-electron deficient heteroaromatic ring is particularly preferred because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane and boranthrene, an aromatic ring or a heteroaromatic ring having a nitrile group or a cyano group such as benzonitrile or cyanobenzene, a carbonyl skeleton such as benzophenone, a phosphine oxide skeleton, a sulfone skeleton, or the like can be used.

As described above, a π-electron deficient skeleton and a π-electron rich skeleton can be used instead of at least one of the π-electron deficient heteroaromatic ring and the in-electron rich heteroaromatic ring.

### <<Structure Example 2 of Layer 111Y(i,j)

A carrier-transport material can be used as the host material. For example, a hole-transport material, an electron-transport material, a substance exhibiting thermally activated delayed fluorescence (TADF), a material having an anthracene skeleton, or a mixed material can be used as the host material. A material having a wider bandgap than the light-emitting material contained in the layer 111Y(i,j) is preferably used as the host material. Thus, energy transfer from excitons generated in the layer 111Y(i,j) to the host material can be inhibited.

### [Hole-Transport Material]

A material having a hole mobility higher than or equal to 1×10⁻⁶ cm²/Vs can be suitably used as the hole-transport material. For example, a hole-transport material that can be used for the layer 112 can be used as the host material.

### [Electron-Transport Material]

A metal complex or an organic compound having a π-electron deficient heteroaromatic ring skeleton can be used as the electron-transport material. For example, an electron-transport material that can be used for the layer 113 can be used as the host material.

### [Material Having Anthracene Skeleton]

An organic compound having an anthracene skeleton can be used as the host material. An organic compound having an anthracene skeleton is particularly preferable in the case where a fluorescent substance is used as a light-emitting substance. Thus, a light-emitting device with high emission efficiency and high durability can be obtained.

Among the organic compounds having an anthracene skeleton, an organic compound having a diphenylanthracene skeleton, in particular, a 9,10-diphenylanthracene skeleton, is chemically stable and thus is preferable. The host material preferably has a carbazole skeleton, in which case the hole-injection and hole-transport properties are improved. In particular, the host material preferably has a dibenzocarbazole skeleton, in which case the HOMO level thereof is shallower than that of carbazole by approximately 0.1 eV so that holes enter the host material easily, the hole-transport property is improved, and the heat resistance is increased. Note that in terms of the hole-injection and hole-transport properties, instead of a carbazole skeleton, a benzofluorene skeleton or a dibenzofluorene skeleton may be used.

Thus, a substance having both a 9,10-diphenylanthracene skeleton and a carbazole skeleton, a substance having both a 9,10-diphenylanthracene skeleton and a benzocarbazole skeleton, or a substance having both a 9,10-diphenylanthracene skeleton and a dibenzocarbazole skeleton is preferable as the host material.

For example, 6-[3-(9,10-diphenyl-2-anthryl)phenyl]-benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: αN-pNPAnth), 9-phenyl-3-[4-(10-phenyl-9-anthryl)phenyl]-9H-carbazole (abbreviation: PCzPA), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), or 3-[4-(1-naphthyl)-phenyl]-9-phenyl-9H-carbazole (abbreviation: PCPN) can be used.

In particular, CzPA, cgDBCzPA, 2mBnfPPA, and PCzPA have excellent characteristics.

### [Substance Exhibiting Thermally Activated Delayed Fluorescence (TADF)]

A TADF material can be used as the host material. When the TADF material is used as the host material, triplet excitation energy generated in the TADF material can be converted into singlet excitation energy by reverse intersystem crossing. Moreover, excitation energy can be transferred to the light-emitting substance. In other words, the TADF material functions as an energy donor, and the light-emitting substance functions as an energy acceptor. Thus, the emission efficiency of the light-emitting device can be increased.

This is very effective in the case where the light-emitting substance is a fluorescent substance. In that case, the S1 level of the TADF material is preferably higher than the S1 level of the fluorescent substance in order that high emission efficiency be achieved. Furthermore, the T1 level of the TADF material is preferably higher than the S1 level of the fluorescent substance. Therefore, the T1 level of the TADF material is preferably higher than the T1 level of the fluorescent substance.

It is also preferable to use a TADF material that emits light whose wavelength overlaps with the wavelength on a lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no π bond are poor in carrier-transport performance; therefore, the TADF material and the luminophore of the fluorescent substance can be made away from each other with little influence on carrier-transportation or carrier recombination.

Here, the luminophore refers to an atomic group (skeleton) that causes light emission in a fluorescent substance. The luminophore is preferably a skeleton having a π bond, further preferably includes an aromatic ring, and still further preferably includes a condensed aromatic ring or a condensed heteroaromatic ring.

Examples of the condensed aromatic ring or the condensed heteroaromatic ring include a phenanthrene skeleton, a stilbene skeleton, an acridone skeleton, a phenoxazine skeleton, and a phenothiazine skeleton. In particular, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferred because of its high fluorescence quantum yield.

For example, the TADF material that can be used as the light-emitting material can be used as the host material.

### Structure Example 1 of Mixed Material

A material in which a plurality of kinds of substances are mixed can be used as the host material. For example, an electron-transport material and a hole-transport material can be used for the mixed material. The weight ratio between the hole-transport material and the electron-transport material contained in the mixed material is (the hole-transport material/the electron-transport material)=(1/19) or more and (19/1) or less. Accordingly, the carrier-transport property of the layer 111Y(i,j) can be easily adjusted. In addition, a recombination region can be controlled easily.

### Structure Example 2 of Mixed Material

A material mixed with a phosphorescent substance can be used as the host material. When a fluorescent substance is used as the light-emitting substance, the phosphorescent substance can be used as an energy donor for supplying excitation energy to the fluorescent substance.

### Structure Example 3 of Mixed Material

A mixed material containing a material forming an exciplex can be used as the host material. For example, a material forming an exciplex whose emission spectrum overlaps with the wavelength of the absorption band on the lowest energy side of the light-emitting substance can be used as the host material. This enables smooth energy transfer and improves emission efficiency. Alternatively, the driving voltage can be reduced. With such a structure, light emission can be efficiently obtained by ExTET (Exciplex-Triplet Energy Transfer), which is energy transfer from the exciplex to the light-emitting substance (phosphorescent material).

A phosphorescent substance can be used as at least one of the materials forming an exciplex. Accordingly, reverse intersystem crossing can be used. Triplet excitation energy can be efficiently converted into singlet excitation energy.

A combination of materials forming an exciplex is preferably such that the HOMO level of a hole-transport material is higher than or equal to the HOMO level of an electron-transport material. Alternatively, the LUMO level of the hole-transport material is preferably higher than or equal to the LUMO level of the electron-transport material. In that case, an exciplex can be efficiently formed. Note that the LUMO levels and the HOMO levels of the materials can be derived from the electrochemical characteristics (the reduction potentials and the oxidation potentials). Specifically, the reduction potentials and the oxidation potentials can be measured by cyclic voltammetry (CV).

The formation of an exciplex can be confirmed by a phenomenon in which the emission spectrum of a mixed film in which the hole-transport material and the electron-transport material are mixed is shifted to a longer wavelength than the emission spectrum of each of the materials (or has another peak on the longer wavelength side) observed in comparison of the emission spectrum of the hole-transport material, the emission spectrum of the electron-transport material, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than the transient PL lifetime of each of the materials, observed in comparison of the transient PL of the hole-transport material, the transient PL of the electron-transport material, and the transient PL of the mixed film of these materials. The transient PL can be rephrased as transient electroluminescence (EL). That is, the formation of an exciplex can also be confirmed by a difference in transient response observed in comparison of the transient EL of the hole-transport material, the transient EL of the electron-transport material, and the transient EL of the mixed film of these materials.

### Structure Example 2 of Display Apparatus 700

The display apparatus 700 described in this embodiment includes an insulating film 528 (see FIG. 3A).

### Structure Example of Insulating Film 528

The insulating film 528 has openings; one opening overlaps with the electrode 551X(i,j) and the other opening overlaps with the electrode 551Y(i,j). The insulating film 528 overlaps with the space 551XY(i,j).

### Structure Example of Space 551XY(i,j)

The space 551XY(i,j) interposed between the electrode 551X(i,j) and the electrode 551Y(i,j) has a groove-like shape, for example. Thus, a step is formed along the groove. Asplit or thinned portion is formed between a film deposited over the space 551XY(i,j) and a film deposited over the electrode 551X(i,j).

When an anisotropic film formation method such as a thermal evaporation method is employed, a split or thinned portion is formed along the step in a space 104XY(i,j) interposed between the layer 104X(i,j) and the layer 104Y(i,j).

Accordingly, current flowing through the region 104XY(i,j) can be reduced, for example. In addition, current flowing between the layer 104X(i,j) and the layer 104Y(i,j) can be reduced. Occurrence of a phenomenon in which the light-emitting device 550Y(i;j) that is adjacent to the light-emitting device 550X(i,j) unintentionally emits light in accordance with the operation of the light-emitting device 550X(i,j) can be inhibited.

### Structure Example 3 of Display Apparatus 700

The display apparatus 700 described in this embodiment includes the light-emitting device 550X(i,j) and the light-emitting device 550Y(i,j) (see FIG. 3B). The light-emitting device 550Y(i,j) is adjacent to the light-emitting device 550X(i,j).

The display apparatus 700 is different from the display apparatus 700 described with reference to FIG. 3A in that part or the whole of the structure of the light-emitting device 550X(i,j) or the light-emitting device 550Y(i,j) is removed from a portion overlapping with the space 551XY(i,j); a split or thinned portion is formed in a region 106XY1(i,j) and a region 106XY2(i,j); and a film 529_1, a film 529_2, and a film 529_3 are provided instead of the insulating film 528. Different portions are described in detail here, and the above description is referred to for portions having the same structure as the above.

### Structure Example of Film 529_1

The film 529_1 has openings; one opening overlaps with the electrode 551X(i,j) and the other opening overlaps with the electrode 551Y(i,j) (see FIG. 3B). The film 529_1 further has an opening overlapping with the space 551XY(i,j). For example, a film containing a metal, a metal oxide, an organic material, or an inorganic insulating material can be used as the film 529_1. Specifically, a light-blocking metal film can be used. Accordingly, the structure of the light-emitting device can be protected from light emitted in the processing step.

### Structure Example of Film 529_2

The film 529_2 has openings; one opening overlaps with the electrode 551X(i,j) and the other opening overlaps with the electrode 551Y(i,j). The film 529_2 overlaps with the space 551XY(i,j).

The film 529_2 includes a region in contact with the layer 104X(i,j) and the unit 103X(i,j).

The film 529_2 includes a region in contact with the layer 104Y(i,j) and the unit 103Y(i,j).

The film 529_2 includes a region in contact with the insulating film 521. The film 5292 can be formed by an atomic layer deposition (ALD) method, for example. Thus, a film with favorable coverage can be formed. Specifically, a metal oxide film or the like can be used as the film 5292. Aluminum oxide can be used, for example.

### Structure Example of Film 529_3

The film 529_3 has openings; one opening overlaps with the electrode 551X(i,j) and the other opening overlaps with the electrode 551Y(i,j). A groove formed in a region overlapping with the space 551XY(i,j) is filled with the film 529_3. The film 529_3 can be formed using a photosensitive resin, for example. Specifically, an acrylic resin or the like can be used.

Thus, the layer 104X(i,j) can be electrically isolated from the layer 104Y(i,j), for example. In addition, current flowing through the region 104XY(i,j) can be reduced, for example. Occurrence of a phenomenon in which the light-emitting device 550Y(i,j) that is adjacent to the light-emitting device 550X(i,j) unintentionally emits light in accordance with the operation of the light-emitting device 550X(i,j) can be inhibited. A step formed between the top surface of the unit 103X(i,j) and the top surface of the unit 103Y(i,j) can be reduced. Occurrence of a phenomenon in which a split or thinned portion due to the step is formed between the electrode 552X(i,j) and the electrode 552Y(i,j) can be inhibited. A continuous conductive film can be used for the electrode 552X(i,j) and the electrode 552Y(i,j).

Note that part or the whole of the structure that can be employed for the light-emitting device 550X(i,j) or the light-emitting device 550Y(j) can be removed from a portion overlapping with the space 551XY(i,j) by using a photolithography technique, for example. In this specification and the like, a device formed using a metal mask or an FMM (fine metal mask, high-definition metal mask) may be referred to as a device having an MM (metal mask) structure. In this specification and the like, a device formed without using a metal mask or an FMM may be referred to as a device having an MML (metal maskless) structure.

In a formation method using a fine metal mask, it is difficult to set the distance between adjacent light-emitting devices to be less than 10 μm, for example. In a formation method employing a photolithography method over a glass substrate, the distance between adjacent light-emitting devices can be decreased to less than 10 μm, less than or equal to 5 μm, less than or equal to 3 μm, less than or equal to 2 μm, less than or equal to 1.5 μm, less than or equal to 1 μm, or less than or equal to 0.5 μm. In a formation method employing a photolithography method over a silicon wafer, the distance between adjacent light-emitting devices can be decreased to less than or equal to 500 nm, less than or equal to 200 nm, less than or equal to 100 nm, or less than or equal to 50 nm with use of an exposure apparatus for LSI, for example.

Accordingly, the area of a non-light-emitting region that exists between adjacent light-emitting devices can be significantly reduced. Furthermore, the aperture ratio can be made close to 100%. For example, the display apparatus of one embodiment of the present invention can have an aperture ratio higher than or equal to 40%, higher than or equal to 50%, higher than or equal to 60%, higher than or equal to 70%, higher than or equal to 80%, or higher than or equal to 90%, and lower than 100%.

Specifically, in a first step, a film to be the unit 103Y(i,j) later is formed over the space 551XY(i,j).

In a second step, a first film to be the film 529_1 later is formed over the film to be the unit 103Y(i,j) later.

In a third step, an opening overlapping with the space 551XY(i,j) is formed in the first film by a photolithography method.

In a fourth step, with use of the first film as a resist, part or the whole of the structure of the light-emitting device 550Y(i,j) is removed from a region overlapping with the space 551XY(i,j). For example, the unit 103Y is removed by a dry etching method. Specifically, an organic compound can be removed with use of an oxygen-containing gas. Accordingly, a groove-like structure is formed in the region overlapping with the space 551XY(i,j).

In a fifth step, a second film to be the film 529_2 later is formed over the first film by an atomic layer deposition method (ALD), for example.

In a sixth step, the film 529_3 is formed with use of a photosensitive polymer, for example. Accordingly, the groove-like structure formed in the region overlapping with the space 551XY(i,j) is filled with the film 529_3.

In a seventh step, an opening overlapping with the electrode 551Y(i,j) is formed in the first film and the second film by a photolithography method, whereby the film 5291 and the film 529_2 are formed.

In an eighth step, the layer 105Y(i,j) is formed over a unit 103Y2(i,j) and the electrode 552Y(i,j) is formed over the layer 105Y(i,j).

Note that this embodiment can be combined with any of the other embodiments described in this specification as appropriate.

### Embodiment 8

In this embodiment, structures of the display apparatus 700 of one embodiment of the present invention will be described with reference to FIG. 4A and FIG. 4B.

FIG. 4A is a cross-sectional view illustrating a structure of the display apparatus 700 of one embodiment of the present invention, and FIG. 4B is a cross-sectional view illustrating a structure of the display apparatus 700 of one embodiment of the present invention, which is different from the structure in FIG. 4A.

### Structure Example 1 of Display Apparatus 700

The display apparatus 700 described in this embodiment includes the light-emitting device 550X(i,j) and a photoelectric conversion device 550S(i,j) (see FIG. 4A). The photoelectric conversion device 550S(i,j) is adjacent to the light-emitting device 550X(i,j).

The display apparatus 700 includes the substrate 510 and the functional layer 520. The functional layer 520 includes the insulating film 521, and the light-emitting device 550X(i,j) and the light-emitting device 550Y(i,j) are formed over the insulating film 521. The functional layer 520 is interposed between the substrate 510 and the light-emitting device 550X(i,j).

### Structure Example of Light-Emitting Device 550X(i,j)

The light-emitting device 550X(i,j) includes the electrode 551X(i,j), the electrode 552X(i,j), and the unit 103X(i,j). The electrode 552X(i,j) overlaps with the electrode 551X(i,j), and the unit 103X(i,j) is interposed between the electrode 552X(i,j) and the electrode 551X(i,j). The light-emitting device 550X(i,j) includes the layer 104X(i,j) and the layer 105X(i,j). The layer 104X(i,j) is interposed between the unit 103X(i,j) and the electrode 551X(i,j), and the layer 105X(i,j) is interposed between the electrode 552X(i,j) and the unit 103X(i,j).

For example, the light-emitting device 550X described in Embodiment 2 to Embodiment 6 can be used as the light-emitting device 550X(i,j). Specifically, a structure that can be employed for the electrode 551X can be employed for the electrode 551X(i,j), and a structure that can be employed for the electrode 552X can be employed for the electrode 552X(i,j). A structure that can be employed for the unit 103X can be employed for the unit 103X(i,j). A structure that can be employed for the layer 104 can be employed for the layer 104X(i,j), and a structure that can be employed for the layer 105 can be employed for the layer 105X(i,j).

### Structure Example of Photoelectric Conversion Device 550S(i,j)

The photoelectric conversion device 550S(i,j) includes an electrode 551S(i,j), an electrode 552S(i,j), and a unit 103S(i,j). The electrode 552S(i,j) overlaps with the electrode 551S(i,j), and the unit 103S(i,j) is interposed between the electrode 552S(i,j) and the electrode 551S(i,j). The photoelectric conversion device 550S(i,j) includes a layer 104S(i,j) and a layer 105S(i,j). The layer 104S(i,j) is interposed between the unit 103S(i,j) and the electrode 551S(i,j), and the layer 105S(i,j) is interposed between the electrode 552S(i,j) and the unit 103S(i,j).

The electrode 551S(i,j) is adjacent to the electrode 551X(i,j), and a space 551XS(i,j) is provided between the electrode 551X(i,j) and the electrode 551S(i,j).

Note that part of a structure that can be employed as a structure of the light-emitting device 550X(i,j) described in Embodiment 2 to Embodiment 6 can be employed as a structure of the photoelectric conversion device 550S(i,j). For example, part of a conductive film that can be used for the electrode 552X(i,j) can be used for the electrode 552S(i,j). A structure that can be employed for the electrode 551X can be employed for the electrode 551S(i,j). A structure that can be employed for the layer 104 can be employed for the layer 104S(i,j), and a structure that can be employed for the layer 105 can be employed for the layer 105S(i,j). Thus, some of the components can be used in common. In addition, the manufacturing process can be simplified.

Note that the photoelectric conversion device 550S(i,j) is different from the light-emitting device 550X(i,j) in that the unit 103S(i,j) having a function of converting light into current is included instead of the unit 103X(i,j) having a function of emitting light. Different portions are described in detail here, and the above description is referred to for portions having the same structure as the above.

### <<Structure Example of Unit 103S(i,j)>

The unit 103S(i,j) has a single-layer structure or a stacked-layer structure. The unit 103S(i,j) can include, for example, a layer selected from functional layers such as a hole-transport layer, an electron-transport layer, and a carrier-blocking layer, besides a photoelectric conversion layer.

The unit 103S(i,j) includes a layer 114S(i,j), a layer 112S(i,j), and a layer 113S(i,j) (see FIG. 4A). The layer 114S(i,j) is interposed between the layer 112S(i,j) and the layer 113S(i,j). Note that the layer 112S(i,j) is interposed between the electrode 551S(i,j) and the layer 114S(i,j), and the layer 113 is interposed between the electrode 552S(i,j) and the layer 114S(i,j).

Note that the unit 103S(i,j) has a function of absorbing light hv and supplying electrons to one electrode and supplying holes to the other electrode. For example, the unit 103S(i,j) supplies holes to the electrode 551S(i,j), and supplies electrons to the electrode 552S(i,j).

Note that part of a structure that can be employed as a structure of the unit 103X described in Embodiment 2 can be employed as a structure of the unit 103S(i,j). For example, a structure that can be employed for the layer 112 can be employed for the layer 112S(i,j), and a structure that can be employed for the layer 113 can be employed for the layer 113S(i,j). Thus, some of the components can be used in common. In addition, the manufacturing process can be simplified.

### Structure Example 1 of Layer 114S(i,j)

The layer 114S(i,j) can be referred to as a photoelectric conversion layer. The layer 114S(i,j) absorbs the light hv, supplies electrons to a layer in contact with one side of the layer 114S(i,j), and supplies holes to a layer in contact with the other side of the layer 114S(i,j). For example, the layer 114S(i,j) supplies holes to the layer 112, and supplies electrons to the layer 113. For example, a material that can be used for an organic solar cell can be used for the layer 114S(i,j). Specifically, an electron-accepting material and an electron-donating material can be used for the layer 114S(i,j).

### Example of Electron-Accepting Material

As the electron-accepting material, a fullerene derivative or a non-fullerene electron acceptor can be used, for example.

As the electron-accepting material, a C₆₀ fullerene, a C₇₀ fullerene, [6,6]-phenyl-C₇₁-butyric acid methyl ester (abbreviation: PC71BM), [6,6]-phenyl-C₆₁-butyric acid methyl ester (abbreviation: PC61BM), 1′, 1″, 4′, 4″-tetrahydro-di[1,4]methanonaphthaleno[1,2:2′, 3′, 56,60:2″, 3″ ][5,6]fullerene-C₆₀ (abbreviation: ICBA), or the like can be used.

As the non-fullerene electron acceptor, a perylene derivative, a compound having a dicyanomethyleneindanone group, or the like can be used. For example, N,N-dimethyl-3,4,9,10-perylenedicarboximide (abbreviation: Me-PTCDI) can be used.

### Example of Electron-Donating Material

As the electron-donating material, a phthalocyanine compound, a tetracene derivative, a quinacridone derivative, a rubrene derivative, or the like can be used.

As the electron-donating material, copper(II) phthalocyanine (abbreviation: CuPc), tin(II) phthalocyanine (SnPc), zinc phthalocyanine (ZnPc), tetraphenyldibenzoperiflanthene (DBP), rubrene, or the like can be used.

### Structure Example 2 of Layer 114S(i,j)

The layer 114S(i,j) can have a single-layer structure or a stacked-layer structure, for example. Specifically, the layer 114S(i,j) can have a bulk heterojunction structure. Alternatively, the layer 114S(i,j) can have a heterojunction structure.

### Example of Bulk Heterojunction Structure

A mixed material containing an electron-accepting material and an electron-donating material can be used for the layer 114S(i,j), for example (see FIG. 4A). Note that a structure in which a mixed material containing an electron-accepting material and an electron-donating material is used for the layer 114S(i,j) can be referred to as a bulk heterojunction structure.

Specifically, a mixed material containing a C₇₀ fullerene and DBP can be used for the layer 114S(i,j).

### Example of Heterojunction Structure

A layer 114N(i,j) and a layer 114P(i,j) can be used for the layer 114S(i,j) (see FIG. 4B). The layer 114N(i,j) is interposed between one electrode and the layer 114P(i,j), and the layer 114P(i,j) is interposed between the layer 114N(i,j) and the other electrode. For example, the layer 114N(i,j) is interposed between the electrode 552S(i,j) and the layer 114P(i,j), and the layer 114P(i,j) is interposed between the layer 114N(i,j) and the electrode 551S(i,j).

An n-type semiconductor can be used for the layer 114N(i,j). For example, Me-PTCDI can be used for the layer 114N(i,j).

A p-type semiconductor can be used for the layer 114P(i,j). For example, rubrene can be used for the layer 114P(i,j).

Note that the photoelectric conversion device 550S(i,j) in which the layer 114P(i,j) is in contact with the layer 114N(i,j) can be referred to as a pn-junction photodiode.

### Embodiment 9

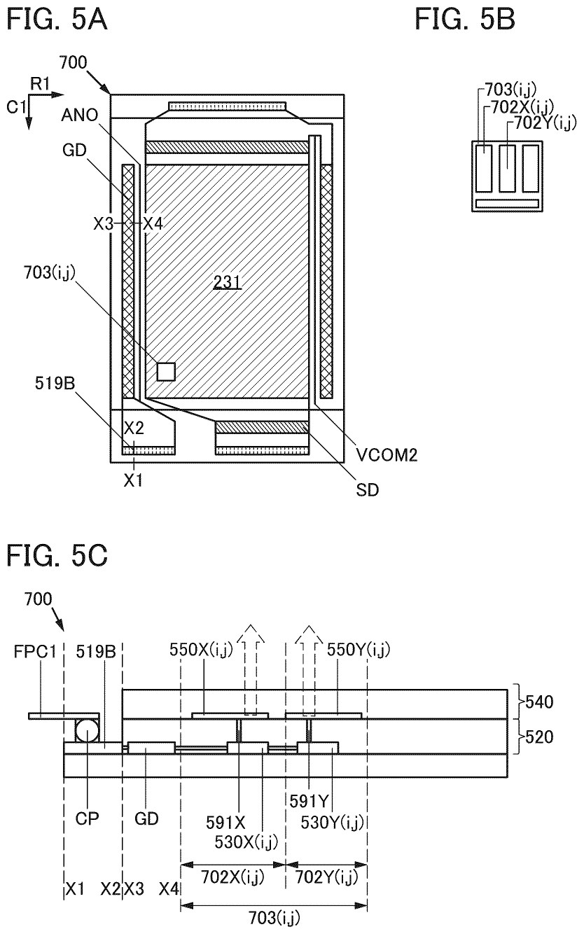

In this embodiment, the structure of a device of one embodiment of the present invention will be described with reference to FIG. 5 to FIG. 7.

FIG. 5 illustrates the structure of a device of one embodiment of the present invention. FIG. 5A is a top view of the device of one embodiment of the present invention, and FIG. 5B is a top view illustrating part of FIG. 5A. FIG. 5C is a cross-sectional view taken along the cutting line X1-X2 and the cutting line X3-X4 in FIG. 5A and a cross-sectional view of a set of pixels 703(ij).

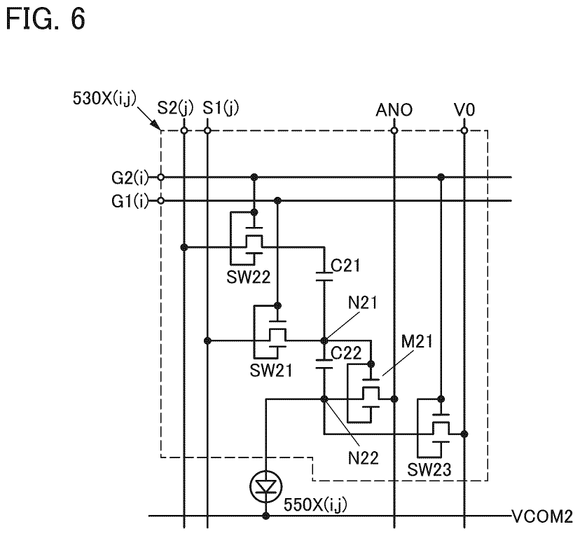

FIG. 6 is a circuit diagram illustrating the structure of the device of one embodiment of the present invention.

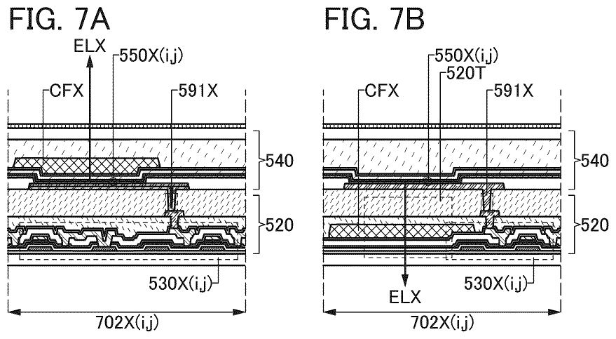

FIG. 7 illustrates the structures of the device of one embodiment of the present invention. FIG. 7A is a cross-sectional view of the device of one embodiment of the present invention, and FIG. 7B is a cross-sectional view different from FIG. 7A.

### Structure Example 1 of Display Apparatus 700

The display apparatus 700 of one embodiment of the present invention includes a region 231 (see FIG. 5A). The display region 231 includes the set of pixels 703(ij).

### Structure Example of Set of Pixels 703(Ij)

The set of pixels 703(ij) includes a pixel 702X(i,j) (see FIG. 5B and FIG. 5C).

The pixel 702X(i,j) includes a pixel circuit 530X(i,j) and the light-emitting device 550X(i,j). The light-emitting device 550X(i,j) is electrically connected to the pixel circuit 530X(i,j).

For example, the light-emitting device described in Embodiment 2 to Embodiment 6 can be used as the light-emitting device 550X(i,j). The display apparatus 700 has a function of displaying an image.

### Structure Example 2 of Display Apparatus 700

In addition, the display apparatus 700 of one embodiment of the present invention includes a functional layer 540 and a functional layer 520 (see FIG. 5C). The functional layer 540 overlaps with the functional layer 520.

The functional layer 540 includes the light-emitting device 550X(i,j).

The functional layer 520 includes the pixel circuit 530X(i,j) and a wiring (see FIG. 5C). The pixel circuit 530X(i,j) is electrically connected to the wiring. For example, a conductive film provided in an opening 591X or an opening 591Y of the functional layer 520 can be used as the wiring. The wiring electrically connects a terminal 519B to the pixel circuit 530X(i,j). Note that a conductive material CP electrically connects the terminal 519B to a flexible printed circuit board FPC1.

### Structure Example 3 of Display Apparatus 700

In addition, the display apparatus 700 of one embodiment of the present invention includes a driver circuit GD and a driver circuit SD (see FIG. 5A).

### Structure Example of Driver Circuit GD

The driver circuit GD supplies a first selection signal and a second selection signal.

### Structure Example of Driver Circuit SD

The driver circuit SD supplies a first control signal and a second control signal.

### Structure Example 1 of Wiring

As wirings, a conductive film G1(i), a conductive film G2(i), a conductive film S1(j), a conductive film S2(j), a conductive film ANO, a conductive film VCOM2, and a conductive film V0 are included (see FIG. 6).

The conductive film G1(i) is supplied with the first selection signal, and the conductive film G2(i) is supplied with the second selection signal.

The conductive film S1(j) is supplied with the first control signal, and the conductive film S2(j) is supplied with the second control signal.

### Structure Example 1 of Pixel Circuit 530X(i,j)

The pixel circuit 530X(i,j) is electrically connected to the conductive film G1(i) and the conductive film S1(j). The conductive film G1(i) supplies the first selection signal, and the conductive film S1(j) supplies the first control signal.

The pixel circuit 530X(i,j) drives the light-emitting device 550X(i,j) in response to the first selection signal and the first control signal. The light-emitting device 550X(i,j) emits light.

One electrode of the light-emitting device 550X(i,j) is electrically connected to the pixel circuit 530X(i,j) and the other electrode is electrically connected to the conductive film VCOOM2.

### Structure Example 2 of Pixel Circuit 530X(i,j)

The pixel circuit 530X(i,j) includes a switch SW21, a switch SW22, a transistor M21, a capacitor C21, and a node N21.

The transistor M21 includes a gate electrode electrically connected to the node N21, a first electrode electrically connected to the light-emitting device 550X(i,j), and a second electrode electrically connected to the conductive film ANO.

The switch SW21 includes a first terminal electrically connected to the node N21, a second terminal electrically connected to the conductive film S1(j), and a gate electrode having a function of controlling the conduction state and the non-conduction state according to the potential of the conductive film G1(i).

The switch SW22 includes a first terminal electrically connected to the conductive film S2(j), and a gate electrode having a function of controlling the conduction state and the non-conduction state according to the potential of the conductive film G2(i).

The capacitor C21 includes a conductive film electrically connected to the node N21 and a conductive film electrically connected to a second electrode of the switch SW22.

Accordingly, an image signal can be stored in the node N21. Alternatively, the potential of the node N21 can be changed using the switch SW22. Alternatively, the intensity of light emitted from the light-emitting device 550X(i,j) can be controlled with the potential of the node N21 As a result, a novel device that is highly convenient, useful, or reliable can be provided.

### Structure Example 3 of Pixel Circuit 530X(i,j)

The pixel circuit 530X(i,j) includes a switch SW23, a node N22, and a capacitor C22.

The switch SW23 includes a first terminal electrically connected to the conductive film V0, a second terminal electrically connected to the node N22, and a gate electrode having a function of controlling the conduction state and the non-conduction state according to the potential of the conductive film G2(i).

The capacitor C22 includes a conductive film electrically connected to the node N21 and a conductive film electrically connected to the node N22.

The first electrode of the transistor M21 is electrically connected to the node N22.

### Structure Example 1 of Pixel 702X(i,j)

The pixel 702X(i,j) includes the light-emitting device 550X(i,j) and the pixel circuit 530X(i,j) (see FIG. 7A). The functional layer 540 includes the light-emitting device 550X(i,j) and a coloring layer CFX and the functional layer 520 includes the pixel circuit 530X(i,j).

The light-emitting device 550X(i,j) is a top-emission light-emitting device, and the light-emitting device 550X(i,j) emits the light ELX to the side where the functional layer 520 is not provided.

The coloring layer CFX transmits part of light emitted from the light-emitting device 550X(i,j). For example, the coloring layer CFX may transmit part of white light, so that blue light, green light, or red light can be extracted. Note that a color conversion layer can be used instead of the coloring layer CFX. Accordingly, light with a short wavelength can be converted into light with a long wavelength.

### <Structure Example 2 of Pixel 702X(i,j)

The pixel 702X(i,j) described with reference to FIG. 7B includes a bottom-emission light-emitting device. The light-emitting device 550X(i,j) emits the light ELX to the side where the functional layer 520 is provided.

The functional layer 520 includes a region 520T, and the region 520T transmits the light ELX. The functional layer 520 includes the coloring layer CFX, and the coloring layer CFX overlaps with the region 520T.

Note that this embodiment can be combined with any of the other embodiments described in this specification as appropriate.

### Embodiment 10

In this embodiment, a light-emitting apparatus including the light-emitting device described in any one of Embodiment 2 to Embodiment 6 will be described.

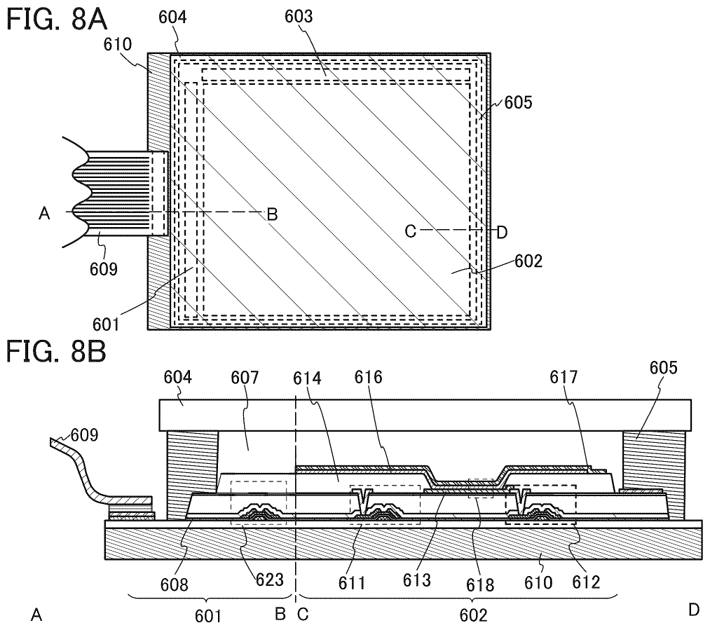

In this embodiment, the light-emitting apparatus fabricated using the light-emitting device described in any one of Embodiment 2 to Embodiment 6 is described with reference to FIG. 8. Note that FIG. 8A is a top view of the light-emitting apparatus and FIG. 8B is a cross-sectional view taken along A-B and C-D in FIG. 8A. This light-emitting apparatus includes a driver circuit portion illustrated with dotted lines and a pixel portion 602, which are to control light emission of the light-emitting devices, and the driver circuit portion includes a source line driver circuit 601 and a gate line driver circuit 603. The light-emitting apparatus is provided with a sealing substrate 604 and a sealing material 605, and a space 607 is surrounded by the sealing material 605.

A lead wiring 608 is a wiring for transmitting signals to be input to the source line driver circuit 601 and the gate line driver circuit 603 and receives a video signal, a clock signal, a start signal, a reset signal, and the like from an FPC (flexible printed circuit) serving as an external input terminal 609. Although only the FPC is illustrated here, a printed wiring board (PWB) may be attached to the FPC. The light-emitting apparatus in this specification includes, in its category, not only the light-emitting apparatus itself but also the light-emitting apparatus provided with the FPC or the PWB.

Next, a cross-sectional structure is described with reference to FIG. 8B. The driver circuit portion and the pixel portion are formed over an element substrate 610; here, the source line driver circuit 601, which is a driver circuit portion, and one pixel in the pixel portion 602 are illustrated.

The element substrate 610 is formed using a substrate formed of glass, quartz, an organic resin, a metal, an alloy, a semiconductor, or the like or a plastic substrate formed of FRP (Fiber Reinforced Plastics), PVF (polyvinyl fluoride), polyester, an acrylic resin, or the like.

The structures of transistors used in pixels or driver circuits are not particularly limited. For example, inverted staggered transistors or staggered transistors may be used. Furthermore, top-gate transistors or bottom-gate transistors may be used. A semiconductor material used for the transistors is not particularly limited, and for example, silicon, germanium, silicon carbide, or gallium nitride can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. It is preferable that a semiconductor having crystallinity be used, in which case deterioration of the transistor characteristics can be inhibited.

Here, an oxide semiconductor is preferably used for semiconductor devices such as the transistors provided in the pixels or driver circuits and transistors used for touch sensors described later, and the like. In particular, an oxide semiconductor having a wider band gap than silicon is preferably used. When an oxide semiconductor having a wider band gap than silicon is used, the off-state current of the transistors can be reduced.

The oxide semiconductor preferably contains at least indium (In) or zinc (Zn). Further preferably, the oxide semiconductor contains an oxide represented by an In—M—Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image displayed in each display region is maintained. As a result, an electronic device with extremely low power consumption can be obtained.

For stable characteristics or the like of the transistor, a base film is preferably provided. The base film can be formed with a single layer or stacked layers using an inorganic insulating film such as a silicon oxide film, a silicon nitride film, a silicon oxynitride film, or a silicon nitride oxide film. The base film can be formed by a sputtering method, a CVD (Chemical Vapor Deposition) method (e.g., a plasma CVD method, a thermal CVD method, or an MOCVD (Metal Organic CVD) method), an ALD (Atomic Layer Deposition) method, a coating method, a printing method, or the like. Note that the base film is not necessarily provided.

Note that an FET 623 is illustrated as a transistor formed in the source line driver circuit 601. In addition, the driver circuit is formed with any of a variety of circuits such as a CMOS circuit, a PMOS circuit, or an NMOS circuit. Although a driver integrated type in which the driver circuit is formed over the substrate is illustrated in this embodiment, the driver circuit is not necessarily formed over the substrate, and can be formed outside.

Although the pixel portion 602 includes a plurality of pixels each including a switching FET 611, a current controlling FET 612, and a first electrode 613 electrically connected to a drain of the current controlling FET 612, one embodiment of the present invention is not limited to this structure. The pixel portion may include three or more FETs and a capacitor in combination.

Note that an insulator 614 is formed to cover an end portion of the first electrode 613. Here, the insulator 614 can be formed using a positive photosensitive acrylic resin film.

In order to improve coverage with an EL layer or the like which is formed later, the insulator 614 is formed to have a curved surface with curvature at its upper end portion or lower end portion. For example, in the case where a positive photosensitive acrylic resin is used for a material of the insulator 614, only the upper end portion of the insulator 614 preferably has a surface with a curvature radius (greater than or equal to 0.2 m and less than or equal to 3 μm). As the insulator 614, either a negative photosensitive resin or a positive photosensitive resin can be used.

An EL layer 616 and a second electrode 617 are formed over the first electrode 613. Here, as a material used for the first electrode 613 functioning as an anode, a material having a high work function is desirably used. For example, a single-layer film of an ITO film, an indium tin oxide film containing silicon, an indium oxide film containing zinc oxide at higher than or equal to 2 wt % and lower than or equal to 20 wt %, a titanium nitride film, a chromium film, a tungsten film, a Zn film, a Pt film, or the like, a stack of a titanium nitride film and a film containing aluminum as its main component, or a three-layer structure of a titanium nitride film, a film containing aluminum as its main component, and a titanium nitride film can be used. The stacked-layer structure enables low wiring resistance, favorable ohmic contact, and a function as an anode.

The EL layer 616 is formed by any of a variety of methods such as an evaporation method using an evaporation mask, an inkjet method, and a spin coating method. The EL layer 616 has the structure described in any one of Embodiment 2 to Embodiment 6. As another material included in the EL layer 616, a low molecular compound or a high molecular compound (including an oligomer or a dendrimer) may be used.

As a material used for the second electrode 617, which is formed over the EL layer 616 and functions as a cathode, a material having a low work function (e.g., Al, Mg, Li, and Ca, or an alloy or a compound thereof (such as MgAg, MgIn, and AlLi)) is preferably used. In the case where light generated in the EL layer 616 passes through the second electrode 617, a stack including a thin metal film and a transparent conductive film (e.g., ITO, indium oxide containing zinc oxide at higher than or equal to 2 wt % and lower than or equal to 20 wt %, indium tin oxide containing silicon, or zinc oxide (ZnO)) is preferably used for the second electrode 617.

Note that the light-emitting device is formed with the first electrode 613, the EL layer 616, and the second electrode 617. The light-emitting device is the light-emitting device described in any one of Embodiment 2 to Embodiment 6. A plurality of light-emitting devices are formed in the pixel portion, and the light-emitting apparatus of this embodiment may include both the light-emitting device described in any one of Embodiment 2 to Embodiment 6 and a light-emitting device having a different structure.

The sealing substrate 604 is attached to the element substrate 610 with the sealing material 605, so that a light-emitting device 618 is provided in the space 607 surrounded by the element substrate 610, the sealing substrate 604, and the sealing material 605. The space 607 is filled with a filler, and may be filled with an inert gas (such as nitrogen or argon) or the sealing material. Although not illustrated in FIG. 8B, it is preferable that the sealing substrate be provided with a depressed portion and a drying agent be provided in the depressed portion, in which case deterioration due to influence of moisture can be inhibited.

An epoxy-based resin or glass frit is preferably used for the sealing material 605. Furthermore, these materials are preferably materials that transmit moisture and oxygen as little as possible. As the sealing substrate 604, a glass substrate, a quartz substrate, or a plastic substrate formed of FRP (Fiber Reinforced Plastics), PVF (polyvinyl fluoride), polyester, an acrylic resin, or the like can be used.

Although not illustrated in FIG. 8A and FIG. 8B, a protective film may be provided over the second electrode. As the protective film, an organic resin film or an inorganic insulating film may be formed. The protective film may be formed so as to cover an exposed portion of the sealing material 605. The protective film can be provided so as to cover surfaces and side surfaces of the pair of substrates and exposed side surfaces of a sealing layer, an insulating layer, and the like.

The protective film can be formed using a material that does not easily transmit an impurity such as water. Thus, diffusion of an impurity such as water from the outside into the inside can be effectively suppressed.

As a material of the protective film, an oxide, a nitride, a fluoride, a sulfide, a ternary compound, a metal, a polymer, or the like can be used. For example, a material containing aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, or indium oxide; a material containing aluminum nitride, hafnium nitride, silicon nitride, tantalum nitride, titanium nitride, niobium nitride, molybdenum nitride, zirconium nitride, or gallium nitride; or a material containing a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, or an oxide containing yttrium and zirconium can be used.

The protective film is preferably formed using a film formation method with favorable step coverage. One such method is an atomic layer deposition (ALD) method. A material that can be formed by an ALD method is preferably used for the protective film. A dense protective film having reduced defects such as cracks or pinholes or a uniform thickness can be formed by an AID method. Furthermore, damage caused to a process member in forming the protective film can be reduced.

By an ALD method, a uniform protective film with few defects can be formed even on, for example, a surface with a complex uneven shape or the upper surface, side surface, and rear surface of a touch panel.

As described above, the light-emitting apparatus fabricated using the light-emitting device described in any one of Embodiment 2 to Embodiment 6 can be obtained.

The light-emitting apparatus in this embodiment is fabricated using the light-emitting device described in any one of Embodiment 2 to Embodiment 6 and thus can have favorable characteristics. Specifically, since the light-emitting device described in any one of Embodiment 2 to Embodiment 6 has high emission efficiency, the light-emitting apparatus can achieve low power consumption.

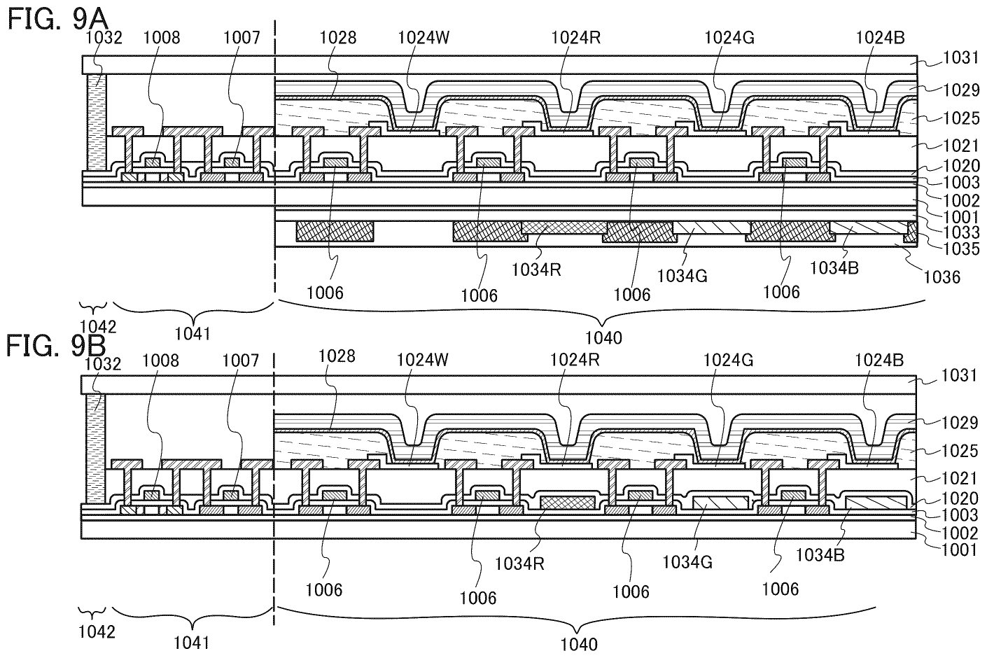

FIG. 9 illustrates examples of a light-emitting apparatus in which full color display is achieved by formation of light-emitting devices emitting white light and provision of coloring layers (color filters) and the like. In FIG. 9A, a substrate 1001, a base insulating film 1002, a gate insulating film 1003, a gate electrode 1006, a gate electrode 1007, a gate electrode 1008, a first interlayer insulating film 1020, a second interlayer insulating film 1021, a peripheral portion 1042, a pixel portion 1040, a driver circuit portion 1041, an electrode 1024W, an electrode 1024R, an electrode 1024G, and an electrode 1024B of light-emitting devices, a partition 1025, an EL layer 1028, an electrode 1029 of the light-emitting devices, a sealing substrate 1031, a sealing material 1032, and the like are illustrated.

In FIG. 9A, coloring layers (a red coloring layer 1034R, a green coloring layer 1034G, and a blue coloring layer 1034B) are provided on a transparent base 1033. A black matrix 1035 may be additionally provided. The transparent base 1033 provided with the coloring layers and the black matrix is aligned and fixed to the substrate 1001. Note that the coloring layers and the black matrix 1035 are covered with an overcoat layer 1036. In FIG. 9A, a light-emitting layer from which light is emitted to the outside without passing through the coloring layer and light-emitting layers from which light is emitted to the outside, passing through the coloring layers of the respective colors are shown. Since light that does not pass through the coloring layer is white and light that passes through the coloring layer is red, green, or blue, an image can be expressed by pixels of the four colors.

FIG. 9B shows an example in which the coloring layers (the red coloring layer 1034R, the green coloring layer 1034G, and the blue coloring layer 1034B) are provided between the gate insulating film 1003 and the first interlayer insulating film 1020. As in the structure, the coloring layers may be provided between the substrate 1001 and the sealing substrate 1031.

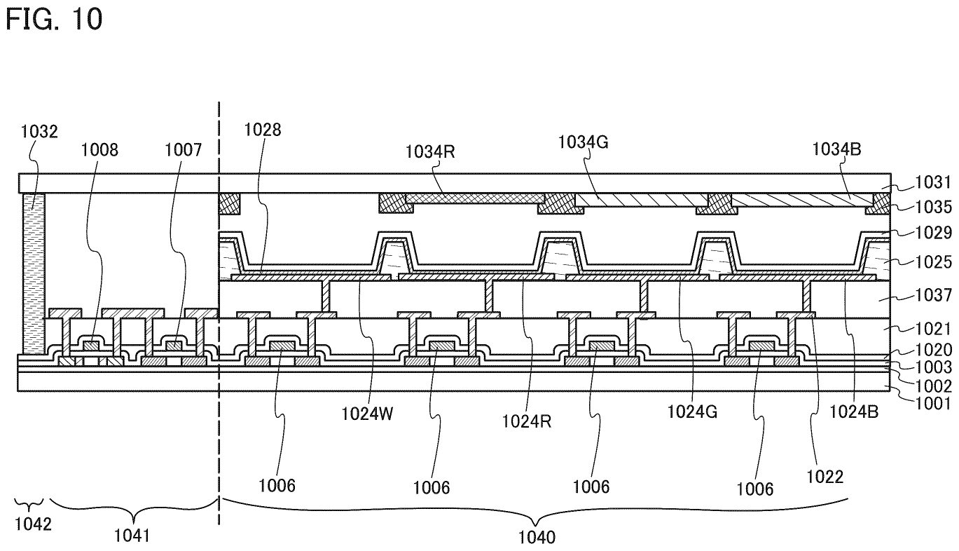

The above-described light-emitting apparatus has a structure in which light is extracted from the substrate 1001 side where FETs are formed (a bottom emission structure), but may have a structure in which light is extracted from the sealing substrate 1031 side (a top emission structure). FIG. 10 is a cross-sectional view of a top-emission light-emitting apparatus. In this case, a substrate which does not transmit light can be used as the substrate 1001. The process up to the step of forming a connection electrode which connects the FET and the anode of the light-emitting device is performed in a manner similar to that of the bottom-emission light-emitting apparatus. Then, a third interlayer insulating film 1037 is formed to cover an electrode 1022. This insulating film may have a planarization function. The third interlayer insulating film 1037 can be formed using a material similar to that of the second interlayer insulating film, and can alternatively be formed using any of other known materials.

The electrode 1024W, the electrode 1024R, the electrode 1024G, and the electrode 1024B of the light-emitting devices each serve as an anode here, but may serve as a cathode. Furthermore, in the case of the top-emission light-emitting apparatus illustrated in FIG. 10, the electrode 1024W, the electrode 1024R, the electrode 1024G, and the electrode 1024B are preferably reflective electrodes. The EL layer 1028 is formed to have a structure similar to the structure of the unit 103X, which is described in any one of Embodiment 2 to Embodiment 6, with which white light emission can be obtained.

In the case of a top emission structure as illustrated in FIG. 10, sealing can be performed with the sealing substrate 1031 on which the coloring layers (the red coloring layer 1034R, the green coloring layer 1034G, and the blue coloring layer 1034B) are provided. The sealing substrate 1031 may be provided with the black matrix 1035 which is positioned between pixels. The coloring layers (the red coloring layer 1034R, the green coloring layer 1034G, and the blue coloring layer 1034B) or the black matrix 1035 may be covered with an overcoat layer. Note that a light-transmitting substrate is used as the sealing substrate 1031. Although an example in which full color display is performed using four colors of red, green, blue, and white is shown here, there is no particular limitation and full color display using four colors of red, yellow, green, and blue or three colors of red, green, and blue may be performed.

In the top-emission light-emitting apparatus, a microcavity structure (microcavity) can be favorably employed. A light-emitting device with a microcavity structure (microcavity) is formed with use of a reflective electrode as the first electrode and a semi-transmissive and semi-reflective electrode as the second electrode. The light-emitting device with a microcavity structure (microcavity) includes at least an EL layer between the reflective electrode and the semi-transmissive and semi-reflective electrode, which includes at least a light-emitting layer serving as a light-emitting region.

Note that the reflective electrode has a visible light reflectivity higher than or equal to 40% and lower than or equal to 100%, preferably higher than or equal to 70% and lower than or equal to 100%, and a resistivity of 1×10⁻² Ω·cm or lower. In addition, the semi-transmissive and semi-reflective electrode has a visible light reflectivity higher than or equal to 20% and lower than or equal to 80%, preferably higher than or equal to 40% and lower than or equal to 70%, and a resistivity of 1×10⁻² Ω·cm or lower.

Light emitted from the light-emitting layer included in the EL layer is reflected and resonated by the reflective electrode and the semi-transmissive and semi-reflective electrode.

In the light-emitting device, by changing the thickness of the transparent conductive film, the composite material, the carrier-transport material, or the like, the optical path length between the reflective electrode and the semi-transmissive and semi-reflective electrode can be changed. Thus, light with a wavelength that is resonated between the reflective electrode and the semi-transmissive and semi-reflective electrode can be intensified while light with a wavelength that is not resonated therebetween can be attenuated.

Note that light that is reflected back by the reflective electrode (first reflected light) considerably interferes with light that directly enters the semi-transmissive and semi-reflective electrode from the light-emitting layer (first incident light). For this reason, the optical path length between the reflective electrode and the light-emitting layer is preferably adjusted to (2n−1)λ/4 (n is a natural number of 1 or larger and k is a wavelength of light to be amplified). By adjusting the optical path length, the phases of the first reflected light and the first incident light can be aligned with each other and the light emitted from the light-emitting layer can be further amplified.

Note that in the above structure, the EL layer may include a plurality of light-emitting layers or may include a single light-emitting layer. For example, in combination with the structure of the above-described tandem light-emitting device, a plurality of EL layers each including a single or a plurality of light-emitting layer(s) may be provided in one light-emitting device with a charge-generation layer interposed between the EL layers.

With the microcavity structure (microcavity), emission intensity with a specific wavelength in the front direction can be increased, whereby power consumption can be reduced. Note that in the case of a light-emitting apparatus which displays images with subpixels of four colors, red, yellow, green, and blue, the light-emitting apparatus can have favorable characteristics because the luminance can be increased owing to yellow light emission and each subpixel can employ a microcavity structure (microcavity) suitable for wavelengths of the corresponding color.

The light-emitting apparatus in this embodiment is fabricated using the light-emitting device described in any one of Embodiment 2 to Embodiment 6 and thus can have favorable characteristics. Specifically, since the light-emitting device described in any one of Embodiment 2 to Embodiment 6 has high emission efficiency, the light-emitting apparatus can achieve low power consumption.

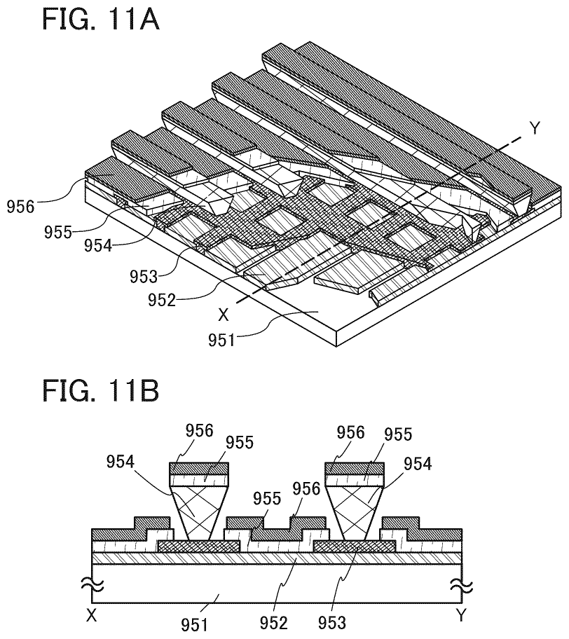

An active matrix light-emitting apparatus is described above, whereas a passive matrix light-emitting apparatus is described below. FIG. 11 illustrates a passive matrix light-emitting apparatus manufactured using the present invention. Note that FIG. 11A is a perspective view of the light-emitting apparatus, and FIG. 11B is a cross-sectional view taken along X-Y in FIG. 11A. In FIG. 11, over a substrate 951, an EL layer 955 is provided between an electrode 952 and an electrode 956. An end portion of the electrode 952 is covered with an insulating layer 953. A partition layer 954 is provided over the insulating layer 953. The sidewalls of the partition layer 954 are aslope such that the distance between one sidewall and the other sidewall is gradually narrowed toward the surface of the substrate. In other words, a cross section taken along the direction of the short side of the partition layer 954 is trapezoidal, and the lower side (a side that is parallel to the surface of the insulating layer 953 and is in contact with the insulating layer 953) is shorter than the upper side (a side that is parallel to the surface of the insulating layer 953 and is not in contact with the insulating layer 953). The partition layer 954 thus provided can prevent defects in the light-emitting device due to static electricity or others. The passive-matrix light-emitting apparatus also includes the light-emitting device described in any one of Embodiment 2 to Embodiment 6; thus, the light-emitting apparatus can have high reliability or low power consumption.

Since many minute light-emitting devices arranged in a matrix in the light-emitting apparatus described above can be each controlled, the light-emitting apparatus can be suitably used as a display apparatus for displaying images.

This embodiment can be freely combined with any of the other embodiments.

### Embodiment 11

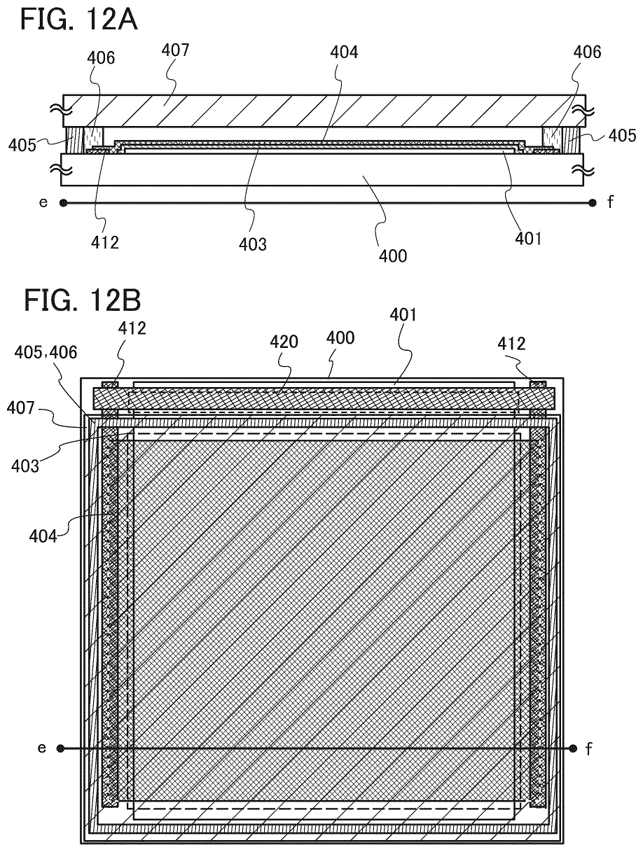

In this embodiment, an example in which the light-emitting device described in any one of Embodiment 2 to Embodiment 6 is used for a lighting device will be described with reference to FIG. 12. FIG. 12B is a top view of the lighting device, and FIG. 12A is a cross-sectional view taken along e-f in FIG. 12B.

In the lighting device in this embodiment, a first electrode 401 is formed over a substrate 400 which is a support and has a light-transmitting property. The first electrode 401 corresponds to the electrode 551X in any one of Embodiment 2 to Embodiment 6. When light is extracted from the first electrode 401 side, the first electrode 401 is formed using a material having a light-transmitting property.

A pad 412 for supplying voltage to a second electrode 404 is formed over the substrate 400.

An EL layer 403 is formed over the first electrode 401. The EL layer 403 corresponds to the structure in which the layer 104, the unit 103X, and the layer 105 are combined, the structure in which the layer 104, the unit 103X, the layer 106, the unit 103X2, and the layer 105 are combined, or the like in any one of Embodiment 2 to Embodiment 6. Refer to the corresponding description for these structures.

The second electrode 404 is formed to cover the EL layer 403. The second electrode 404 corresponds to the electrode 552X in any one of Embodiment 2 to Embodiment 6. The second electrode 404 is formed using a material having high reflectance when light is extracted from the first electrode 401 side. The second electrode 404 is connected to the pad 412, whereby voltage is supplied.

As described above, the lighting device described in this embodiment includes a light-emitting device including the first electrode 401, the EL layer 403, and the second electrode 404. Since the light-emitting device is a light-emitting device with high emission efficiency, the lighting device in this embodiment can be a lighting device with low power consumption.

The substrate 400 provided with the light-emitting device having the above structure is fixed to a sealing substrate 407 with a sealing material 405 and a sealing material 406 and sealing is performed, whereby the lighting device is completed. It is possible to use only either the sealing material 405 or the sealing material 406. The inner sealing material 406 (not illustrated in FIG. 12B) can be mixed with a desiccant that enables moisture to be adsorbed, which results in improved reliability.

When parts of the pad 412 and the first electrode 401 are extended to the outside of the sealing material 405 and the sealing material 406, the extended parts can serve as external input terminals. An IC chip 420 mounted with a converter or the like may be provided over the external input terminals, for example.

The lighting device described in this embodiment includes the light-emitting device described in any one of Embodiment 2 to Embodiment 6 as an EL element, and thus can be a lighting device with low power consumption.

### Embodiment 12

In this embodiment, examples of electronic devices each partly including the light-emitting device described in any one of Embodiment 2 to Embodiment 6 will be described. The light-emitting device described in any one of Embodiment 2 to Embodiment 6 has high emission efficiency and low power consumption. As a result, the electronic devices described in this embodiment can each include a light-emitting portion having low power consumption.

Examples of the electronic device including the above light-emitting device include television devices (also referred to as TV or television receivers), monitors for computers and the like, digital cameras, digital video cameras, digital photo frames, cellular phones (also referred to as mobile phones or mobile phone devices), portable game machines, portable information terminals, audio playback devices, and large game machines such as pachinko machines. Specific examples of these electronic devices are shown below.

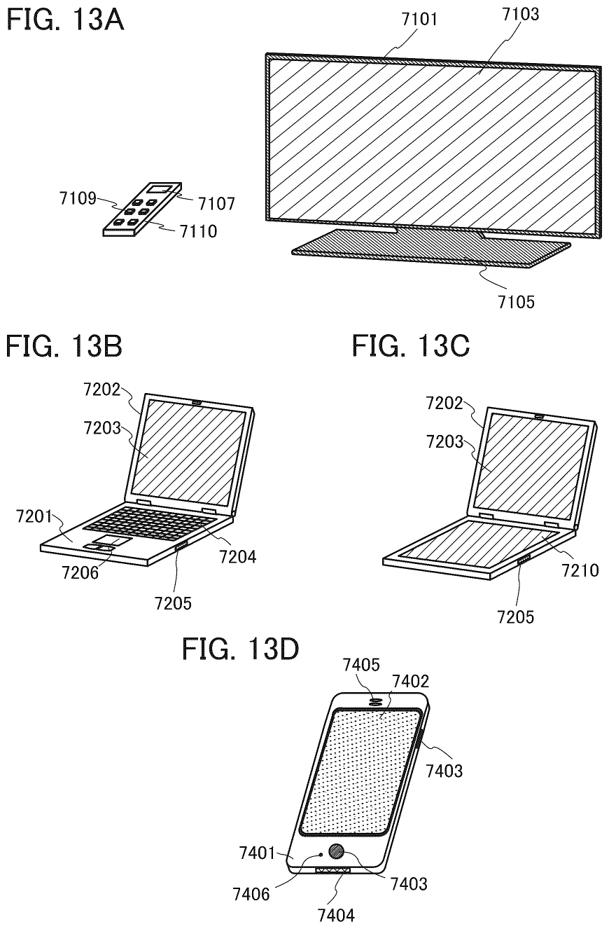

FIG. 13A shows an example of a television device. In the television device, a display portion 7103 is incorporated in a housing 7101. Here, the housing 7101 is supported by a stand 7105. Images can be displayed on the display portion 7103, and in the display portion 7103, the light-emitting devices described in any one of Embodiment 2 to Embodiment 6 are arranged in a matrix.

The television device can be operated with an operation switch of the housing 7101 or a separate remote controller 7110. With operation keys 7109 of the remote controller 7110, channels or volume can be controlled and images displayed on the display portion 7103 can be controlled. Furthermore, the remote controller 7110 may be provided with a display portion 7107, on which information output from the remote controller 7110 may be displayed.

Note that the television device is provided with a receiver, a modem, or the like. With use of the receiver, a general television broadcast can be received. Moreover, when the television device is connected to a communication network with or without wires via the modem, one-way (from a sender to a receiver) or two-way (between a sender and a receiver or between receivers) data communication can be performed.

FIG. 13B illustrates a computer, which includes a main body 7201, a housing 7202, a display portion 7203, a keyboard 7204, an external connection port 7205, a pointing device 7206, and the like. Note that this computer is fabricated using the light-emitting devices described in any one of Embodiment 2 to Embodiment 6 and arranged in a matrix in the display portion 7203. The computer in FIG. 13B may have a structure illustrated in FIG. 13C. A computer in FIG. 13C is provided with a second display portion 7210 instead of the keyboard 7204 and the pointing device 7206. The second display portion 7210 is a touch panel, and input operation can be performed by touching display for input displayed on the second display portion 7210 with a finger or a dedicated pen. The second display portion 7210 can also display images other than the display for input. The display portion 7203 may also be a touch panel. Connecting the two screens with a hinge can prevent troubles; for example, the screens can be prevented from being cracked or broken while the computer is being stored or carried.

FIG. 13D shows an example of a portable terminal. The portable terminal is provided with a display portion 7402 incorporated in a housing 7401, operation buttons 7403, an external connection port 7404, a speaker 7405, a microphone 7406, and the like. Note that the portable terminal has the display portion 7402 fabricated by arranging the light-emitting devices described in any one of Embodiment 2 to Embodiment 6 in a matrix.

When the display portion 7402 of the portable terminal illustrated in FIG. 13D is touched with a finger or the like, data can be input into the portable terminal. In this case, operations such as making a call and creating an e-mail can be performed by touching the display portion 7402 with a finger or the like.

The display portion 7402 has mainly three screen modes. The first mode is a display mode mainly for displaying images. The second mode is an input mode mainly for inputting information such as text. The third mode is a display-and-input mode in which the two modes, the display mode and the input mode, are combined.

For example, in the case of making a call or creating an e-mail, a text input mode mainly for inputting text is selected for the display portion 7402 so that text displayed on the screen can be input. In this case, it is preferable to display a keyboard or number buttons on almost the entire screen of the display portion 7402.

When a sensing device including a sensor such as a gyroscope sensor or an acceleration sensor for detecting inclination is provided inside the portable terminal, display on the screen of the display portion 7402 can be automatically changed in direction by determining the orientation of the portable terminal (whether the portable terminal is placed horizontally or vertically).

The screen modes are switched by touching the display portion 7402 or operating the operation buttons 7403 of the housing 7401. Alternatively, the screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed for a certain period while a signal sensed by an optical sensor in the display portion 7402 is sensed, the screen mode may be controlled so as to be switched from the input mode to the display mode.

The display portion 7402 may also function as an image sensor. For example, an image of a palm print, a fingerprint, or the like is taken when the display portion 7402 is touched with the palm or the finger, whereby personal authentication can be performed. Furthermore, by providing a backlight which emits near-infrared light or a sensing light source which emits near-infrared light in the display portion, an image of a finger vein, a palm vein, or the like can be taken.

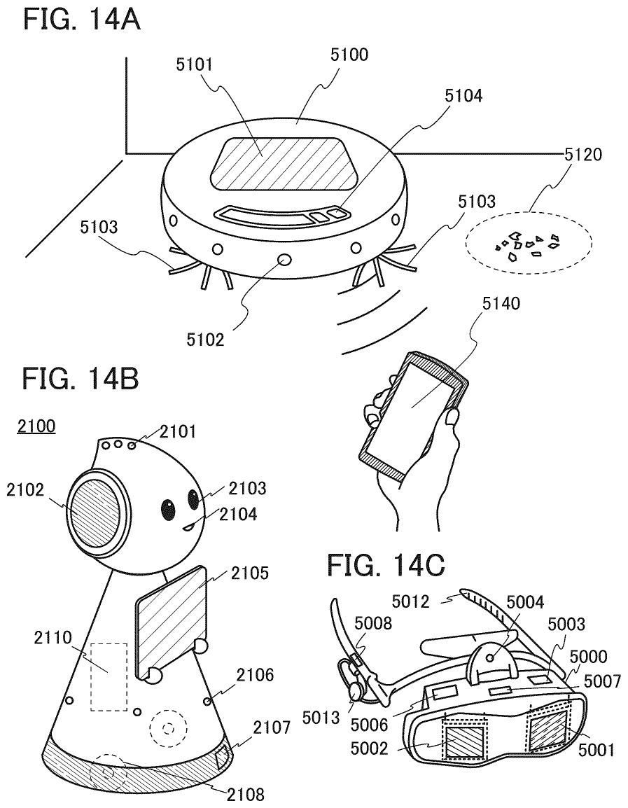

FIG. 14A is a schematic view showing an example of a cleaning robot.

A cleaning robot 5100 includes a display 5101 on its top surface, a plurality of cameras 5102 on its side surface, a brush 5103, and operation buttons 5104. Although not illustrated, the bottom surface of the cleaning robot 5100 is provided with a tire, an inlet, and the like. Furthermore, the cleaning robot 5100 includes various sensors such as an infrared sensor, an ultrasonic sensor, an acceleration sensor, a piezoelectric sensor, an optical sensor, and a gyroscope sensor. The cleaning robot 5100 has a wireless communication means.

The cleaning robot 5100 is self-propelled, detects dust 5120, and sucks up the dust through the inlet provided on the bottom surface.

The cleaning robot 5100 can determine whether there is an obstacle such as a wall, furniture, or a step by analyzing images taken by the cameras 5102. When the cleaning robot 5100 detects an object that is likely to be caught in the brush 5103, such as a wire, by image analysis, the rotation of the brush 5103 can be stopped.

The display 5101 can display the remaining capacity of a battery, the amount of collected dust, or the like. The display 5101 may display a path on which the cleaning robot 5100 has run. The display 5101 may be a touch panel, and the operation buttons 5104 may be provided on the display 5101.

The cleaning robot 5100 can communicate with a portable electronic device 5140 such as a smartphone. The portable electronic device 5140 can display images taken by the cameras 5102. Accordingly, an owner of the cleaning robot 5100 can monitor his/her room even when the owner is not at home. The owner can also check the display on the display 5101 by the portable electronic device 5140 such as a smartphone.

The light-emitting apparatus of one embodiment of the present invention can be used for the display 5101.

A robot 2100 illustrated in FIG. 14B includes an arithmetic device 2110, a microphone 2102, an upper camera 2103, a speaker 2104, a display 2105, a lower camera 2106, an obstacle sensor 2107, and a moving mechanism 2108.

The microphone 2102 has a function of detecting a speaking voice of a user, an environmental sound, and the like. The speaker 2104 also has a function of outputting sound. The robot 2100 can communicate with a user using the microphone 2102 and the speaker 2104.

The display 2105 has a function of displaying various kinds of information. The robot 2100 can display information desired by a user on the display 2105. The display 2105 may be provided with a touch panel. Moreover, the display 2105 may be a detachable information terminal, in which case charging and data communication can be performed when the display 2105 is set at the home position of the robot 2100.

The upper camera 2103 and the lower camera 2106 each have a function of taking an image of the surroundings of the robot 2100. The obstacle sensor 2107 can detect an obstacle in the direction where the robot 2100 advances with the moving mechanism 2108. The robot 2100 can move safely by recognizing the surroundings with the upper camera 2103, the lower camera 2106, and the obstacle sensor 2107. The light-emitting apparatus of one embodiment of the present invention can be used for the display 2105.

FIG. 14C shows an example of a goggles-type display. The goggles-type display includes, for example, a housing 5000, a display portion 5001, a speaker 5003, an LED lamp 5004, operation keys (including a power switch or an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 5008, a display portion 5002, a support 5012, and an earphone 5013.

The light-emitting apparatus of one embodiment of the present invention can be used for the display portion 5001 and the display portion 5002.

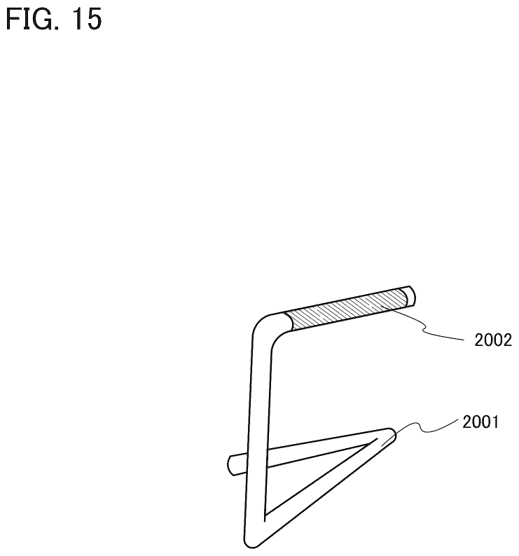

FIG. 15 shows an example in which the light-emitting device described in any one of Embodiment 2 to Embodiment 6 is used for a table lamp which is a lighting device. The table lamp illustrated in FIG. 15 includes a housing 2001 and a light source 2002, and the lighting device described in Embodiment 11 may be used for the light source 2002.

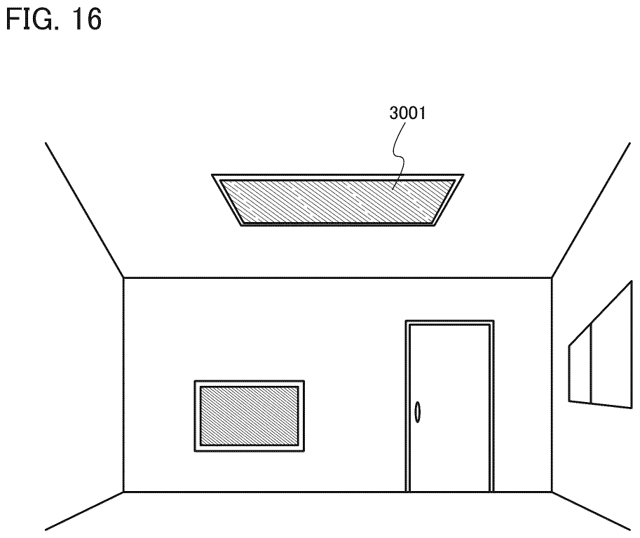

FIG. 16 shows an example in which the light-emitting device described in any one of Embodiment 2 to Embodiment 6 is used for an indoor lighting device 3001. Since the light-emitting device described in any one of Embodiment 2 to Embodiment 6 has high emission efficiency, the lighting device can have low power consumption. Furthermore, since the light-emitting device described in any one of Embodiment 2 to Embodiment 6 can have a large area, the light-emitting device can be used for a large-area lighting device. Furthermore, since the light-emitting device described in any one of Embodiment 2 to Embodiment 6 is thin, the light-emitting device can be used for a thin lighting device.

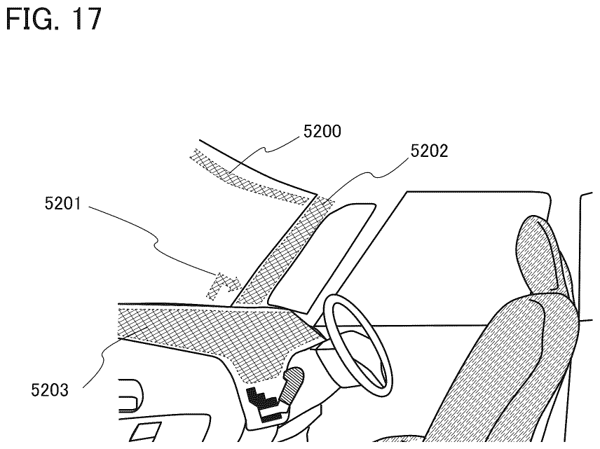

The light-emitting device described in any one of Embodiment 2 to Embodiment 6 can also be used for an automobile windshield or an automobile dashboard. FIG. 17 illustrates one mode in which the light-emitting device described in any one of Embodiment 2 to Embodiment 6 is used for an automobile windshield or an automobile dashboard. A display region 5200 to a display region 5203 each include the light-emitting device described in any one of Embodiment 2 to Embodiment 6.

The display region 5200 and the display region 5201 are display apparatuses which are provided in the automobile windshield and in which the light-emitting device described in any one of Embodiment 2 to Embodiment 6 is incorporated. When the light-emitting device described in any one of Embodiment 2 to Embodiment 6 is manufactured using electrodes having light-transmitting properties as a first electrode and a second electrode, what is called a see-through display apparatus, through which the opposite side can be seen, can be obtained. Such a see-through display apparatus can be provided even in the automobile windshield without hindering the view. In the case where a driving transistor or the like is provided, a transistor having a light-transmitting property, such as an organic transistor including an organic semiconductor material or a transistor including an oxide semiconductor, is preferably used.

The display region 5202 is a display apparatus provided in a pillar portion, in which the light-emitting device described in any one of Embodiment 2 to Embodiment 6 is incorporated. The display region 5202 can compensate for the view hindered by the pillar by displaying an image taken by an imaging unit provided in the car body. Similarly, the display region 5203 provided in the dashboard portion can compensate for the view hindered by the car body by displaying an image taken by an imaging unit provided on the outside of the automobile. Thus, blind areas can be eliminated to enhance the safety. Images that compensate for the areas which a driver cannot see enable the driver to ensure safety easily and comfortably.

The display region 5203 can provide a variety of kinds of information by displaying navigation data, speed, a tachometer, a mileage, a fuel level, a gearshift state, air-condition setting, and the like. The content or layout of the display can be changed freely by a user as appropriate. Note that such information can also be displayed on the display region 5200 to the display region 5202. The display region 5200 to the display region 5203 can also be used as lighting devices.

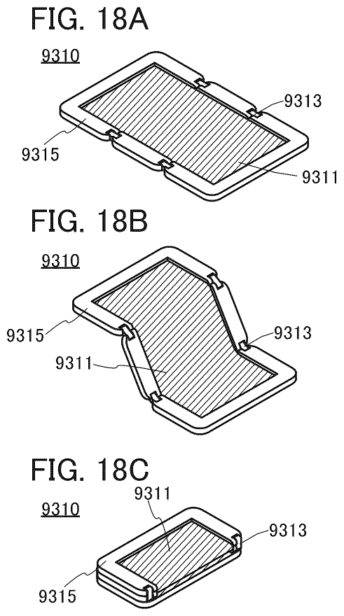

FIG. 18A to FIG. 18C illustrate a foldable portable information terminal 9310. FIG. 18A illustrates the portable information terminal 9310 that is opened. FIG. 18B illustrates the portable information terminal 9310 in the middle of change from one of an opened state and a folded state to the other. FIG. 18C illustrates the portable information terminal 9310 that is folded. The portable information terminal 9310 is highly portable when folded. The portable information terminal 9310 is highly browsable when opened because of a seamless large display region.

A display panel 9311 is supported by three housings 9315 joined together by hinges 9313. Note that the display panel 9311 may be a touch panel (an input/output device) including a touch sensor (an input device). By folding the display panel 9311 at the hinges 9313 between two housings 9315, the portable information terminal 9310 can be reversibly changed in shape from the opened state to the folded state. The light-emitting apparatus of one embodiment of the present invention can be used for the display panel 9311.

Note that the structure described in this embodiment can be combined with any of the structures described in Embodiment 2 to Embodiment 6 as appropriate.

As described above, the application range of the light-emitting apparatus including the light-emitting device described in any one of Embodiment 2 to Embodiment 6 is wide, and thus the light-emitting apparatus can be applied to electronic devices in a variety of fields. By using the light-emitting device described in any one of Embodiment 2 to Embodiment 6, an electronic device with low power consumption can be obtained.

Note that this embodiment can be combined with any of the other embodiments described in this specification as appropriate.

### Example 1

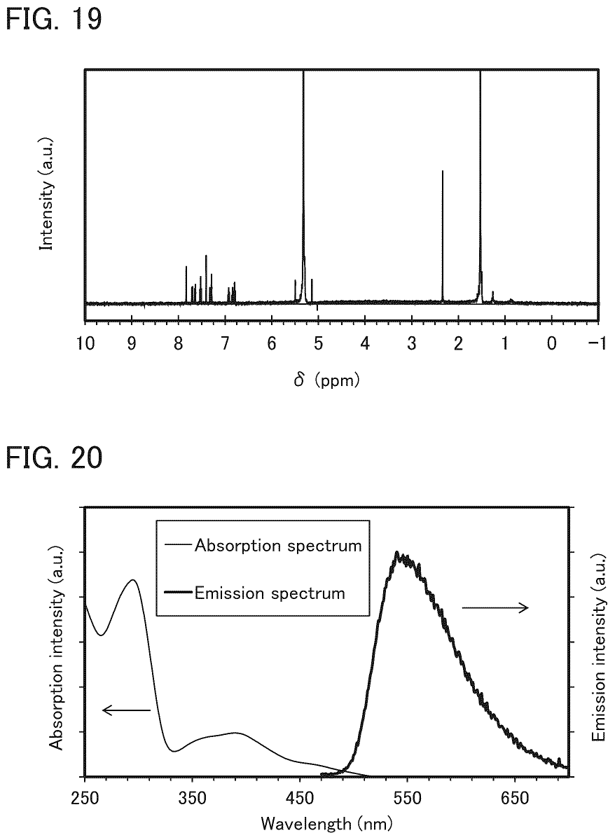

In this example, physical properties and synthesis examples of the organic compounds of embodiments of the present invention will be described with reference to FIG. 19 to FIG. 26.

FIG. 19 shows measurement results of a ¹H NMVR spectrum of Ir(mppy-3CP)₃.

FIG. 20 shows measurement results of an absorption spectrum and an emission spectrum of Ir(mppy-3CP)₃ in a dichloromethane solution.

FIG. 21 shows measurement results of a ¹H NMR spectrum of Ir(mppy-dmCP)₃.

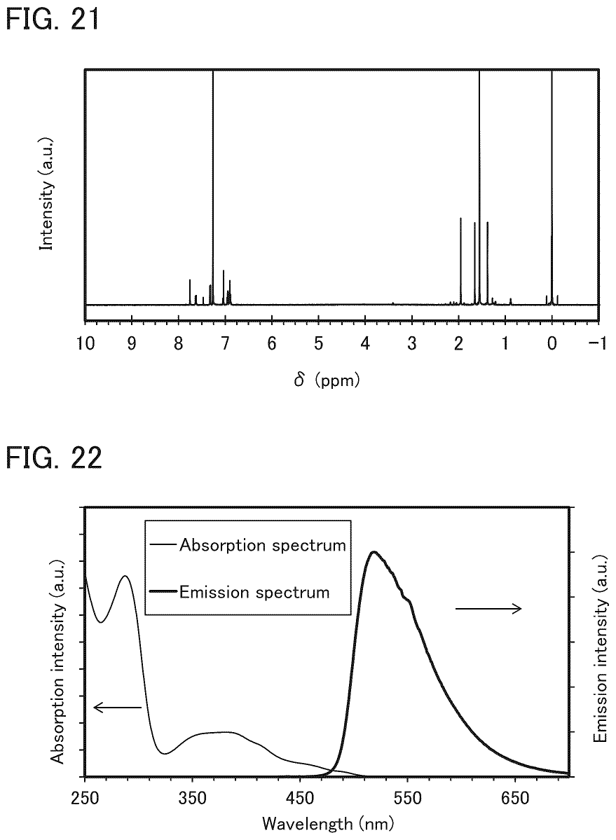

FIG. 22 shows measurement results of an absorption spectrum and an emission spectrum of Ir(mppy-dmCP)₃ in a dichloromethane solution.

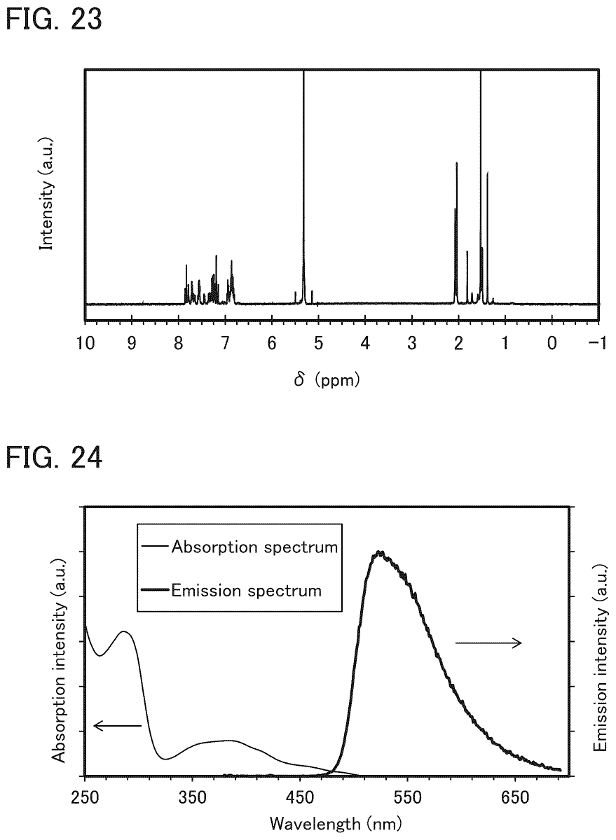

FIG. 23 shows measurement results of a ¹H NMR spectrum of Ir(mppy-m5CP)₃.

FIG. 24 shows measurement results of an absorption spectrum and an emission spectrum of Ir(mppy-m5CP)₃ in a dichloromethane solution.

FIG. 25 shows measurement results of a ¹H NMR spectrum of Ir(ppy-m5CP)₃.

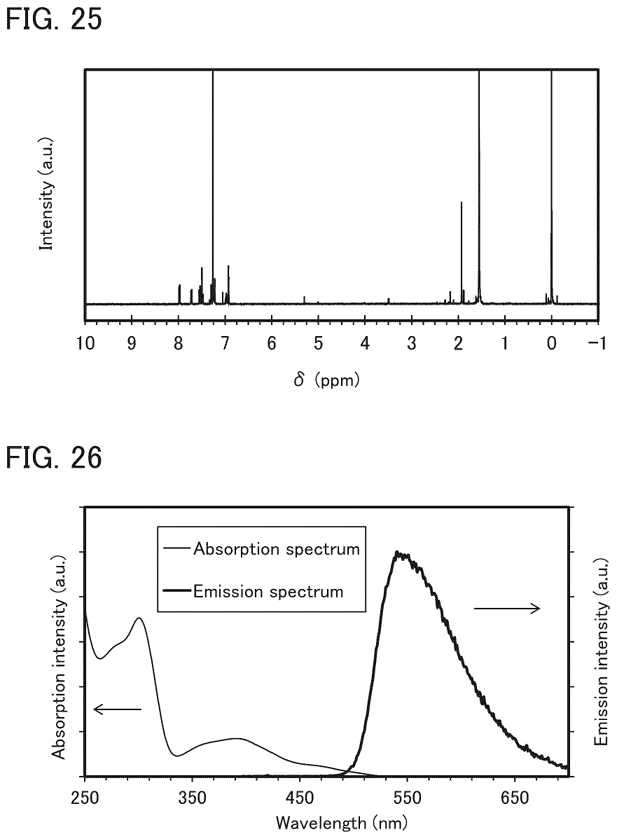

FIG. 26 shows measurement results of an absorption spectrum and an emission spectrum of Ir(ppy-m5CP)₃ in a dichloromethane solution.

### Synthesis Example 1

Synthesis example 1 describes an example of a method for synthesizing tris[2-(4-methyl-5-(3-cyanophenyl)-2-pyridinyl-κN)phenyl-κC]iridium(III) (abbreviation: Ir(mppy-3CP)₃) represented by Structural Formula (136) in Embodiment 1.

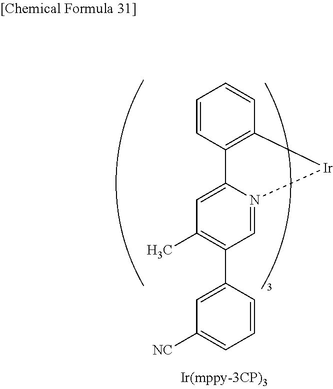

### Step 1; Synthesis of 4-methyl-2-phenyl-5-(3-cyanophenyl)pyridine (abbreviation: Hmppy-3CP)

2.36 g of 5-bromo-4-methyl-2-phenylpyridine, 1.77 g of 3-cyanophenylboronic acid, 2.54 g of tripotassium phosphate, 35 mL of toluene, and 3.5 mL of water were put into a three-neck flask equipped with a reflux pipe, and the air in the flask was replaced with nitrogen. The mixture in the flask was degassed by being stirred under reduced pressure, and then, 0.089 g of tris(dibenzylideneacetone)dipalladium(0) (abbreviation: Pd₂(dba)₃) and 0.16 g of 2-dicyclohexylphosphino-2′,6′-dimethoxybiphenyl (abbreviation: S-Phos) were added thereto. The mixture reacted at 110° C. for 7.5 hours while being stirred. Synthesis Scheme (1a) of Step 1 is shown below.

After a predetermined time elapsed, the solvent was distilled off, water was added, and a target substance was extracted with use of toluene. The residue obtained by distilling off toluene from the extracted solution was separated by a silica gel column chromatography method using a mixed solvent of hexane and ethyl acetate (hexane:ethyl acetate=5:1) as a mobile phase, and then the mobile phase was distilled off, whereby 2.43 g of a pyridine derivative was obtained as a white solid (yield: 92%).

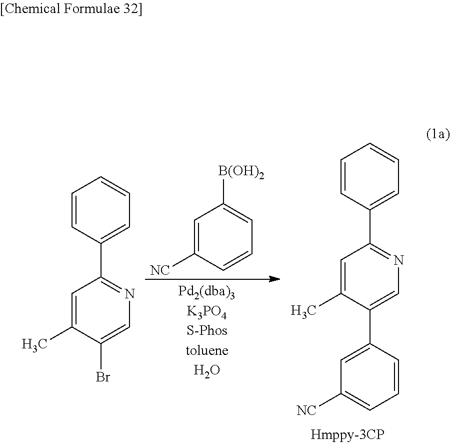

### Step 2; Synthesis of tris[2-(4-methyl-5-(3-cyanophenyl)-2-pyridinyl-κN)phenyl-κC]iridium(III) (abbreviation: Ir(mppy-3CP)₃))

2.42 g of 4-methyl-2-phenyl-5-(3-cyanophenyl)pyridine (abbreviation: Hmppy-3CP) obtained in Step 1 above and 0.88 g of tris(2,4-pentanedionato)iridium(III) (abbreviation: Ir(acac)₃) were put into a reaction container equipped with a three-way cock, and the air in the reaction container was replaced with argon. The mixture reacted at 250° C. for 71 hours while being stirred. Synthesis Scheme (1b) of Step 2 is shown below.

After a predetermined time elapsed, the obtained solid was separated by a silica gel column chromatography method using dichloromethane as a mobile phase. Moreover, from a mixed solution of dichloromethane, methanol, and the solid obtained by distilling off the mobile phase, 0.22 g of a yellow solid (yield: 12%) was obtained by a recrystallization method. By a train sublimation method, 0.22 g of the yellow solid was sublimated and purified, whereby 0.15 g of a target substance was obtained as a yellow solid (yield: 68%). Note that the conditions of the sublimation purification were such that the pressure was 2.7 Pa, the flow rate of an argon gas was 10.5 mL/min, and the heating temperature was 370° C.

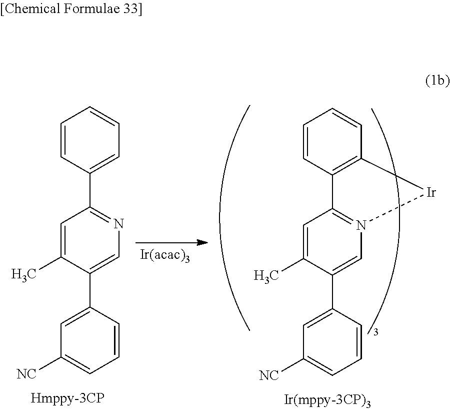

Measurement results obtained by nuclear magnetic resonance spectroscopy (¹H-NMR) revealed that the yellow solid obtained in Step 2 above is Ir(mppy-3CP)₃). A ¹H-NMR chart is shown in FIG. 19 and analysis results are shown below.

¹H-NMR. δ (CD₂Cl₂): 2.34 (s, 9H), 6.79 (d, 3H), 6.84 (t, 3H), 6.92 (t, 3H), 7.29 (s, 3H), 7.32 (d, 3H), 7.41 (s, 3H), 7.52 (t, 3H), 7.64 (d, 3H), 7.71 (d, 3H), 7.83 (s, 3H).

FIG. 20 shows measurement results of an ultraviolet-visible absorption spectrum (hereinafter, simply referred to as an “absorption spectrum”) of a dichloromethane solution containing Ir(mppy-3CP)₃ and an emission spectrum thereof. The horizontal axis represents wavelength, and the vertical axis represents absorption intensity and emission intensity. Ir(mppy-3CP)₃ has an emission peak at 540 nm, and green light emission was observed from dichloromethane. The absorption spectrum shown in FIG. 20 is the result obtained in such away that the absorption spectrum measured by putting only dichloromethane in a quartz cell was subtracted from the absorption spectrum measured by putting the dichloromethane solution (0.010 mmol/L) in a quartz cell.

The measurement of the absorption spectrum was conducted at room temperature, for which an ultraviolet-visible spectrophotometer (V550 type produced by JASCO Corporation) was used and the dichloromethane solution (0.010 mmol/L) was put in a quartz cell.

The measurement of the emission spectrum was conducted at room temperature, for which a fluorescence spectrophotometer (FS920 produced by Hamamatsu Photonics K.K.) was used and the deoxidized dichloromethane solution (0.010 mmol/L) was put and sealed in a quartz cell under a nitrogen atmosphere in a glove box (LABstar M13 (1250/780) produced by Bright Co., Ltd.).

Ir(mppy-3CP)₃ has a methyl group at R¹⁰⁷ of a pyridine ring. The methyl group inhibits free rotation of a phenyl group into which a cyano group is introduced. Thus, Ir(mppy-3CP)₃ exhibits an excellent thermophysical property. Furthermore, the width of the emission spectrum is narrowed to increase the color purity of an emission color. In addition, the organic compound can be suitably used as a green light-emitting material.

### Synthesis Example 2

Synthesis example 2 describes an example of a method for synthesizing tris[2-(4-methyl-5-(4-cyano-2,6-dimethylphenyl)-2-pyridinyl-κN)phenyl-κC]iridium(III) (abbreviation: Ir(mppy-dmCP)₃) represented by Structural Formula (104) in Embodiment 1.

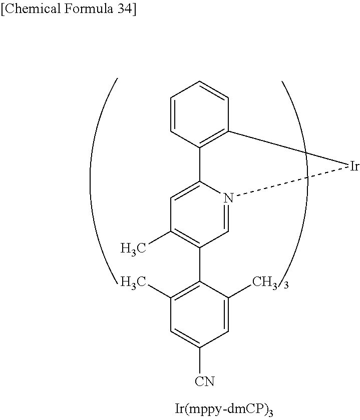

### Step 1; Synthesis of 5-bromo-4-methyl-2-phenylpyridine>

15.87 g of 2,5-dibromo-4-methylpyridine, 9.27 g of phenylboronic acid, 23.51 g of potassium carbonate, 530 mL of acetonitrile, and 265 mL of methanol were put into a three-neck flask equipped with a reflux pipe, and the air in the flask was replaced with nitrogen. The mixture in the flask was degassed by being stirred under reduced pressure, and then, 0.56 g of dipalladium(II) acetate (abbreviation: Pd(OAc)₂) and 1.65 g of triphenylphosphine (abbreviation: PPh₃) were added thereto. The mixture reacted at 50° C. for 19.5 hours while being stirred. Synthesis Scheme (2a) of Step 1 is shown below.

After a predetermined time elapsed, the solvent was distilled off, water was added, and a target substance was extracted with use of dichloromethane. The residue obtained by distilling off dichloromethane from the extracted solution was separated by a silica gel column chromatography method using a mixed solvent of hexane and ethyl acetate (hexane:ethyl acetate 10:1) as a mobile phase, and then the mobile phase was distilled off, whereby 13.40 g of a pyridine derivative was obtained as a colorless oily substance (yield: 85%).

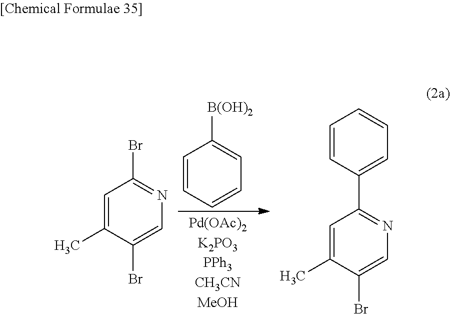

### Step 2; Synthesis of 4-methyl-2-phenyl-5-(4-cyano-2,6-dimethylphenyl)pyridine (abbreviation: Hmppy-dmCP)

3.25 g of 5-bromo-4-methyl-2-phenylpyridine obtained in Step 1 above, 4.09 g of 3,5-dimethyl-4-(4,4,5,5-tetramethyl-1,3,2-dioxaborolan-2-yl)benzonitrile, 10.96 g of tripotassium phosphate, 4.13 g of 2-dicyclohexylphosphino-2′,6′-dimethoxybiphenyl (abbreviation: S-Phos), and 160 mL of toluene were put into a three-neck flask equipped with a reflux pipe, and the air in the flask was replaced with nitrogen. The mixture in the flask was degassed by being stirred under reduced pressure, and then, 2.25 g of tris(dibenzylideneacetone)dipalladium(0) (abbreviation: Pd₂(dba)₃) was added thereto. The mixture reacted at 130° C. for 15 hours while being stirred. Synthesis Scheme (2b) of Step 2 is shown below.

After a predetermined time elapsed, the obtained mixture was suction-filtered. The residue obtained by distilling off dichloromethane from the filtrate was separated by a silica gel column chromatography method using a mixed solvent of hexane and ethyl acetate (hexane:ethyl acetate=10:1) as a mobile phase, and then the mobile phase was distilled off, whereby 2.18 g of a pyridine derivative was obtained as a yellowish white solid (yield: 55%).

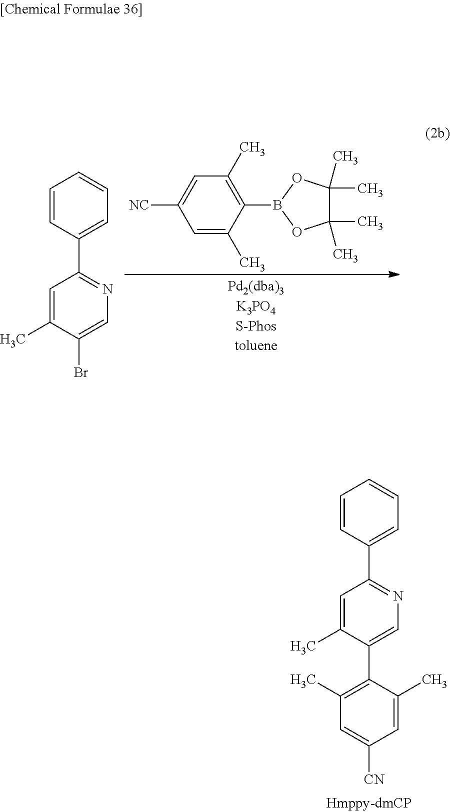

### Step 3; Synthesis of di-p-chloro-tetrakis[2-(4-methyl-5-(4-cyano-2,6-dimethylphenyl)-2-pyridinyl-κN)phenyl-κC]diiridium(III) (abbreviation: [Ir(mppy-dmCP)₂Cl]₂)

15 mL of 2-ethoxyethanol, 5 mL of water, 2.01 g of 4-methyl-2-phenyl-5-(4-cyano-2,6-dimethylphenyl)pyridine (abbreviation: Hmppy-dmCP) obtained in Step 2, and 0.99 g of iridium chloride hydrate (IrCl₃·H₂O) (produced by Furuya Metal Co., Ltd.) were put into a recovery flask equipped with a reflux pipe, and the air in the flask was replaced with argon. Then, the flask was irradiated with a microwave of 2.45 GHz for two hours at an output of 100 W to cause reaction. Synthesis Scheme (2c) of Step 3 is shown below.

After a predetermined time elapsed, the obtained residue was washed with methanol while being suction-filtered, whereby 1.82 g of a dinuclear complex, which is di-μ-chloro-tetrakis[2-(4-methyl-5-(4-cyano-2,6-dimethylphenyl)-2-pyridinyl-κN)phenyl-κC]diiridium(III) (abbreviation: [Ir(mppy-dmCP)₂Cl]₂), was obtained as a yellow solid (yield: 67%).

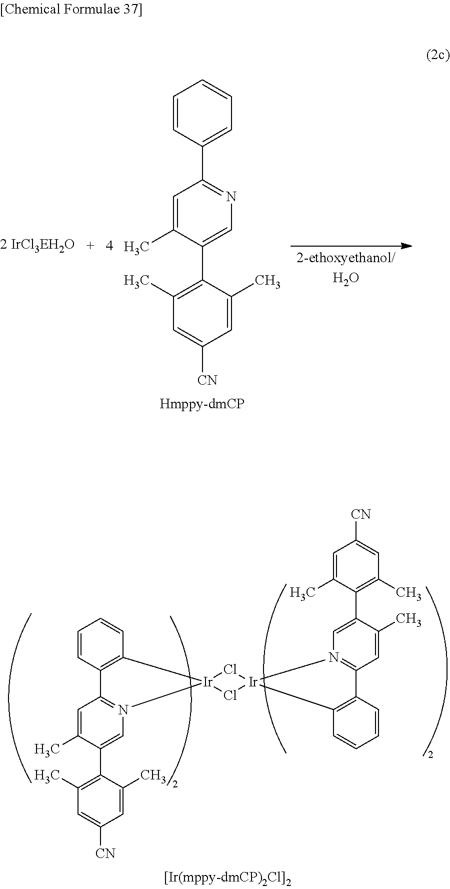

### Step 4; Synthesis of tris[2-(4-methyl-5-(4-cyano-2,6-dimethylphenyl)-2-pyridinyl-κN)phenyl-κC]iridium(III) (abbreviation: Ir(mppy-dmCP)₃)

1.82 g of di-w-chloro-tetrakis[2-(4-methyl-5-(4-cyano-2,6-dimethylphenyl)-2-pyridinyl-κN)phenyl-C(]diiridium(III) (abbreviation: [Ir(mppy-dmCP)₂Cl]₂) obtained in Step 3, 1.70 g of 4-methyl-2-phenyl-5-(4-cyano-2,6-dimethylphenyl)pyridine (abbreviation: Hmppy-dmCP) obtained in Step 2, 1.51 g of potassium carbonate, and 8 g of phenol were put into a three-neck flask equipped with a reflux pipe, and the air in the flask was replaced with nitrogen. After that, the mixture reacted at 185° C. for 24 hours while being stirred. Synthesis Scheme (2d) of Step 4 is shown below.

After a predetermined time elapsed, the obtained mixture was washed with water and methanol while being suction-filtered. The obtained solid was separated by a silica gel column chromatography method using dichloromethane as a mobile phase. Moreover, from a mixed solution of dichloromethane, methanol, and the solid obtained by distilling off the mobile phase, 0.16 g of a yellow solid (yield: 7%) was obtained by a recrystallization method. By a train sublimation method, 0.16 g of the yellow solid was sublimated and purified, whereby 0.10 g of a target substance was obtained as a yellow solid (yield: 63%). Note that the conditions of the sublimation purification were such that the pressure was 2.6 Pa, the flow rate of an argon gas was 11 mL/min, and the heating temperature was 360° C.

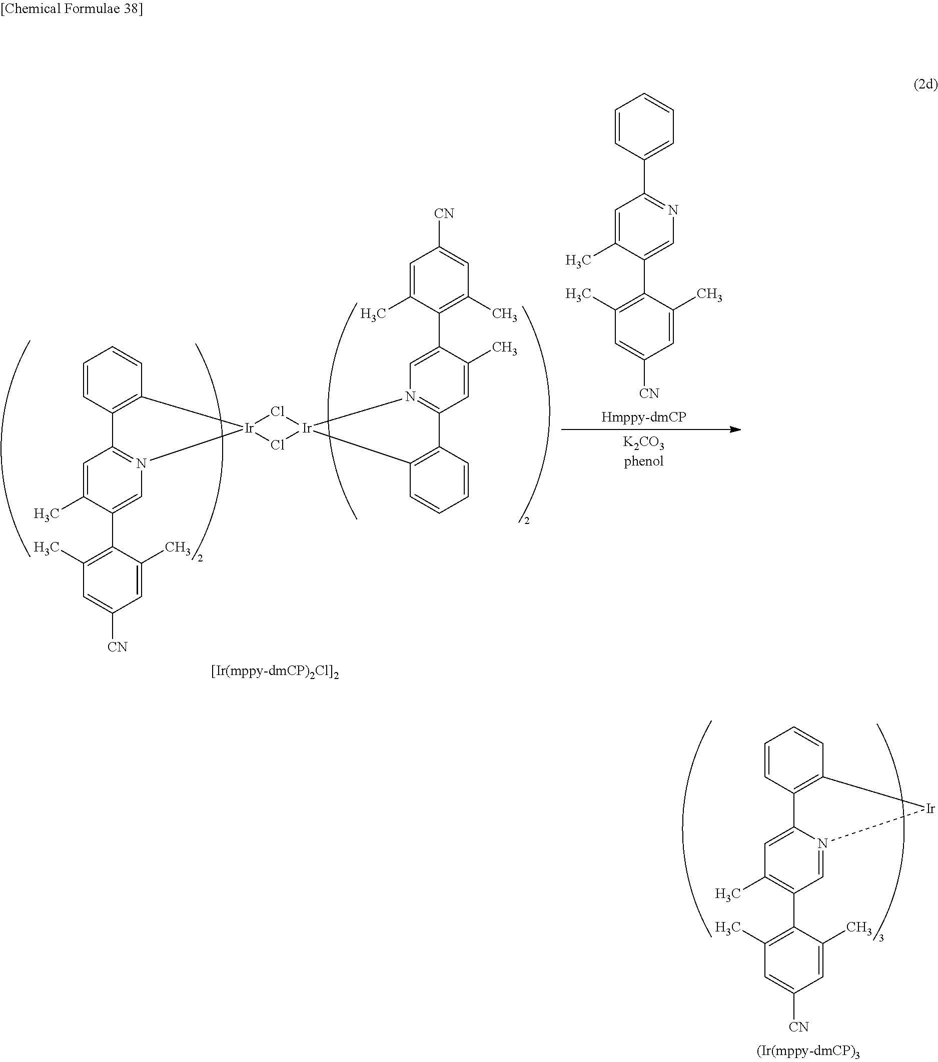

Measurement results obtained by nuclear magnetic resonance spectroscopy (¹H-NMR) revealed that the yellow solid obtained in Step 4 above is Ir(mppy-dmCP)₃. A ¹H-NMR chart is shown in FIG. 21 and analysis results are shown below.

¹H-NMR. δ (CDCl₃): 1.38 (s, 9H), 1.65 (s, 9H), 1.96 (s, 9H), 6.88-6.96 (m, 9H), 7.30 (s, 3H), 7.32 (d, 6H), 7.63 (d, 3H), 7.75 (s, 3H).

FIG. 22 shows measurement results of an ultraviolet-visible absorption spectrum of a dichloromethane solution containing Ir(mppy-dmCP)₃ and an emission spectrum thereof. The horizontal axis represents wavelength, and the vertical axis represents absorption intensity and emission intensity. Ir(mppy-dmCP)₃ has an emission peak at 519 nm, and green light emission was observed from dichloromethane. The absorption spectrum shown in FIG. 22 is the result obtained in such a way that the absorption spectrum measured by putting only dichloromethane in a quartz cell was subtracted from the absorption spectrum measured by putting the dichloromethane solution (0.0105 mmol/L) in a quartz cell.

The measurement of the absorption spectrum was conducted at room temperature, for which an ultraviolet-visible spectrophotometer (V550 type produced by JASCO Corporation) was used and the dichloromethane solution (0.0105 mmol/L) was put in a quartz cell.

The measurement of the emission spectrum was conducted at room temperature, for which an absolute PL quantum yield measurement system (C11347-01 produced by Hamamatsu Photonics K.K.) was used and the deoxidized dichloromethane solution (0.0105 mmol/L) was put and sealed in a quartz cell under a nitrogen atmosphere in a glove box (LABstar M13 (1250/780) produced by Bright Co., Ltd.).

Ir(mppy-dmCP)₃ has the methyl group at the two ortho-positions (R¹⁰² and R¹⁰⁶) of the phenyl group into which the cyano group is introduced at R¹⁰⁴ in General Formula (G0) shown in Embodiment 1. Ir(mppy-dmCP)₃ has another methyl group at R¹⁰⁷ of the pyridine ring. These three methyl groups very strongly inhibit free rotation of the phenyl group. Thus, Ir(mppy-dmCP)₃ exhibits an excellent thermophysical property. Furthermore, the width of the emission spectrum is narrowed to increase the color purity of an emission color. In addition, the organic compound can be suitably used as a green light-emitting material.

### Synthesis Example 3

Synthesis example 3 describes a method for synthesizing tris[2-(4-methyl-5-(5-cyano-2-methylphenyl)-2-pyridinyl-κN)phenyl-κC]iridium(III) (abbreviation: Ir(mppy-m5CP)₃), which is the organometallic complex of the present invention represented by Structural Formula (137) in Embodiment 1.

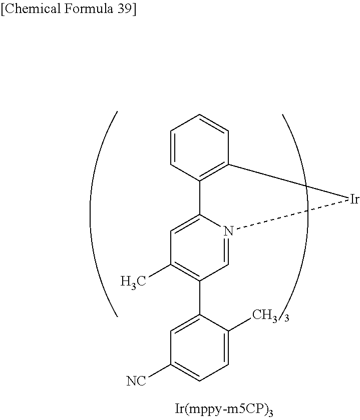

### Step 1; Synthesis of 4-methyl-2-phenyl-5-(5-cyano-2-methylphenyl)pyridine (abbreviation: Hmppy-3CP)

2.31 g of 5-bromo-4-methyl-2-phenylpyridine, 2.23 g of 5-cyano-2-phenylboronic acid, 7.88 g of tripotassium phosphate, and 115 mL of toluene were put into a three-neck flask equipped with a reflux pipe, and the air in the flask was replaced with nitrogen. The mixture in the flask was degassed by being stirred under reduced pressure, and then, 1.08 g of tris(dibenzylideneacetone)dipalladium(0) (abbreviation: Pd₂(dba)₃) and 2.01 g of 2-dicyclohexylphosphino-2′,6′-dimethoxybiphenyl (abbreviation: S-Phos) were added thereto. The mixture reacted at 130° C. for 7.5 hours while being stirred. Synthesis Scheme (3a) of Step 1 is shown below.

After a predetermined time elapsed, the solvent was distilled off, water was added, and a target substance was extracted with use of toluene. The residue obtained by distilling off toluene from the extracted solution was separated by a silica gel column chromatography method using a mixed solvent of toluene and ethyl acetate (toluene:ethyl acetate=30:1) as a mobile phase, and then the mobile phase was distilled off, whereby 2.12 g of a pyridine derivative was obtained as a yellow oily substance (yield: 80%).

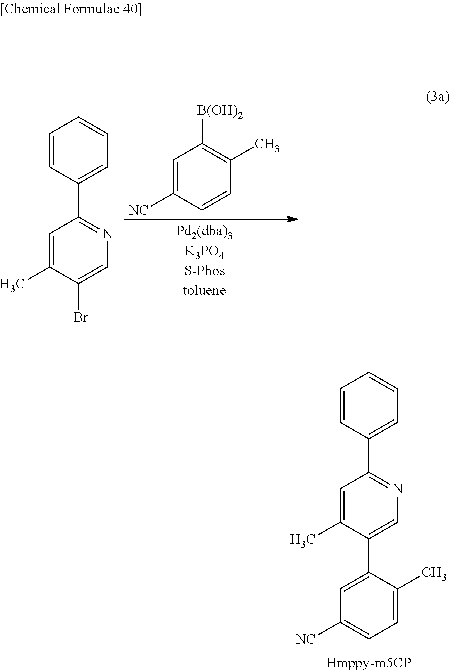

### Step 2; Synthesis of tris[2-(4-methyl-5-(5-cyano-2-methylphenyl)-2-pyridinyl-κN)phenyl-κC]iridium(I) (abbreviation: Ir(mppy-m5CP)₃))

2.42 g of 4-methyl-2-phenyl-5-(5-cyano-2-methylphenyl)pyridine (abbreviation: Hmppy-m5CP) obtained in Step 1 above and 0.88 g of tris(2,4-pentanedionato)iridium(III) (abbreviation: Ir(acac)₃) were put into a reaction container equipped with a three-way cock, and the air in the reaction container was replaced with argon. The mixture reacted at 250° C. for 67.5 hours while being stirred. Synthesis Scheme (3b) of Step 2 is shown below.

After a predetermined time elapsed, the obtained solid was separated by a silica gel column chromatography method using dichloromethane as a mobile phase. Moreover, from a mixed solution of dichloromethane, methanol, and the solid obtained by distilling off the mobile phase, 0.24 g of a yellow solid (yield: 19%) was obtained by a recrystallization method. By a train sublimation method, 0.24 g of the yellow solid was sublimated and purified, whereby 0.18 g of a target substance was obtained as a yellow solid (yield: 75%). Note that the conditions of the sublimation purification were such that the pressure was 2.6 Pa, the flow rate of an argon gas was 11 mL/min, and the heating temperature was 375° C.

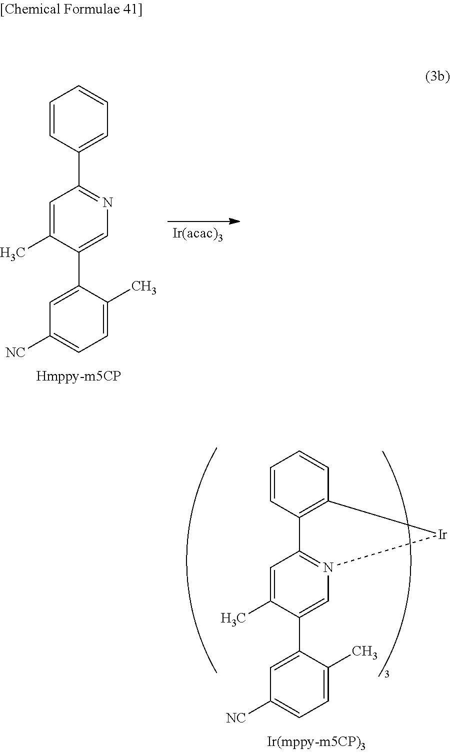

Measurement results obtained by nuclear magnetic resonance spectroscopy (¹H-NMR) revealed that the yellow solid obtained in Step 2 above is Ir(mppy-m5CP)₃). A ¹H-NMR chart is shown in FIG. 23 and analysis results are shown below.

¹H-NMR. δ (CD₂Cl₂): 1.38 (s, 31), 1.49 (d, 3H), 2.04 (s, 61), 2.07 (s, 61), 6.84-6.96 (in, 91), 7.15-7.36 (m, 8H), 7.44 (d, 11), 7.54-7.58 (n, 31), 7.65-7.73 (i, 311), 7.78-7.86 (n, 311).

FIG. 24 shows measurement results of an ultraviolet-visible absorption spectrum of a dichloromethane solution containing Ir(mppy-m5CP)₃ and an emission spectrum thereof. The horizontal axis represents wavelength, and the vertical axis represents absorption intensity and emission intensity. Ir(mppy-m5CP)₃ has an emission peak at 523 nm, and green light emission was observed from dichloromethane. The absorption spectrum shown in FIG. 24 is the result obtained in such a way that the absorption spectrum measured by putting only dichloromethane in a quartz cell was subtracted from the absorption spectrum measured by putting the dichloromethane solution (0.0109 mmol/L) in a quartz cell.

The measurement of the absorption spectrum was conducted at room temperature, for which an ultraviolet-visible spectrophotometer (V550 type produced by JASCO Corporation) was used and the dichloromethane solution (0.0109 mmol/L) was put in a quartz cell.

The measurement of the emission spectrum was conducted at room temperature, for which a fluorescence spectrophotometer (FS920 produced by Hamamatsu Photonics K.K.) was used and the deoxidized dichloromethane solution (0.0109 mmol/L) was put and sealed in a quartz cell under a nitrogen atmosphere in a glove box (LABstar MI3 (1250/780) produced by Bright Co., Ltd.).

Ir(mppy-m5CP)₃ has the methyl group at R¹⁰², which is the ortho-position, of the phenyl group into which the cyano group is introduced at R¹⁰⁵ in General Formula (G0) shown in Embodiment 1. Ir(mppy-m5CP)₃ has another methyl group at R¹¹¹ of the pyridine ring. These two methyl groups strongly inhibit free rotation of the phenyl group. Thus, Ir(mppy-m5CP)₃ exhibits an excellent thermophysical property. Furthermore, the width of the emission spectrum is narrowed to increase the color purity of an emission color. In addition, the organic compound can be suitably used as a green light-emitting material.

### Synthesis Example 4

Synthesis example 4 describes an example of a method for synthesizing tris[2-(5-(5-cyano-2-methylphenyl)-2-pyridinyl-κN)phenyl-κC]iridium(III) (abbreviation: Ir(ppy-m5CP)₃) represented by Structural Formula (138) in Embodiment 1.

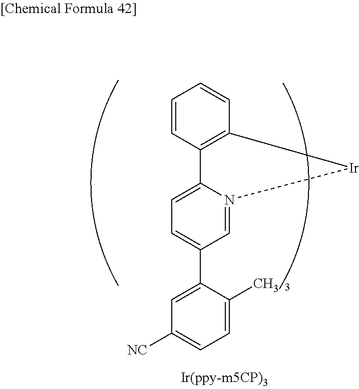

### Step 1; Synthesis of 5-(5-cyano-2-methylphenyl)-2-phenylpyridine (abbreviation: Hppy-m5CP)

9.82 g of 5-bromo-2-methylpyridine, 8.03 g of 5-cyano-2-methylphenylboronic acid, 10.62 g of tripotassium phosphate, 150 mL of toluene, and 15 mL of water were put into a three-neck flask equipped with a reflux pipe, and the air in the flask was replaced with nitrogen. The mixture in the flask was degassed by being stirred under reduced pressure, and then, 0.38 g of tris(dibenzylideneacetone)dipalladium(0) (abbreviation: Pd₂(dba)₃) and 0.70 g of 2-dicyclohexylphosphino-2′,6′-dimethoxybiphenyl (abbreviation: S-Phos) were added thereto. The mixture reacted at 110° C. for 2 hours while being stirred. Synthesis Scheme (4a) of Step 1 is shown below.

After a predetermined time elapsed, the solvent was distilled off, water was added, and a target substance was extracted with use of toluene. The residue obtained by distilling off toluene from the extracted solution was separated by a silica gel column chromatography method using a mixed solvent of hexane and ethyl acetate (hexane:ethyl acetate=10:1) as a mobile phase, and then the mobile phase was distilled off, whereby 11.21 g of a pyridine derivative was obtained as a colorless oily substance (yield: 98%).

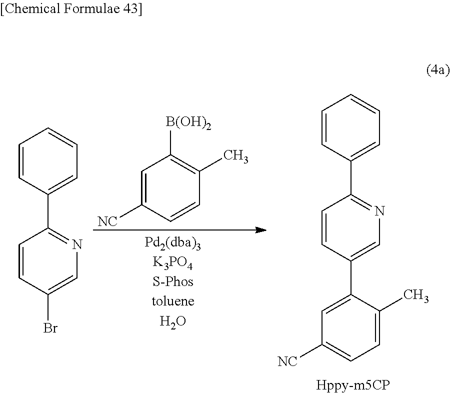

### Step 2; Synthesis of tris[2-(5-(5-cyano-2-methylphenyl)-2-pyridinyl-κN)phenyl-κC]iridium(III) (abbreviation: Ir(ppy-m5CP)₃)

222 g of 5-(5-cyano-2-methylphenyl)-2-phenylpyridine (abbreviation: Hppy-m5CP) obtained in Step 1 above and 0.78 g of tris(2,4-pentanedionato)iridium(III) (abbreviation: Ir(acac)₃) were put into a reaction container equipped with a three-way cock, and the air in the reaction container was replaced with argon. The mixture reacted at 250° C. for 78 hours while being stirred. Synthesis Scheme (4b) of Step 2 is shown below.

After a predetermined time elapsed, the obtained solid was separated by a silica gel column chromatography method using a mixed solvent of hexane and ethyl acetate (hexane:ethyl acetate=2:1) as a mobile phase. Next, the solid obtained by distilling off the mobile phase was separated by a silica gel column chromatography method using dichloromethane as a mobile phase. Moreover, from a mixed solution of dichloromethane, methanol, and the solid obtained by distilling off the mobile phase, 0.30 g of a target substance was obtained as a yellow solid (yield: 19%) by a recrystallization method.

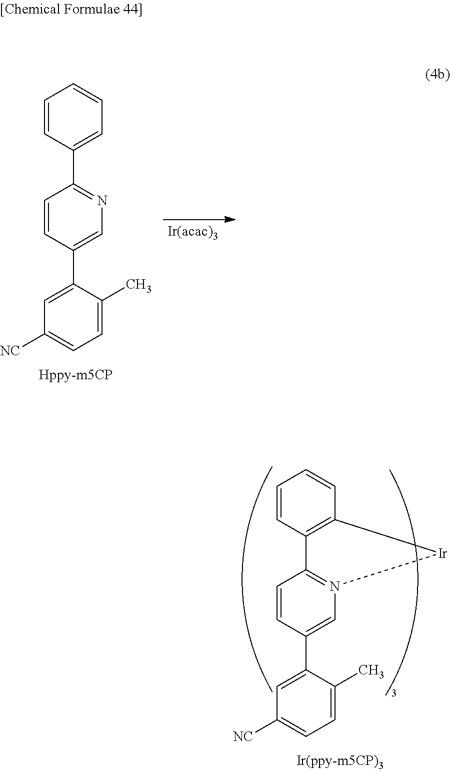

Measurement results obtained by nuclear magnetic resonance spectroscopy (¹H-NMR) revealed that the yellow solid obtained in Step 2 above is Ir(ppy-m5CP)₃). A ¹H-NMR chart is shown in FIG. 25 and analysis results are shown below.

¹H-NMR. δ (CDCl₃): 1.93 (s, 91H), 6.92 (d, 61), 6.96-6.99 (m, 3H), 7.22 (d, 3H), 7.29 (d, 311), 7.49-7.51 (m, 61), 7.55 (dd, 311), 7.72 (d, 311), 7.98 (d, 3H).

FIG. 26 shows measurement results of an ultraviolet-visible absorption spectrum of a dichloromethane solution containing Ir(ppy-m5CP)₃ and an emission spectrum thereof. The horizontal axis represents wavelength, and the vertical axis represents absorption intensity and emission intensity. Ir(ppy-m5CP)₃ has an emission peak at 540 nm, and green light emission was observed from dichloromethane. The absorption spectrum shown in FIG. 26 is the result obtained in such a way that the absorption spectrum measured by putting only dichloromethane in a quartz cell was subtracted from the absorption spectrum measured by putting the dichloromethane solution (0.0099 mmol/L) in a quartz cell.

The measurement of the absorption spectrum was conducted at room temperature, for which an ultraviolet-visible spectrophotometer (V550 type produced by JASCO Corporation) was used and the dichloromethane solution (0.0099 mmol/L) was put in a quartz cell.

The measurement of the emission spectrum was conducted at room temperature, for which a fluorescence spectrophotometer (FS920 produced by Hamamatsu Photonics K.K.) was used and the deoxidized dichloromethane solution (0.0099 mmol/L) was put and sealed in a quartz cell under a nitrogen atmosphere in a glove box (LABstar MI3 (1250/780) produced by Bright Co., Ltd.).

Ir(ppy-m5CP)₃ has the methyl group at R¹⁰² of the phenyl group into which the cyano group is introduced at R¹⁰⁵. The methyl group strongly inhibits free rotation of the phenyl group. Thus, Ir(ppy-m5CP)₃ exhibits an excellent thermophysical property. Furthermore, the width of the emission spectrum is narrowed to increase the color purity of an emission color. In addition, the organic compound can be suitably used as a green light-emitting material.

### Example 2

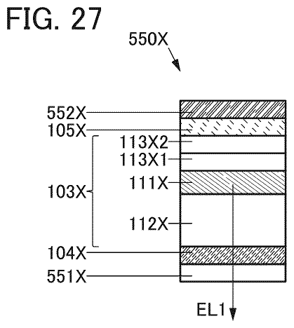

In this example, a light-emitting device 1 of one embodiment of the present invention is described with reference to FIG. 27 to FIG. 34.

FIG. 27 illustrates a structure of the light-emitting device 550X.

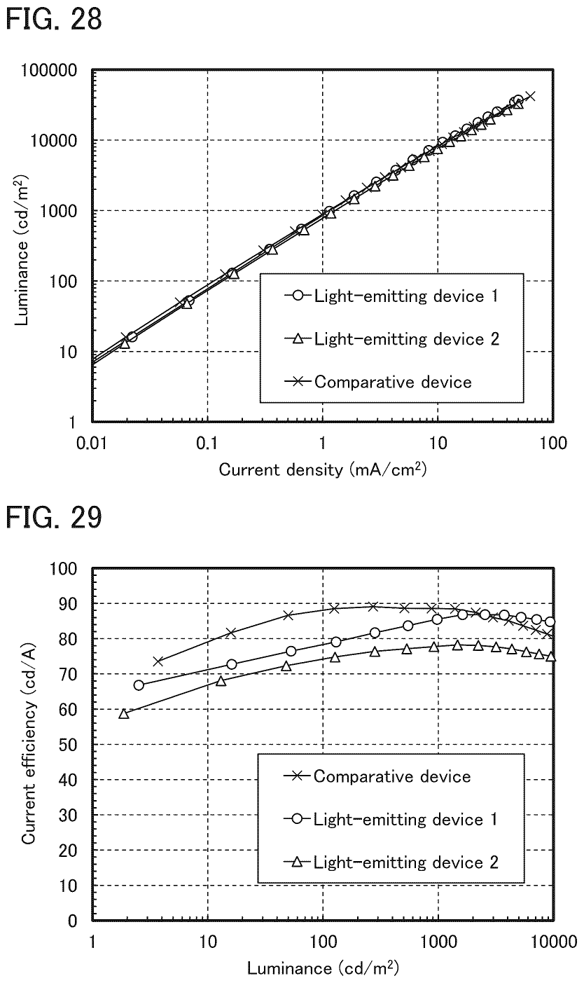

FIG. 28 shows current density-luminance characteristics of the light-emitting device 1 and a light-emitting device 2.

FIG. 29 shows luminance-current efficiency characteristics of the light-emitting device 1 and the light-emitting device 2.

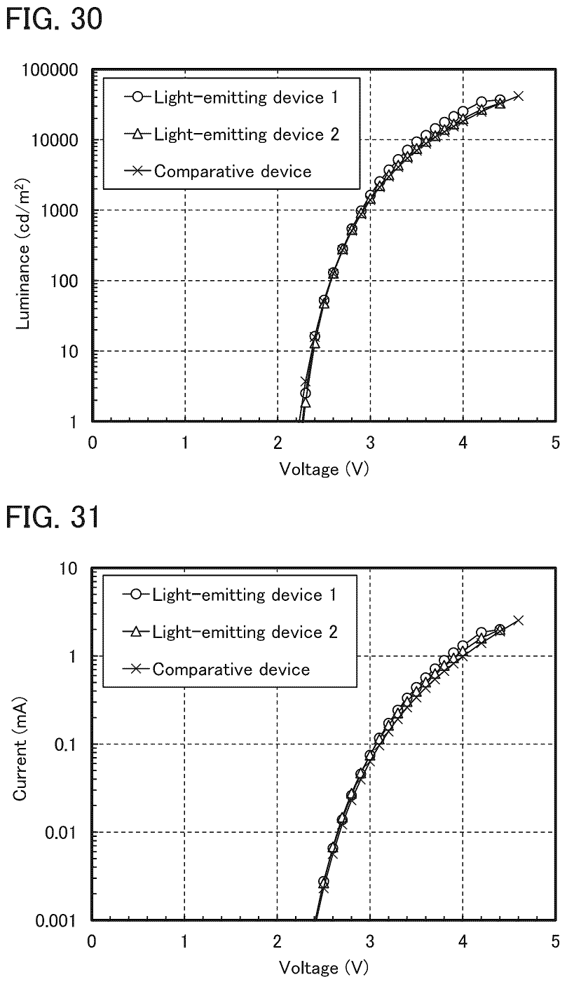

FIG. 30 shows voltage-luminance characteristics of the light-emitting device 1 and the light-emitting device 2.

FIG. 31 shows voltage-current characteristics of the light-emitting device 1 and the light-emitting device 2.

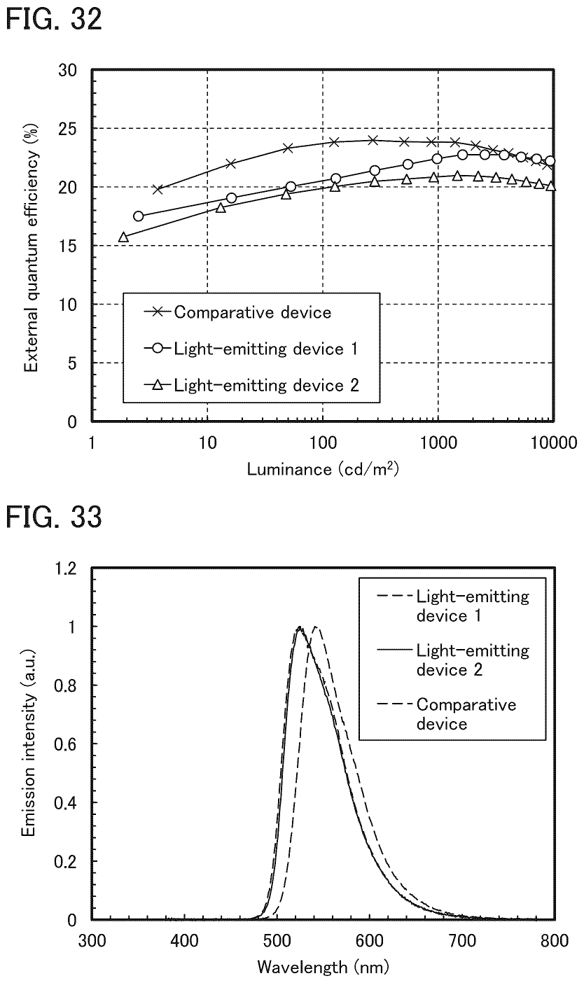

FIG. 32 shows luminance-external quantum efficiency characteristics of the light-emitting device 1 and the light-emitting device 2. Note that the external quantum efficiency was calculated from luminance assuming that the light distribution characteristics of the light-emitting device are Lambertian type.

FIG. 33 shows emission spectra of the light-emitting device 1 and the light-emitting device 2 emitting light at a luminance of 1000 cd/m².

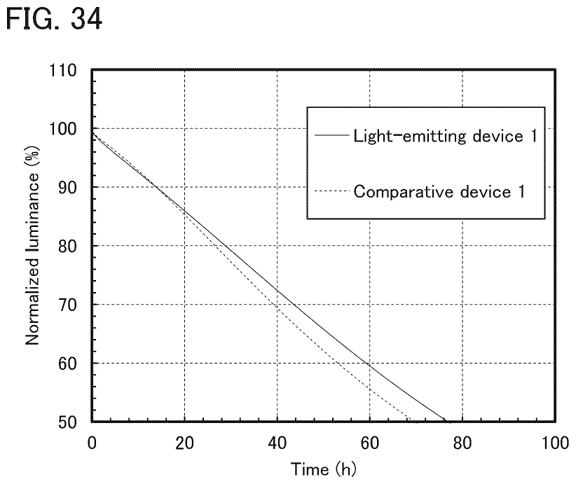

FIG. 34 shows a change in normalized luminance over time of the light-emitting device 1 emitting light at a constant current density (50 mA/cm²).

### <Light-Emitting Device 1>

The fabricated light-emitting device 1, which is described in this example, has a structure similar to that of the light-emitting device 550X (see FIG. 27).

### Structure of Light-Emitting Device 1>>

Table 1 shows the structure of the light-emitting device 1. Structural formulae of materials used in the light-emitting devices described in this example are shown below. Note that in the tables in this example, a subscript character and a superscript character are written in ordinary size for convenience. For example, a subscript character in an abbreviation or a superscript character in a unit are written in ordinary size in the tables. Such notations in the tables can be replaced by referring to the description in the specification.

TABLE 1

| | Refer- | | Compo- | Thick- |
|---|---|---|---|---|
| Struc- | ence | | sition | ness/ |
| ture | numeral | Material | ratio | nm |
| Electrode | 552X | Al | | 200 |
| Layer | 105X | LiF | | 1 |
| Layer | 113X2 | NBphen | | 10 |
| Layer | 113X1 | mPCCzPTzn-02 | | 20 |
| Layer | 111X | mPCCzPTzn- | 0.6:0.4:0.1 | 40 |
| | | 02:PCCP:Ir(mppy-3CP)3 | | |
| Layer | 112X | PCBBi1BP | | 20 |
| Layer | 104X | DBT3P-II:MoOx | 2:1 | 40 |
| Electrode | 551X | ITSO | | 70 |

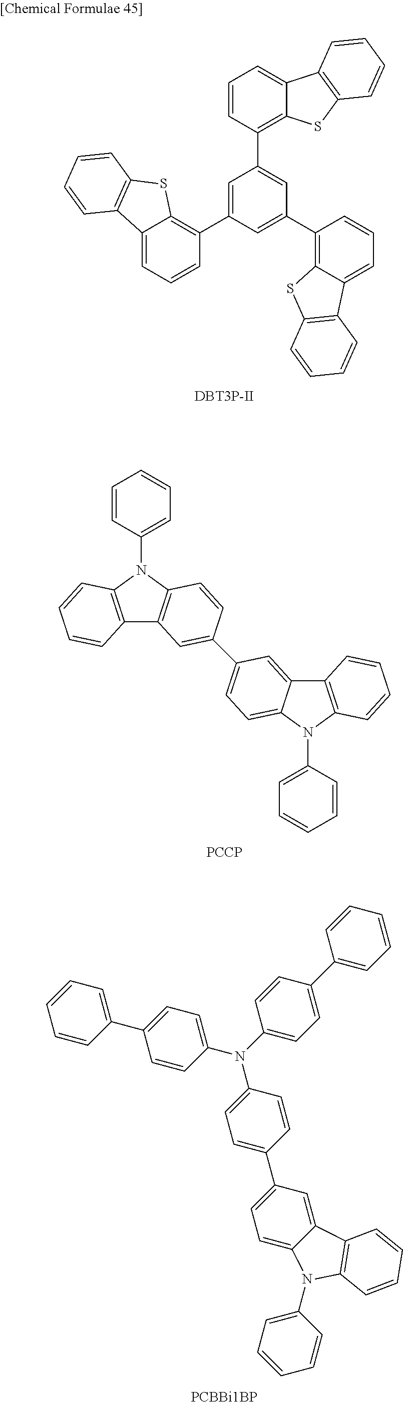 [SMILES: c1ccc2c(c1)sc1c(-c3cc(-c4cccc5c4sc4ccccc45)cc(-c4cccc5c4sc4ccccc45)c3)cccc12 ; "DBT3P-II" ; c1ccc(-n2c3ccccc3c3cc(-c4ccc5c(c4)c4ccccc4n5-c4ccccc4)ccc32)cc1 ; "PCCP" ; c1ccc(-c2ccc(N(c3ccc(-c4ccccc4)cc3)c3ccc(-c4ccc5c(c4)c4ccccc4n5-c4ccccc4)cc3)cc2)cc1 ; "PCBBi1BP"]

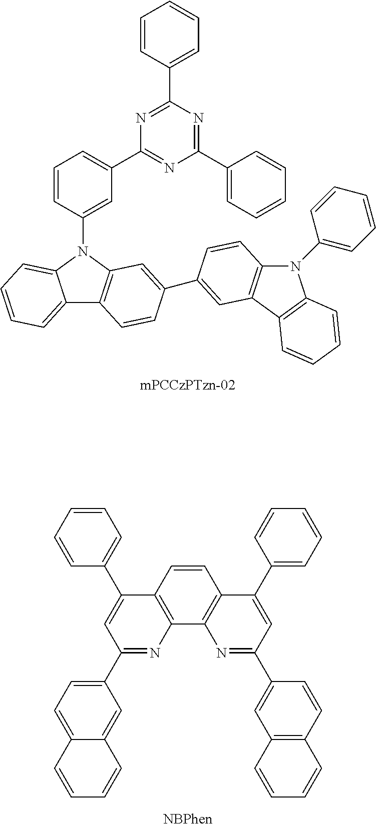 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; c1ccc(-c2cc(-c3ccc4ccccc4c3)nc3c2ccc2c(-c4ccccc4)cc(-c4ccc5ccccc5c4)nc23)cc1]

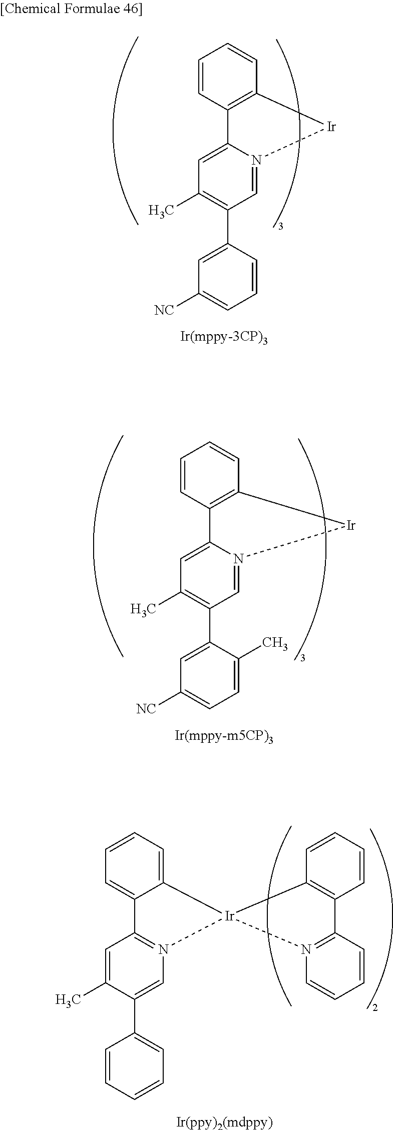

### <<Method for Fabricating Light-Emitting Device 1>>

The light-emitting device 1 described in this example was fabricated using a method including the following steps.

### [Step 1]

In Step 1, the electrode 551X was formed. Specifically, the electrode 551X was formed by a sputtering method using indium oxide-tin oxide containing silicon or silicon oxide (abbreviation: ITSO) as a target. The electrode 551X contains ITSO and has a thickness of 70 nm and an area of 4 mm² (2 mm×2 mm).

Next, a workpiece over which the electrode was formed was washed with water, baked at 200° C. for an hour, and then subjected to UV ozone treatment for 370 seconds. After that, the workpiece was transferred into a vacuum evaporation apparatus where the inside pressure was reduced to approximately 10-4 Pa, and vacuum baking was performed at 170° C. for 30 minutes in a heating chamber of the vacuum evaporation apparatus. Then, the workpiece was cooled down for approximately 30 minutes.

### [Step 2]

In Step 2, the layer 104X was formed over the electrode 551X. Specifically, materials were co-evaporated by a resistance-heating method. Note that the layer 104X contains 4,4′,4″-(benzene-1,3,5-triyl)tri(dibenzothiophene) (abbreviation: DBT3P-II) and molybdenum oxide (abbreviation: MoOx) at DBT3P-II:MoOx=2:1 (weight ratio) and has a thickness of 40 nm.

### [Step 3]

In Step 3, the layer 112X was formed over the layer 104X. Specifically, a material was evaporated by a resistance-heating method. Note that the layer 112X contains 4,4′-diphenyl-4″-(9-phenyl-9H-carbazol-3-yl)triphenylamine (abbreviation: PCBBiIBP) and has a thickness of 20 nm.

### [Step 4]

In Step 4, the layer 111X was formed over the layer 112X. Specifically, materials were co-evaporated by a resistance-heating method. Note that the layer 111X contains 9-[3-(4,6-diphenyl-1,3,5-triazin-2-yl)phenyl]-9′-phenyl-2,3′-bi-9H-carbazole (abbreviation: mPCCzPTzn-02), 9,9′-diphenyl-9H,9′H-3,3′-bicarbazole (abbreviation: PCCP), and tris[2-(4-methyl-5-(3-cyanophenyl)-2-pyridinyl-κN)phenyl-κC]iridium(III) (abbreviation: Ir(mppy-3CP)₃) at mPCCzPTzn-02:PCCP:Ir(mppy-3CP)₃=0.6:0.4:0.1 (weight ratio) and has a thickness of 40 nm.

### [Step 5]

In Step 5, a layer 113X1 was formed over the layer 111X. Specifically, a material was evaporated by a resistance-heating method. Note that the layer 113X1 contains mPCCzPTzn-02 and has a thickness of 20 nm.

### [Step 6]

In Step 6, a layer 113X2 was formed over the layer 113X1. Specifically, a material was evaporated by a resistance-heating method. Note that the layer 113X2 contains 2,9-di(2-naphthyl)-4,7-diphenyl-1,10-phenanthroline (abbreviation: NBphen) and has a thickness of 10 nm.

### [Step 7]

In Step 7, the layer 105X was formed over the layer 113X2. Specifically, a material was evaporated by a resistance-heating method. Note that the layer 105X contains lithium fluoride (LiF) and has a thickness of 1 nm.

### [Step 8]

In Step 8, the electrode 552X was formed over the layer 105X. Specifically, a material was evaporated by a resistance-heating method. Note that the electrode 552X contains aluminum (Al) and has a thickness of 200 nm.

### <<Operation Characteristics of Light-Emitting Device 1>>

When supplied with electric power, the light-emitting device 1 emitted light EL1 (see FIG. 27). The operation characteristics of the light-emitting device 1 were measured at room temperature (23° C.) (see FIG. 28 to FIG. 33). Note that luminance and CIE chromaticity were measured with a luminance colorimeter (BM-5A produced by TOPCON TECHNOHOUSE CORPORATION), and emission spectra were measured with a multi-channel spectrometer (PMA-11 produced by Hamamatsu Photonics K.K.).

Table 2 shows main initial characteristics of the fabricated light-emitting device emitting light at a luminance of approximately 1000 cd/m². A time LT50 taken for the luminance to drop to 50% of its initial luminance was measured under the condition where the light-emitting device emitted light at a constant current density (50 mA/cm²) in an environment at 85° C. Table 3 shows the LT50. Table 2 also shows the characteristics of the other light-emitting devices whose structures are described later.

TABLE 2

| | | | | | | | External |
|---|---|---|---|---|---|---|---|
| | | | Current | | | Current | quantum |
| | Voltage | Current | density | Chromaticity | Chromaticity | efficiency | efficiency |
| | (V) | (mA) | (mA/cm2) | x | y | (cd/A) | (%) |
| Light-emitting device 1 | 2.9 | 0.05 | 1.1 | 0.39 | 0.60 | 85.5 | 22.4 |
| Light-emitting device 2 | 2.9 | 0.05 | 1.2 | 0.35 | 0.62 | 77.7 | 20.8 |
| Comparative device 1 | 2.9 | 0.04 | 1.0 | 0.33 | 0.63 | 88.6 | 23.8 |

TABLE 3

| | LT50 |
|---|---|
| | (hr) |
| Light-emitting device 1 | 77.0 |
| Comparative device 1 | 70.0 |

The light-emitting device 1 was found to have favorable characteristics. For example, the light-emitting device 1 was able to have long time LT50 taken for the luminance to drop to 50% of its initial luminance, in the severe high-temperature environment at 85° C. Moreover, the driving lifetime was made longer than that of the comparative device 1 whose structure is described in Reference example 1 described later. Furthermore, the introduction of the cyano group improved the heat resistance without impairing the favorable driving voltage and the favorable external quantum efficiency characteristics.

### <Light-Emitting Device 2>

The fabricated light-emitting device 2 described in this example has a structure similar to that of the light-emitting device 550X (see FIG. 27). The structure of the light-emitting device 2 is different from that of the light-emitting device 1 in the layer 111X. Specifically, the light-emitting device 2 is different from the light-emitting device T in that the layer 111X contains tris[2-(4-methyl-5-(5-cyano-2-methylphenyl)-2-pyridinyl-κN)phenyl-κC]iridium(III) (abbreviation: Ir(mppy-m5CP)₃) instead of Ir(mppy-3CP)₃.

### <<Method for Fabricating Light-Emitting Device 2>>

The light-emitting device 2 described in this example was fabricated using a method including the following steps.

The method for fabricating the light-emitting device 2 is different from the method for fabricating the light-emitting device 1 in that Ir(mppy-m5CP)₃ was used in Step 4 instead of Ir(mppy-3CP)₃. Different portions are described in detail here, and the above description is referred to for portions formed by a similar method.

### [Step 4]

In Step 4, the layer 111X was formed over the layer 112X. Specifically, materials were co-evaporated by a resistance-heating method. Note that the layer 111X contains mPCCzPTzn-02, PCCP, and Ir(mppy-m5CP)₃ at mPCCzPTzn-02:PCCP:Ir(mppy-m5CP)₃=0.6:0.4:0.1 (weight ratio) and has a thickness of 40 nm.

### <<Operation Characteristics of Light-Emitting Device 2>>

When supplied with electric power, the light-emitting device 1 and the light-emitting device 2 emitted the light EL1 (see FIG. 27). The operation characteristics of the light-emitting device 2 were measured at room temperature (see FIG. 28 to FIG. 33).

Table 2 shows main initial characteristics of the fabricated light-emitting device emitting light at a luminance of approximately 1000 cd/m².

The light-emitting device 2 was found to have favorable characteristics. For example, the light-emitting device 2 emitted green light with high color purity. Moreover, the light-emitting device 2 had color purity which can be suitably used for full color display.

### Reference Example 1

The fabricated comparative device 1, which is described in this reference example, has a structure similar to that of the light-emitting device 550X (see FIG. 27).

### Structure of Comparative Device 1>>

The structure of the comparative device 1 is different from that of the light-emitting device 1 in the layer 111X. Specifically, the comparative device 1 is different from the light-emitting device 1 in that the layer 111X contains [2-(4-methyl-5-phenyl-2-pyridinyl-κN)phenyl-κC]bis[2-(2-pyridinyl-A)phenyl-κC]iridium(III) (abbreviation: Ir(ppy)₂(mdppy)) instead of Ir(mppy-3CP)₃.

### <<Method for Fabricating Comparative Device 1>>

The comparative device 1 described in this example was fabricated using a method including the following steps.

The method for fabricating the comparative device 1 is different from the method for fabricating the light-emitting device 1 in that Ir(ppy)₂(mdppy) was used in Step 4 instead of Ir(mppy-3CP)₃. Different portions are described in detail here, and the above description is referred to for portions formed by a similar method.

### [Step 4]

In Step 4, the layer 111X was formed over the layer 112X. Specifically, materials were co-evaporated by a resistance-heating method. Note that the layer 111X contains mPCCzPTzn-02, PCCP, and Ir(ppy)₂(mdppy) at mPCCzPTzn-02:PCCP:Ir(ppy)₂(mdppy)=0.6:0.4:0.1 (weight ratio) and has a thickness of 40 nm.

### <<Operation Characteristics of Comparative Device 1>>

When supplied with electric power, the comparative device 1 emitted the light EL1 (see FIG. 27). The operation characteristics of the comparative device 1 were measured at room temperature (see FIG. 28 to FIG. 33).

Table 2 shows main initial characteristics of the fabricated comparative device 1 emitting light at a luminance of approximately 1000 cd/in². A time LT50 taken for the luminance to drop to 50% of its initial luminance was measured under the condition where the comparative device 1 emitted light at a constant current density (50 mA/cm²) in an environment at 85° C. Table 3 shows the LT50.

### REFERENCE NUMERALS

ANO: conductive film, C21: capacitor, C22: capacitor, CFX: coloring layer, CP: conductive material, GD: driver circuit, hv: light, M21: transistor, N21: node, N22: node, SD: driver circuit, SW21: switch, SW22: switch, SW23: switch, ELX: light, ELY: light, 103S: unit, 103X: unit, 103Y: unit, 104S: layer, 104X: layer, 104XY: region, 104Y: layer, 104: layer, 105S: layer, 105X: layer, 105Y: layer, 105: layer, 106_1: layer, 106_2: layer, 106_3: layer, 106: layer, 111X: layer, 111Y: layer, 112_2: layer, 112S: layer, 112X: layer, 112: layer, 113_2: layer, 113S: layer, 113X: layer, 113: layer, 114N: layer, 114P: layer, 114S: layer, 231: region, 400: substrate, 401: first electrode, 403: EL layer, 404: second electrode, 405: sealing material, 406: sealing material, 407: sealing substrate, 412: pad, 420: IC chip, 510: substrate, 519B: terminal, 520T: region, 520: functional layer, 521: insulating film, 528: insulating film, 529_1: film, 529_2: film, 529_3: film, 530X: pixel circuit, 540: functional layer, 550S: photoelectric conversion device, 550X: light-emitting device, 550Y: light-emitting device, 551S: electrode, 551X: electrode, 551XS: space, 551XY: space, 551Y: electrode, 552S: electrode, 552X: electrode, 552Y: electrode, 591X: opening, 591Y: opening, 601: source line driver circuit, 602: pixel portion, 603: gate line driver circuit, 604: sealing substrate, 605: sealing material, 607: space, 608: lead wiring, 609: external input terminal, 610: element substrate, 611: switching FET, 612: current controlling FET, 613: first electrode, 614: insulator, 616: EL layer, 617: second electrode, 618: light-emitting device, 623: FET, 700: display apparatus, 702X: pixel, 703: pixel, 951: substrate, 952: electrode, 953: insulating layer, 954: partition layer, 955: EL layer, 956: electrode, 1001: substrate, 1002: base insulating film, 1003: gate insulating film, 1006: gate electrode, 1007: gate electrode, 1008: gate electrode, 1020: first interlayer insulating film, 1021: second interlayer insulating film, 1022: electrode, 1024B: electrode, 1024G: electrode, 1024R: electrode, 1024W: electrode, 1025: partition, 1028: EL layer, 1029: electrode, 1031: sealing substrate, 1032: sealing material, 1033: base, 1034B: coloring layer, 1034G: coloring layer, 1034R: coloring layer, 1035: black matrix, 1036: overcoat layer, 1037: third interlayer insulating film, 1040: pixel portion, 1041: driver circuit portion, 1042: peripheral portion, 2001: housing, 2002: light source, 2100: robot, 2102: microphone, 2103: upper camera, 2104: speaker, 2105: display, 2106: lower camera, 2107: obstacle sensor, 2108: moving mechanism, 2110: arithmetic device, 3001: lighting device, 5000: housing, 5001: display portion, 5002: display portion, 5003: speaker, 5004: LED lamp, 5006: connection terminal, 5007: sensor, 5008: microphone, 5012: support, 5013: earphone, 5100: cleaning robot, 5101: display, 5102: camera, 5103: brush, 5104: operation button, 5120: dust, 5140: portable electronic device, 5200: display region, 5201: display region, 5202: display region, 5203: display region, 7101: housing, 7103: display portion, 7105: stand, 7107: display portion, 7109: operation key, 7110: remote controller, 7201: main body, 7202: housing, 7203: display portion, 7204: keyboard, 7205: external connection port, 7206: pointing device, 7210: second display portion, 7401: housing, 7402: display portion, 7403: operation button, 7404: external connection port, 7405: speaker, 7406: microphone, 9310: portable information terminal, 9311: display panel, 9313: hinge, 9315: housing

1. An organic compound represented by General Formula (G0): 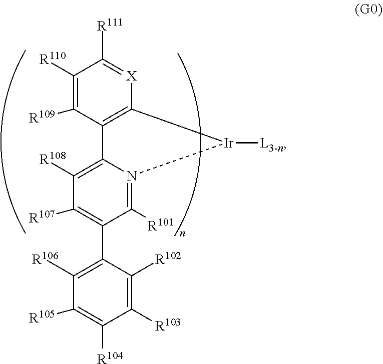
wherein:
X is a nitrogen atom or a carbon atom;
when X is a carbon atom, X is bonded to hydrogen or a substituent;
one of R¹⁰⁴ and R¹⁰⁵ is a cyano group;
at least one of R¹⁰² and R¹⁰⁷ is an alkyl group having 1 to 6 carbon atoms;
the rest of R¹⁰¹ to R¹¹¹ are each independently bonded to hydrogen or a substituent;
the substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group;
n is an integer greater than or equal to 1 and less than or equal to 3; and
L is a ligand represented by Structural Formula (L0): 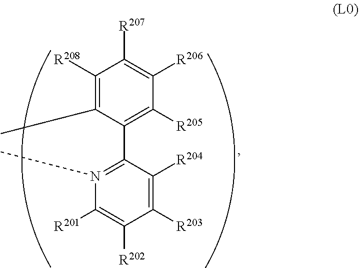
wherein:
R²⁰¹ to R²⁰⁸ are each independently hydrogen or an alkyl group having 1 to 6 carbon atoms.

2. The organic compound according to claim 1,
wherein the organic compound is represented by General Formula (G1):

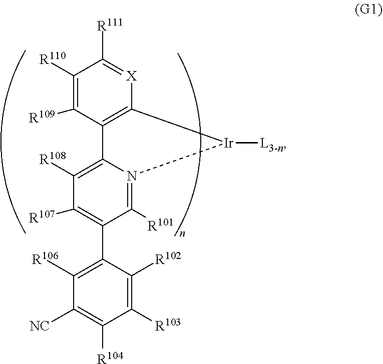

3. An organic compound represented by General Formula (G2): 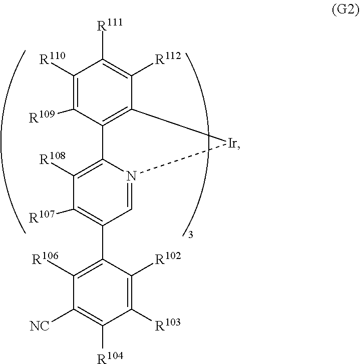
wherein:
at least one of R¹⁰² and R¹⁰⁷ is an alkyl group having 1 to 6 carbon atoms;
the rest of R¹⁰² to R¹¹² are each independently bonded to hydrogen or a substituent; and
the substituents are each independently an alkyl group having 1 to 6 carbon atoms, a cycloalkyl group having 3 to 7 carbon atoms, a substituted or unsubstituted aryl group having 6 to 13 carbon atoms, a substituted or unsubstituted heteroaryl group having 1 to 5 carbon atoms, an amino group, or a hydroxy group.

4. The organic compound according to claim 3,
wherein the organic compound is represented by General Formula (G3):

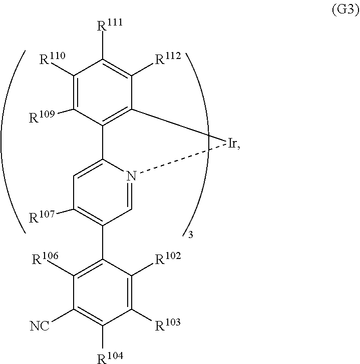

5. The organic compound according to claim 3,
wherein the organic compound is represented by General Formula (G4):

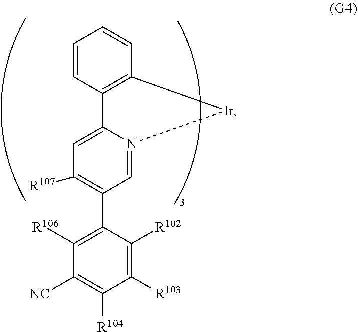

6. A light-emitting device comprising:
a first electrode;
a second electrode; and
a first unit,
wherein the first unit is interposed between the first electrode and the second electrode, and
wherein the first unit comprises the organic compound according to claim 1.

7. A display apparatus comprising:
a first light-emitting device; and
a second light-emitting device,
wherein the first light-emitting device comprises a third electrode, a fourth electrode, a second unit, and a first layer,
wherein the second unit is interposed between the third electrode and the fourth electrode,
wherein the first layer is interposed between the second unit and the third electrode,
wherein the second unit comprises the organic compound according to claim 1,
wherein the first layer comprises a second organic compound comprising a halogen group or a cyano group, or a transition metal oxide,
wherein the second light-emitting device is adjacent to the first light-emitting device,
wherein the second light-emitting device comprises a fifth electrode, a sixth electrode, a third unit, and a second layer,
wherein a space is between the fifth electrode and the third electrode,
wherein the third unit is interposed between the sixth electrode and the fifth electrode,
wherein the third unit comprises a light-emitting material,
wherein the second layer is interposed between the third unit and the fifth electrode,
wherein the second layer comprises the second organic compound or the transition metal oxide,
wherein the second layer comprises a region thinner than the first layer between the second layer and the first layer, and
wherein the region overlaps with the space.

8. A display apparatus comprising:
a first functional layer; and
a second functional layer,
wherein the first functional layer overlaps with the second functional layer,
wherein the first functional layer comprises a first pixel circuit and a second pixel circuit,
wherein the second functional layer comprises a first light-emitting device and a second light-emitting device,
wherein the first light-emitting device comprises a third electrode, a fourth electrode, and a second unit,
wherein the second unit is interposed between the third electrode and the fourth electrode,
wherein the second unit comprises the organic compound according to claim 1,
wherein the third electrode is electrically connected to the first pixel circuit,
wherein the second light-emitting device comprises a fifth electrode, a sixth electrode, and a third unit,
wherein the third unit is interposed between the fifth electrode and the sixth electrode,
wherein the fifth electrode is electrically connected to the second pixel circuit, and
wherein the sixth electrode is electrically connected to the fourth electrode.

9. The organic compound according to claim 1, wherein the substituents are bonded to each other to form a ring.

10. The organic compound according to claim 3, wherein the substituents are bonded to each other to form a ring.

11. A light-emitting device comprising:
a first electrode;
a second electrode; and
a first unit,
wherein the first unit is interposed between the first electrode and the second electrode, and
wherein the first unit comprises the organic compound according to claim 3.

12. A display apparatus comprising:
a first light-emitting device; and
a second light-emitting device,
wherein the first light-emitting device comprises a third electrode, a fourth electrode, a second unit, and a first layer,
wherein the second unit is interposed between the third electrode and the fourth electrode,
wherein the first layer is interposed between the second unit and the third electrode,
wherein the second unit comprises the organic compound according to claim 3,
wherein the first layer comprises a second organic compound comprising a halogen group or a cyano group, or a transition metal oxide,
wherein the second light-emitting device is adjacent to the first light-emitting device,
wherein the second light-emitting device comprises a fifth electrode, a sixth electrode, a third unit, and a second layer,
wherein a space is between the fifth electrode and the third electrode,
wherein the third unit is interposed between the sixth electrode and the fifth electrode,
wherein the third unit comprises a light-emitting material,
wherein the second layer is interposed between the third unit and the fifth electrode,
wherein the second layer comprises the second organic compound or the transition metal oxide,
wherein the second layer comprises a region thinner than the first layer between the second layer and the first layer, and
wherein the region overlaps with the space.

13. A display apparatus comprising:
a first functional layer; and
a second functional layer,
wherein the first functional layer overlaps with the second functional layer,
wherein the first functional layer comprises a first pixel circuit and a second pixel circuit,
wherein the second functional layer comprises a first light-emitting device and a second light-emitting device,
wherein the first light-emitting device comprises a third electrode, a fourth electrode, and a second unit,
wherein the second unit is interposed between the third electrode and the fourth electrode,
wherein the second unit comprises the organic compound according to claim 3,
wherein the third electrode is electrically connected to the first pixel circuit,
wherein the second light-emitting device comprises a fifth electrode, a sixth electrode, and a third unit,
wherein the third unit is interposed between the fifth electrode and the sixth electrode,
wherein the fifth electrode is electrically connected to the second pixel circuit, and
wherein the sixth electrode is electrically connected to the fourth electrode.
